(19) United States
(12) Patent Application Publication
(10) Pub. No.: US 2023/0215784 A1
(43) Pub. Date: Jul. 6, 2023

(54) METHOD OF MANUFACTURING A SEMICONDUCTOR DEVICE INCLUDING INTERLAYER INSULATING FILMS HAVING DIFFERENT YOUNGS MODULUS

(71) Applicant: RENESAS ELECTRONICS CORPORATION, Tokyo (JP)

(72) Inventors: Masahiro MATSUMOTO, Tokyo (JP); Masahiko FUJISAWA, Tokyo (JP); Akihiko OSAKI, Tokyo (JP); Atsushi ISHII, Tokyo (JP)

(21) Appl. No.: 18/182,780

(22) Filed: Mar. 13, 2023

Related U.S. Application Data
(63) Continuation of application No. 16/811,846, filed on Mar. 6, 2020.
Application No. 16/811,846 is a continuation of application No. 13/264,120, filed on Oct. 12, 2011, now abandoned.

(51) Int. Cl. H01L 23/532; H01L 23/522; H01L 21/768

(52) U.S. Cl. CPC H01L 23/53295; H01L 23/5226; H01L 21/768

(57) ABSTRACT

A preferred aim of the invention is to provide technique for improving reliability of semiconductor devices when using a low-dielectric-constant film having a lower dielectric constant than a silicon oxide film to a part of an interlayer insulating film. More specifically, to achieve the preferred aim, an interlayer insulating film IL1 forming a first fine layer is formed of a middle-Young's-modulus film, and thus it is possible to separate an integrated high-Young's-modulus layer (a semiconductor substrate 1S and a contact interlayer insulating film CIL) and an interlayer insulating film (a low-Young's-modulus film; a low-dielectric-constant film) IL2 forming a second fine layer not to let them directly contact with each other, and stress can be diverged. As a result, film exfoliation of the interlayer insulating film IL2 formed of a low-Young's-modulus film can be prevented and thus reliability of semiconductor devices can be improved.

### CROSS REFERENCE TO RELATED APPLICATIONS

This application is a Continuation of U.S. patent application Ser. No. 16/811,846, filed on Mar. 6, 2020, which is a Continuation of U.S. patent application Ser. No. 13/264,120, filed on Oct. 12, 2011, which is the U.S. National Phase under 35 U.S.C. § 371 of International Application No. PCT/JP2009/058510, filed on Apr. 30, 2009, the disclosure of which are incorporated by reference herein.

### TECHNICAL FIELD

The present invention relates to a semiconductor device and a method of manufacturing the same, more particularly to technology effectively applied to a semiconductor device in which a semiconductor chip having a multilayer wiring structure is packaged by covering with resin and a method of manufacturing the semiconductor device.

### BACKGROUND ART

Japanese Patent Application Laid-Open Publication No. 2006-32864 (Patent Document 1) describes a structure in which a multilayer wiring is formed on a semiconductor substrate. More specifically, a semiconductor element is formed on the semiconductor substrate and a contact interlayer insulator is formed to cover the semiconductor element. Then, to the contact interlayer insulator, a plug to be electrically connected to the semiconductor element is formed. On the contact interlayer insulator to which the plug is formed, a wiring formed of a normal metal layer is formed, and a planarizing insulating layer formed of boron-phosphorus-silicate glass is formed to cover the wiring. On the planarizing insulating layer, a first insulating layer formed of a SiOC film is formed, and a first buried wiring formed of a copper film is formed to be buried in the first insulting layer. Then, a second insulating layer is formed on the first insulting layer in which the first buried wiring is formed. The second insulating layer has a stacked-layer structure of a lower layer insulating layer having a relatively high dielectric constant and an upper layer insulating layer formed of polyarylether having a low dielectric constant. Here, a plug is formed to the lower insulating layer included in the second insulating layer and a second buried wiring formed of a copper film is formed in the upper insulating layer included in the second insulating layer.

### CONVENTIONAL ART DOCUMENT

### Patent Document

Patent Document 1: Japanese Patent Application Laid-Open Publication No. 2006-32864

### DISCLOSURE OF THE INVENTION

### Problems to be Solved by the Invention

MISFET (Metal Insulator Semiconductor Field Effect Transistor) is formed on a semiconductor substrate composing a semiconductor chip, and a multilayer wiring is formed on the MISFET. In recent years, to achieve high integration of semiconductor chips, miniaturization of multilayer wiring has been advanced. Therefore, an increase in resistance due to miniaturization of wirings and an increase in parasitic capacitance due to a reduction in the distance between wirings have become apparent. That is, as electric signals are flowed in the multilayer wiring, delay of the electric signals occurs due to the increase in resistance of the wiring and the increase in parasitic capacitance between the wirings. For example, in a circuit in which timing is important, it is feared that delay of electric signals flowed in wirings poses malfunction and the circuit does not function as a normal circuit. Therefore, to prevent delay of electric signals flowed in the wiring, it is necessary to suppress an increase in resistance of the wiring and to reduce the parasitic capacitance between wirings.

Therefore, in recent years, material forming the multilayer wiring has been changed from aluminum film to copper film. That is because, as the copper film has a lower resistivity than the aluminum film, it is necessary to suppress an increase in resistance of the wiring even when the wiring is miniaturized. Further, in view of reducing the parasitic capacitance between wirings, forming a part of the interlayer insulator provided between wirings with a low-dielectric-constant film having a low dielectric constant has been implemented.

As explained above, to achieve an improvement in performance of semiconductor devices having a multilayer wiring, a copper film is used as a material for the wiring and a low-dielectric-constant film is used in a part of the interlayer insulating film.

A semiconductor chip is packaged in “back-end process”. For example, after mounting a semiconductor chip on a wiring board, a pad formed to the semiconductor chip and terminals formed to the wiring board are connected by wires. Thereafter, the semiconductor chip being sealed by a resin is packaged. As the finished package is used in various temperature conditions, the semiconductor chip is required to operate normally accommodating a wide range of temperature range. Therefore, after being packaged, the semiconductor chip is subjected to a temperature cycle test.

For example, when a temperature cycle test is performed to a package in which a semiconductor chip is sealed by a resin, as the coefficient of thermal expansion and Young's modulus are different in the resin and the semiconductor chip, stress is applied to the semiconductor chip. In this case, in a semiconductor chip using a low-dielectric-constant film to a part of an interlayer insulating film, exfoliation of the low-dielectric-constant film particularly occurs. That is, it has been found out that the exfoliation of the low-dielectric-constant film occurs because stress is generated to the semiconductor chip due to differences in the coefficient of thermal expansion and Young's modulus between the semiconductor chip and the resin in a temperature change implemented in the temperature cycle test, and the stress is generated on the semiconductor chip. When exfoliation of the interlayer insulating film occurs in the semiconductor chip, the semiconductor chip is defective as a device, lowering reliability of the semiconductor device.

A preferred aim of the present invention is to provide technique capable of improving reliability of semiconductor devices even when using a low-dielectric-constant film having a lower dielectric constant than a silicon oxide film to a part of an interlayer insulating film.

The above and other preferred aims and novel characteristics of the present invention will be apparent from the description of the present specification and the accompanying drawings.

### Means for Solving the Problems

The typical ones of the inventions disclosed in the present application will be briefly described as follows.

A method of manufacturing a semiconductor device according to a typical embodiment includes the steps of: (a) forming a MISFET on a semiconductor substrate; (b) forming a contact interlayer insulating film covering the MISFET on the semiconductor substrate; and (c) forming a first plug in the contact interlayer insulating film and electrically connecting the first plug and the MISFET. And, the method includes the steps of: (d) forming a first interlayer insulating film on the contact interlayer insulating film to which the first plug is formed; and (e) forming a first layer wiring buried in the first interlayer insulating film and electrically connecting the first layer wiring and the first plug. In addition, the method includes the steps of: (f) forming a second interlayer insulating film on the first interlayer insulating film to which the first layer wiring is formed; and (g) forming a second plug buried in the second interlayer insulating film and a second layer wiring and electrically connecting the second layer wiring and the first layer wiring via the second plug. Subsequently, the method includes the steps of: (h) further forming a multilayer wiring on the second layer interlayer insulating film; (i) forming a passivation film on an uppermost layer wiring of the multilayer wiring; and (j) forming an opening portion to the passivation film and forming a pad by exposing the uppermost layer wiring from the opening portion. Next, the method includes the steps of: (k) singulating the semiconductor substrate into semiconductor chips; (l) packaging the semiconductor chips, in which the step (l) includes sealing at least a part of the semiconductor chip with a resin. Here, among the contact interlayer insulating film, the first interlayer insulating film, and the second interlayer insulating film, the contact interlayer insulating film is formed of a high-Young's-modulus film having the highest Young's modulus, the second interlayer insulating film is formed of a low-Young's-modulus film having the lowest Young's modulus, and the first interlayer insulating film is formed of a middle-Young's-modulus film having a Young's modulus lower than that of the contact interlayer insulating film and higher than that of the second interlayer insulating film.

Moreover, a semiconductor device according to a typical embodiment includes: (a) a semiconductor chip having a pad; and (b) a package body packaging the semiconductor chip, in which the package body has a resin body sealing at least a part of the semiconductor chip. The semiconductor chip includes: (a1) semiconductor substrate; (a2) a MISFET formed to the semiconductor substrate; (a3) a contact interlayer insulating film covering the MISFET and formed on the semiconductor substrate; and (a4) a first plug penetrating through the contact interlayer insulating film and electrically connected to the MISFET. Further, the semiconductor device includes: (a5) a first interlayer insulating film formed on the contact interlayer insulating film to which the first plug is formed; (a6) a first layer wiring formed in the first interlayer insulating film and electrically connected to the first plug; and (a7) a second interlayer insulating film formed on the first interlayer insulating film to which the first layer wiring is formed. Moreover, the semiconductor device includes: (a8) a second plug formed in the second interlayer insulating film and electrically connected to the first layer wiring; and (a9) a second layer wiring formed in the second interlayer insulating film and electrically connected to the second plug. Here, among the contact interlayer insulating film, the first interlayer insulating film, and the second interlayer insulating film, the contact interlayer insulating film is formed of a high-Young's-modulus film having the highest Young's modulus, the second interlayer insulating film is formed of a low-Young's-modulus film having the lowest Young's modulus, and the first interlayer insulating film is formed of a middle-Young's-modulus film having a Young's modulus lower than that of the contact interlayer insulating film and higher than that of the second interlayer insulating film.

### Effects of the Invention

The effects obtained by typical aspects of the present invention will be briefly described below.

It is possible to improve reliability of a semiconductor device even when using a low-dielectric-constant film having a lower dielectric constant than a silicon oxide film to a part of an interlayer insulating film.

### BRIEF DESCRIPTIONS OF THE DRAWINGS

FIG. 1 is a cross-sectional view illustrating a configuration example of a package;

FIG. 2 is a cross-sectional view illustrating another configuration example of the package;

FIG. 3 is a cross-sectional view illustrating a configuration (device structure) of a semiconductor device in a first embodiment of the present invention;

FIG. 4 is a cross-sectional view illustrating a first layer wiring (first fine layer) and a second layer wiring (second fine layer) formed on the first layer wiring in the device structure illustrated in FIG. 3;

FIG. 5 is a cross-sectional view illustrating a seventh layer wiring (semi-global layer) and an eighth layer wiring (global layer) formed on the seventh layer wiring in the device structure illustrated in FIG. 3;

FIG. 6 is a table sorting material films used to an interlayer insulating film of the first embodiment in view of relative permittivity (dielectric constant);

FIG. 7 is a table sorting material films used to an interlayer insulating film of the first embodiment in view of Young's modulus;

FIG. 8 is a table sorting material films used to an interlayer insulating film of the first embodiment in view of density;

FIG. 9 is a graph illustrating a relationship of relative permittivity (dielectric constant) and Young's modulus regarding a material film composing an interlayer insulating film;

FIG. 10 is a graph illustrating a relationship of relative permittivity (dielectric constant) and Young's modulus regarding a material film composing an interlayer insulating film;

FIG. 11 is a graph illustrating a relationship of relative permittivity (dielectric constant) and density regarding a material film composing an interlayer insulating film;

FIG. 12 is a graph illustrating a relationship of a distance from a semiconductor substrate and shear stress;

FIG. 13 is a cross-sectional view illustrating a manufacturing process of a semiconductor device according to the first embodiment;

FIG. 14 is a cross-sectional view illustrating the manufacturing process of the semiconductor device continued from FIG. 13;

FIG. 15 is a cross-sectional view illustrating the manufacturing process of the semiconductor device continued from FIG. 14;

FIG. 16 is a cross-sectional view illustrating the manufacturing process of the semiconductor device continued from FIG. 15;

FIG. 17 is a cross-sectional view illustrating the manufacturing process of the semiconductor device continued from FIG. 16;

FIG. 18 is a cross-sectional view illustrating the manufacturing process of the semiconductor device continued from FIG. 17;

FIG. 19 is a cross-sectional view illustrating the manufacturing process of the semiconductor device continued from FIG. 18;

FIG. 20 is a cross-sectional view illustrating the manufacturing process of the semiconductor device continued from FIG. 19;

FIG. 21 is a cross-sectional view illustrating the manufacturing process of the semiconductor device continued from FIG. 20;

FIG. 22 is a cross-sectional view illustrating the manufacturing process of the semiconductor device continued from FIG. 21;

FIG. 23 is a cross-sectional view illustrating the manufacturing process of the semiconductor device continued from FIG. 22;

FIG. 24 is a cross-sectional view illustrating the manufacturing process of the semiconductor device continued from FIG. 23;

FIG. 25 is a cross-sectional view illustrating the manufacturing process of the semiconductor device continued from FIG. 24;

FIG. 26 is a cross-sectional view illustrating the manufacturing process of the semiconductor device continued from FIG. 25;

FIG. 27 is a cross-sectional view illustrating the manufacturing process of the semiconductor device continued from FIG. 26;

FIG. 28 is a cross-sectional view illustrating the manufacturing process of the semiconductor device continued from FIG. 27;

FIG. 29 is a cross-sectional view illustrating the manufacturing process of the semiconductor device continued from FIG. 28;

FIG. 30 is a cross-sectional view illustrating the manufacturing process of the semiconductor device continued from FIG. 29;

FIG. 31 is a cross-sectional view illustrating the manufacturing process of the semiconductor device continued from FIG. 30;

FIG. 32 is a cross-sectional view illustrating the manufacturing process of the semiconductor device continued from FIG. 31;

FIG. 33 is a cross-sectional view illustrating the manufacturing process of the semiconductor device continued from FIG. 32;

FIG. 34 is a cross-sectional view illustrating the manufacturing process of the semiconductor device continued from FIG. 33;

FIG. 35 is a cross-sectional view illustrating the manufacturing process of the semiconductor device continued from FIG. 34;

FIG. 36 is a cross-sectional view illustrating the manufacturing process of the semiconductor device continued from FIG. 35;

FIG. 37 is a cross-sectional view illustrating the manufacturing process of the semiconductor device continued from FIG. 36;

FIG. 38 is a cross-sectional view illustrating the manufacturing process of the semiconductor device continued from FIG. 37;

FIG. 39 is a cross-sectional view illustrating the manufacturing process of the semiconductor device continued from FIG. 38;

FIG. 40 is a cross-sectional view illustrating the manufacturing process of the semiconductor device continued from FIG. 39;

FIG. 41 is a cross-sectional view illustrating the manufacturing process of the semiconductor device continued from FIG. 40;

FIG. 42 is a cross-sectional view illustrating the manufacturing process of the semiconductor device continued from FIG. 41;

FIG. 43 is a cross-sectional view illustrating the manufacturing process of the semiconductor device continued from FIG. 42;

FIG. 44 is a cross-sectional view illustrating the manufacturing process of the semiconductor device continued from FIG. 43;

FIG. 45 is a cross-sectional view illustrating the manufacturing process of the semiconductor device continued from FIG. 44;

FIG. 46 is a cross-sectional view illustrating the manufacturing process of the semiconductor device continued from FIG. 45;

FIG. 47 is a cross-sectional view illustrating the manufacturing process of the semiconductor device continued from FIG. 46;

FIG. 48 is a cross-sectional view illustrating the manufacturing process of the semiconductor device continued from FIG. 47;

FIG. 49 is a cross-sectional view illustrating a configuration example of a package according to a second embodiment;

FIG. 50 is a cross-sectional view illustrating a manufacturing process of a semiconductor device according to the second embodiment;

FIG. 51 is a cross-sectional view illustrating the manufacturing process of the semiconductor device continued from FIG. 50;

FIG. 52 is a cross-sectional view illustrating the manufacturing process of the semiconductor device continued from FIG. 51;

FIG. 53 is a cross-sectional view illustrating the manufacturing process of the semiconductor device continued from FIG. 52;

FIG. 54 is a cross-sectional view illustrating the manufacturing process of the semiconductor device continued from FIG. 53;

FIG. 55 is a cross-sectional view illustrating the manufacturing process of the semiconductor device continued from FIG. 54;

FIG. 56 is a cross-sectional view illustrating the manufacturing process of the semiconductor device continued from FIG. 55;

FIG. 57 is a cross-sectional view illustrating the manufacturing process of the semiconductor device continued from FIG. 56;

FIG. 58 is a cross-sectional view illustrating the manufacturing process of the semiconductor device continued from FIG. 57;

FIG. 59 is a cross-sectional view illustrating the manufacturing process of the semiconductor device continued from FIG. 58;

FIG. 60 is a cross-sectional view illustrating a configuration example of a package according to a third embodiment;

FIG. 61 is a plan view illustrating a lead frame;

FIG. 62 is a cross-sectional view illustrating a manufacturing process of a semiconductor device according to the third embodiment;

FIG. 63 is a cross-sectional view illustrating the manufacturing process of the semiconductor device continued from FIG. 62;

FIG. 64 is a cross-sectional view illustrating the manufacturing process of the semiconductor device continued from FIG. 63;

FIG. 65 is a cross-sectional view illustrating the manufacturing process of the semiconductor device continued from FIG. 64;

FIG. 66 is a cross-sectional view illustrating a configuration (device structure) of a semiconductor device according to a fourth embodiment;

FIG. 67 is a graph illustrating a relationship of a distance from a surface of a semiconductor substrate and shear stress;

FIG. 68 is a cross-sectional view illustrating a configuration (device structure) of a semiconductor device according to a fifth embodiment;

FIG. 69 is a cross-sectional view illustrating a manufacturing process of a semiconductor device according to the fifth embodiment;

FIG. 70 is a cross-sectional view illustrating the manufacturing process of the semiconductor device continued from FIG. 69;

FIG. 71 is a cross-sectional view illustrating the manufacturing process of the semiconductor device continued from FIG. 70; and

FIG. 72 is a cross-sectional view illustrating the manufacturing process of the semiconductor device continued from FIG. 71.

### BEST MODE FOR CARRYING OUT THE INVENTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Also, components having the same function are denoted by the same reference symbols throughout the drawings for describing the embodiment, and the repetitive description thereof will be omitted. Also, in some drawings used in the embodiments, hatching is used even in a plan view so as to make the drawings easy to see.

### First Embodiment

A semiconductor device is formed of: a semiconductor chip to which semiconductor elements such as a MISFET and a multilayer wiring; and a package formed to cover the semiconductor chip. The package has functions of: (1) electrically connecting the semiconductor elements formed to the semiconductor chip and external circuits; and (2) protecting the semiconductor chip from external environment such as humidity and temperature and preventing damage due to vibration and shock and characteristic degradation of the semiconductor chip. Further, the package also has functions of: (3) facilitating handling of the semiconductor chip; and (4) diffusing heat generated from the semiconductor chip during operation to bring out functions of semiconductor elements to the maximum. There are various types of packages having such functions. Hereinafter, a configuration example of the package will be described.

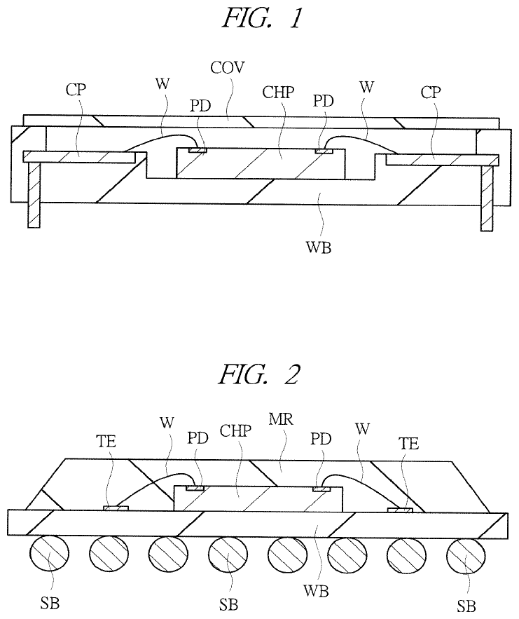

FIG. 1 is a cross-sectional view illustrating a configuration example of a package (package body). In FIG. 1, a groove is formed at a canter portion of a wiring board WB and a semiconductor chip CHP is arranged in the groove. Further, a wiring CP formed of a conductive film is formed to the wiring board WB, and the wiring CP and a pad PD formed to the semiconductor chip CHP are electrically connected by a wire W. The wiring CP formed to the wiring board WB is led out to an external portion of the wiring board WB so that the semiconductor chip and an external circuit are electrically connected via the wiring CP formed to the wiring board WB. The semiconductor chip CHP is sealed by the wiring board WB and a cover (lid) COV to be protected from external environment such as humidity and temperature.

As the package is used in various temperature conditions, the package is required to operate normally accommodating a wide range of temperature change. Therefore, the semiconductor chip is subjected to a temperature cycle test after being packaged. Here, in the case of the package illustrated in FIG. 1, as the semiconductor chip CHP is not sealed with a resin, there is no stress generated to the semiconductor chip CHP even when a wide range of temperature change is applied to the package. That is, in the package illustrated in FIG. 1, the semiconductor chip CHP is not covered by a resin. Therefore, it is considered that stress posed by differences in coefficient of thermal expansion and Young's modulus is not applied to the semiconductor chip CHP. Accordingly, in the package illustrated in FIG. 1, it is considered that there is not much problem of stress generated to the semiconductor chip CHP. “Stress” mentioned herein includes compressive stress, tensile stress, etc.

Next, a configuration example of a package in which stress applied to the semiconductor chip is problematic will be described. FIG. 2 is a cross-sectional view illustrating another configuration example of the package. In FIG. 2, on the wiring board WB, the semiconductor chip CHP is mounted. The pad PD formed to the semiconductor chip CHP is electrically connected to a terminal TW formed to the wiring board WB by the wire W. On a back surface of the wiring board WB, a solder ball SB which functions as an external connection terminal is formed. In the wiring board WB, the terminal TE formed to a main surface of the wiring board WB and the solder ball SB formed to the back surface of the wiring board WB are electrically connected via a wiring (not illustrated) formed inside the wiring board WB. Therefore, the pad PD formed to the semiconductor chip CHP is electrically connected to the solder ball SB to be an external connection terminal via the wire W and the terminal TE. That is, in the package illustrated in FIG. 2, the semiconductor chip CHP and an external circuit can be electrically connected via the solder ball SB.

Further, in the package illustrated in FIG. 2, a resin MR is formed on the main surface side of the wiring board WB. With the resin MR, the semiconductor chip CHP and the wire W formed on the main surface of the wiring board WB are sealed. That is, in the package illustrated in FIG. 2, the resin MR is formed to cover the semiconductor chip CHP, so that the semiconductor chip CHP is protected by the resin MR from external environment such as humidity and temperature.

In this manner, in the package illustrated in FIG. 2, the semiconductor chip CHP is sealed with the resin MR; therefore, stress is applied to the semiconductor chip CHP due to a temperature change in a temperature cycle test. That is, when a wide range of temperature change by the temperature cycle test is applied to the package, stress is generated to the semiconductor chip CHP due to differences in coefficient of thermal expansion and Young's modulus between the semiconductor chip CHP and the resin MR. When the stress is generated to the semiconductor chip CHP, a problem of film exfoliation is feared to occur in the multilayer wiring formed in the semiconductor chip CHP.

A preferred aim of the first embodiment is to provide technique of suppressing film exfoliation between interlayer insulating films composing the multilayer wiring occurring due to stress applied to the semiconductor chip CHP. Therefore, the package in regard to the first embodiment has a structure in which a part of the semiconductor chip CHP is contacted with the resin MR. In such a package, it is considered that stress is prone to be generated between the semiconductor chip CHP and the resin MR due to differences in coefficient of thermal expansion and Young's modulus. Specifically, the package in regard to the first embodiment is not the package illustrated in FIG. 1 but the package as illustrated in FIG. 2.

Hereinafter, on the premise of a package in which at least a part of the semiconductor chip CHP is sealed with the resin MR, a technical idea capable of suppressing exfoliation between interlayer insulating films formed in the semiconductor chip CHP posed by stress applied to the semiconductor chip CHP will be described. In the first embodiment, to suppress exfoliation between interlayer insulating films caused by stress applied to the semiconductor chip CHP, there is a device provided to the interlayer insulating film formed in the semiconductor chip CHP. That is, the technical idea according to the first embodiment is, instead of reducing stress generated between the semiconductor chip CHP and the resin MR, providing a devise to the configuration of the interlayer insulating films formed inside the semiconductor chip CHP on the premise of generation of the stress.

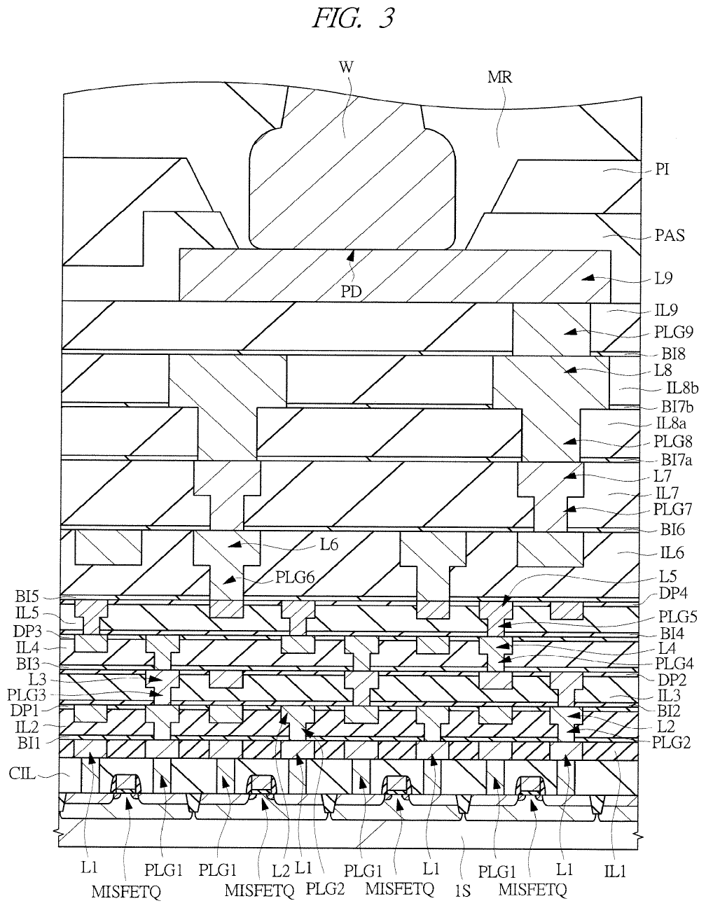

First, the device structure formed to the semiconductor chip CHP will be described. FIG. 3 is a cross-sectional view illustrating a device structure according to the first embodiment. In FIG. 3, a plurality of MISFETQs are formed on a semiconductor substrate 1S formed of single crystal silicon. The plurality of MISFETQs are formed in active regions isolated by device isolation regions, and has, for example, the following configuration. More specifically, a well is formed in the active region isolated by the device isolation regions, and the MISFETQ is formed on the well. The MISFETQ has a gate insulating film formed of, for example, a silicon oxide film on a main surface of the semiconductor substrate 1S, and a gate electrode formed of a stacked film of a polysilicon film and a silicide film (nickel silicide film or the like) provided on the polysilicon film on the gate insulating film. On both sidewalls of the gate electrode, sidewalls formed of, for example, silicon oxide films are formed, and shallow impurity diffusion regions being aligned with the gate electrode are formed in the semiconductor substrate under the sidewalls. And, deed impurity diffusion regions being aligned with the sidewalls are formed on the outside of the shallow impurity diffusion regions. One pair of the shallow impurity diffusion regions and one pair of the deep impurity diffusion regions form a source region and a drain region of the MISFETQ, respectively. In the above-described manner, the MISFETQs are formed on the semiconductor substrate 1S.

Next, as illustrated in FIG. 3, a contact interlayer insulating film CIL is formed on the semiconductor substrate 1S to which the MISFETQ is formed. The contact interlayer insulating film CIL is formed of a stacked film of: an ozone TEOS film formed through, for example, thermal CVD using ozone and TEOS (tetra ethyl ortho silicate) as source materials; and a plasma TEOS film, which is formed on the ozone TEOS film and formed through plasma CVS using TEOS as a source material. And, a plug PLG1 penetrating through the contact interlayer insulating film CIL and reaching the source region and drain region of the MISFETQ is formed. The plug PLG1 is formed by burying, for example, a barrier conductive film formed of a titanium/titanium-nitride film (hereinafter, “titanium/titanium-nitride film” indicates a film formed of titanium and titanium nitride provided on the titanium) and a tungsten film formed on the barrier conductive film. The titanium/titanium-nitride film is provided for preventing tungsten forming the tungsten film from diffusing into silicon, and it prevents damage of fluoride attack to the contact interlayer insulating film CIL and the semiconductor substrate 1S in CVD in which WF6 (tungsten fluoride) is subjected to reduction processing upon forming the tungsten film. Note that, the contact interlayer insulating film CIL may be formed of either of silicon oxide film (SiO₂ film), SiOF film, or silicon nitride film.

Next, a first layer wiring L1 is formed on the contact interlayer insulating film CIL. More specifically, the first layer wiring L1 is formed to be buried in an interlayer insulating film IL1 formed on the contact interlayer insulating film CIL to which the plug PLG1 is formed. That is, the first layer wiring L1 is formed by burying a film (hereinafter, cited as a copper film) mainly containing copper to a wiring trench from which the plug PLG1 is exposed at a bottom portion, the wiring trench penetrating through the interlayer insulating film IL. The interlayer insulating film IL1 is formed of, for example, a SiOC film, a HSQ (hydrogen silsesquioxane: formed by an application process; a silicon oxide film having Si—H bonds, or hydrogen-containing silsesquioxane) film, or a MSQ (methyl silsesquioxane: formed by an application process; a silicon oxide film having Si—C bonds, or carbon-containing silsesquioxane) film. Here, the first layer wiring L1 will be sometimes called a first fine layer in the present Specification.

Subsequently, a second layer wiring L2 is formed on the interlayer insulating film IL1 to which the first layer wiring L1 is formed. More specifically, a barrier insulating film BI1 is formed on the interlayer insulating film IL1 to which the first layer wiring L1 is formed, and an interlayer insulating film IL2 is formed on the barrier insulating film BI1. And, a damage protection film DP1 is formed on the interlayer insulating film IL2. The barrier insulating film BI1 is formed of any one of, for example, a stacked film of a SiCN film and a SiCO film provided on the SiCN film, a SiC film, or a SiN film, and the interlayer insulating film IL2 is formed of, for example, a SiOC film having a void, a HSQ film having a void, or a MSQ film having a void. A size (diameter) of the void is, for example, about lnm. The damage protection film DP1 is formed of, for example, a SiOC film. The second layer wiring L2 and a plug

PLG2 are formed to be buried in the barrier insulating film BI1, the second layer wiring L2 and the damage protection film DP1. The second layer wiring L2 and the plug PLG2 are formed of, for example, copper films. Note that, the stacked film formed of a SiCN film and a SiCO film may be a stacked film formed of a first film selected from a SiCN film or a SiN film and a second film selected from a SiCO film, a silicon oxide film, or a TEOS film and provided on the first film. The same goes to a stacked film formed on a SiCN film and SiCO film described below.

Then, in the same manner as the second layer wiring L2, a third layer wiring L3 to a fifth layer wiring L5 are formed. More specifically, a barrier insulating film BI2 is formed on the damage protection film DP1, and an interlayer insulating film IL2 is formed on the barrier insulating film BI2. Then, a damage protection film DP2 is formed on the interlayer insulating film IL3. The barrier insulating film BI2 is formed of any one of, for example, a stacked film of a SiCN film and a SiCO film provided on the SiCN film, a SiC film, or a SiN film, and the interlayer insulating film IL3 is formed of, for example, a SiOC film having a void, a HSQ film having a void, or a MSQ film having a void. The damage protection film DP2 is formed of, for example, a SiOC film. The third layer wiring L3 and a plug PLG3 are formed to be buried in the barrier insulating film BI2, the interlayer insulating film IL3 and the damage protection film DP2. The third layer wiring L3 and the plug PLG3 are formed of, for example, copper films.

Next, a barrier insulating film BI3 is formed on the damage protection film DP2 and an interlayer insulating film IL4 is formed on the barrier insulating film BI3. Then, a damage protection film DP3 is formed on the interlayer insulating film IL4. The barrier insulating film BI3 is formed of any one of, for example, a stacked film of a SiCN film and a SiCO film provided on the SiCN film, a SiC film, or a SiN film, and the interlayer insulating film IL4 is formed of, for example, a SiOC film having a void, a HSQ film having a void, or a MSQ film having a void. The damage protection film DP3 is formed of, for example, a SiOC film. A fourth layer wiring L4 and a plug PLG4 are formed to be buried in the barrier insulating film BI3, the interlayer insulating film IL4 and the damage protection film DP3. The fourth layer wiring L4 and the plug PLG4 are formed of, for example, copper films.

Further, a barrier insulating film BI4 is formed on the damage protection film DP3 and an interlayer insulating film IL5 is formed on the barrier insulating film BI4. Then, a damage protection film DP4 is formed on the interlayer insulating film IL5. The barrier insulating film BI4 is formed of any one of, for example, a stacked film of a SiCN film and a SiCO film provided on the SiCN film, a SiC film, or a SiN film, and the interlayer insulating film IL5 is formed of, for example, a SiOC film having a void, a HSQ film having a void, or a MSQ film having a void. The damage protection film DP4 is formed of, for example, a SiOC film. A fifth layer wiring L5 and a plug PLG5 are formed to be buried in the barrier insulating film BI4, the interlayer insulating film IL5 and the damage protection film DP4. The fifth layer wiring L5 and the plug PLG5 are formed of, for example, copper films. Herein, the second layer wiring L2 to the fifth layer wiring L5 will be collectively called as a second fine layer in the present Specification.

Subsequently, a barrier insulating film BI5 is formed on the damage protection film DP4 and an interlayer insulating film IL6 is formed on the barrier insulating film BI5. The barrier insulating film BI5 is formed of any one of, for example, a stacked film of a SiCN film and a SiCO film provided on the SiCN film, a SiC film, or a SiN film, and the interlayer insulating film IL6 is formed of, for example, a SiOC film, a HSQ film, or a MSQ film. A sixth layer wiring L6 and a plug PLG6 are formed to be buried in the barrier insulating film BI5 and the interlayer insulating film IL6. The sixth layer wiring L6 and the plug PLG6 are formed of, for example, copper films.

Next, a barrier insulating film BI6 is formed on the interlayer insulating film IL6 and an interlayer insulating film IL7 is formed on the barrier insulating film BI6. The barrier insulating film BI6 is formed of any one of, for example, a stacked film of a SiCN film and a SiCO film provided on the SiCN film, a SiC film, or a SiN film, and the interlayer insulating film IL7 is formed of, for example, a SiOC film, a HSQ film, or a MSQ film. A seventh layer wiring L7 and a plug PLG7 are formed to be buried in the barrier insulating film BI6 and the interlayer insulating film IL7. The sixth layer wiring L7 and the plug PLG7 are formed of, for example, copper films. Herein, the sixth layer wiring L6 and the seventh layer wiring L7 will be collectively called as a semi global layer in the present Specification.

Further, a barrier insulating film BI7a is formed on the interlayer insulating film IL7, and an interlayer insulating film IL8a is formed on the barrier insulating film BI7a. Then, an etching stop insulating film BI7b is formed on the interlayer insulating film IL8a, and an interlayer insulating film IL8b is formed on the etching stop insulating film BI7b. The barrier insulating film BI7a is formed of any one of, for example, a stacked film of a SiCN film and a SiCO film, a SiC film, or a SiN film; the etching stop insulating film BI7b is formed of any one of, for example, a SiCN film, SiC film, or a SiN film; and the interlayer insulating film IL8a and interlayer insulating film IL8b are each formed of, for example, a silicon oxide film (SiO₂ film), a SiOF film, and/or a TEOS film. A plug PLG8 is formed to be buried in the barrier insulating film BI7a and the interlayer insulating film IL8a, and an eighth layer wiring L8 is formed to be buried in the etching stop insulating film BI7b and the interlayer insulating film IL8b. The eighth layer wiring L8 and the plug PLG8 are formed of, for example, copper films. Herein, the eighth layer wiring L8 will be called a global layer in the present Specification.

Subsequently, a barrier insulating film BI8 is formed on the interlayer insulating film IL8b, and interlayer insulating film IL9 is formed on the barrier insulating film BI8. The barrier insulating film BI8 is formed of any one of, for example, a stacked film of a SiCN film and a SiCO film, a SiC film, or a SiN film, and the interlayer insulating film IL9 is formed of, for example, a silicon oxide film (SiO₂ film), a SiOF film, or a TEOS film. A plug PLG9 is formed to be buried in the barrier insulating film BI8 and the interlayer insulating film IL9. Then, a ninth layer wiring L9 is formed on the interlayer insulating film IL9. The plug PLG9 and the ninth layer wiring L9 are formed of, for example, an aluminum film.

A passivation film PAS to be a surface protection film is formed on the ninth layer wiring L9, and a part of the ninth layer wiring L9 is exposed from an opening portion formed to the passivation film PAS. The exposed region of the ninth layer wiring L9 is a pad PD. The passivation film PAS has a function of protecting injection of impurities, and is formed of, for example, a silicon oxide film and a silicon nitride film formed on the silicon oxide film. In addition, a polyimide film PI is formed on the passivation film PAS. The polyimide film PI also has a region opened in the region where the pad PD is formed.

The wire W is connected to the pad PD, and the polyimide film PI including the pad PD to which the wire W is connected is sealed with the resin MR. The device structure illustrated in FIG. 3 is configured in the above-described manner, and an example of the configuration in more details will be described hereinafter.

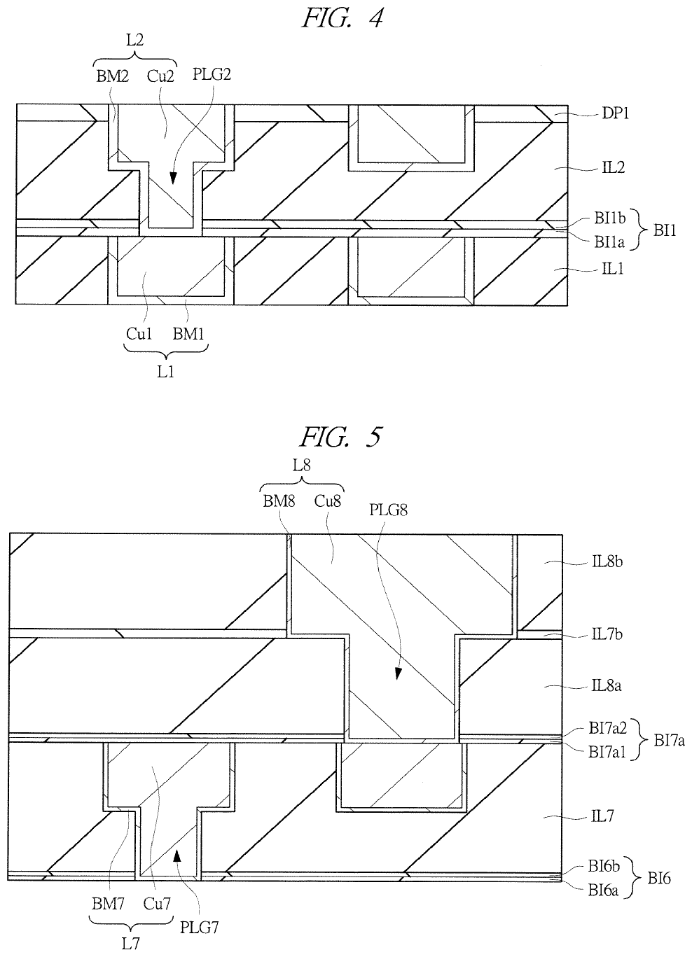

FIG. 4 is a cross-sectional view illustrating the first layer wiring (first fine layer) L1 and the second layer wiring (second fine layer) L2 formed on the first layer wiring L1 in the device configuration illustrated in FIG. 3. In FIG. 4, the first layer wiring L1 is formed in a wiring trench formed on the interlayer insulating film IL1 that is formed of, for example, a SiOC film. More specifically, the first layer wiring L1 is formed of: a barrier conductive film BM1 formed of a tantalum/tantalum-nitride film (hereinafter, the tantalum/tantalum-nitride film indicates a film formed of tantalum nitride and tantalum formed on the tantalum nitride) and a titanium/titanium-nitride film; and a copper film Cu1 formed on the barrier conductive film BM1 to fill in the wiring trench. In this manner, the barrier conductive film BM1 is formed without directly forming a copper film in the wiring trench formed to the interlayer insulating film IL1 so that copper forming the copper film is prevented from diffusing into silicon forming the semiconductor substrate 1S by a thermal processing etc. That is, as a diffusion coefficient of copper atom to silicon is relatively large, copper easily diffuses into silicon. In this case, as semiconductor elements such as MISFETQ etc. are formed to the semiconductor substrate 1S, if copper atoms diffuse to formation regions of the semiconductor elements, characteristics degradation represented by defect in withstand voltage etc. of the semiconductor elements is posed. Therefore, the barrier conductive film BM1 is provided so that copper atoms do not diffuse from the copper film forming the first layer wiring. In other words, the barrier conductive film BM1 is a film having a function of preventing diffusion of copper atoms.

Then, as illustrated in FIG. 4, the barrier insulating film BI1 is formed on the interlayer insulating film IL1 to which the first layer wiring L1 is formed, and the interlayer insulating film IL2 is formed on the barrier insulating film BI1. The damage protection film DP1 is formed on the interlayer insulating film IL2. Here, the barrier insulating film BI1 is formed of a stacked film of a SiCN film BI1a and a SiCO film BI1b, and the interlayer insulating film IL2 is formed of, for example, a SiOC film having a void. Further, the damage protection film DP1 is formed of a SiOC film. The second layer wiring L2 and the plug PLG2 are formed to be buried in the barrier insulating film BI1, the interlayer insulating film IL2, and the damage protection film DP1. The second layer wiring L2 and the plug PLG2 are also formed of a stacked film of a barrier conductive film BM2 and a copper film Cu2.

Next, FIG. 5 is a cross-sectional view illustrating the seventh layer wiring (semi global layer) L7 and the eighth layer wiring (global layer) L8 formed on the seventh layer wiring in the device structure illustrated in FIG. 3. Also in FIG. 5, the barrier insulating film BI6 is formed of a SiCN film BI6a and a SiCO film BI6b, and the barrier insulating film BI7a is formed of a SiCN film BI7a1 and a SiCO film BI7a2. The etching stop insulating film BI7b is formed of a SiCN film. In addition, the seventh layer wiring L7 and the plug PLG7 are formed of a stacked film of a barrier conductive film BM7 and a copper film Cu7, and the eighth layer wiring L8 and the plug PLG8 are also formed of a barrier conductive film BM8 and a copper film Cu8. While the first layer wiring L1, the second layer wiring L2, the seventh layer wiring L7, and the eighth layer wiring L8 have been described in FIGS. 4 and 5, all the copper wirings and plugs forming the first layer wiring L1 to the eighth layer wiring L8 are each formed of a stacked film of a copper film and a barrier conductive film. Moreover, all the barrier insulating films are each formed of a stacked film of a SiCN film and a SiCO film.

As described above, the semiconductor device according to the first embodiment has a structure of a multilayer wiring structure having, for example, the first layer wiring L1 to the ninth layer wiring L9. Here, the interlayer insulating films forming the multilayer wiring structure are formed of different types of films, respectively. This is because required functions of the interlayer insulating films are different, respectively. That is, based on a function required to each interlayer insulating film, a film of a material suitable to each interlayer insulating film is selected. Specifically, based on the property, a material film is used to each interlayer insulating film.

In the following, material films to be used to respective interlayer insulating films will be classified in view of their properties. First, they are classified in view of dielectric constant (relative permittivity) as an example of property. FIG. 6 is a table of classifying material films used in the interlayer insulating films of the first embodiment in view of relative permittivity. As illustrated in FIG. 6, relative permittivities of silicon oxide film (SiO₂ film), silicon nitride film (SiN film), TEOS film, SiOF film, SiCN film, SiC film, and SiCO film are larger than or equal to 3.5, and thus these films are classified into high-dielectric-constant films in the present Specification. On the contrary, relative permittivities of SiOC film, HSQ film, and MSQ film are larger than or equal to 2.8 and smaller than 3.5 and thus these films are classified to middle-dielectric-constant films. In addition, permittivities of SiOC film having a void, HSQ film having a void, and MSQ film having a void are lower than 2.8 and thus are classified into low-dielectric-constant films. As described above, the interlayer insulating films (including the barrier insulating films and damage protection films) used in the first embodiment can be classified into high-dielectric-constant films, middle-dielectric-constant films, and low-dielectric-constant films in view of relative permittivity.

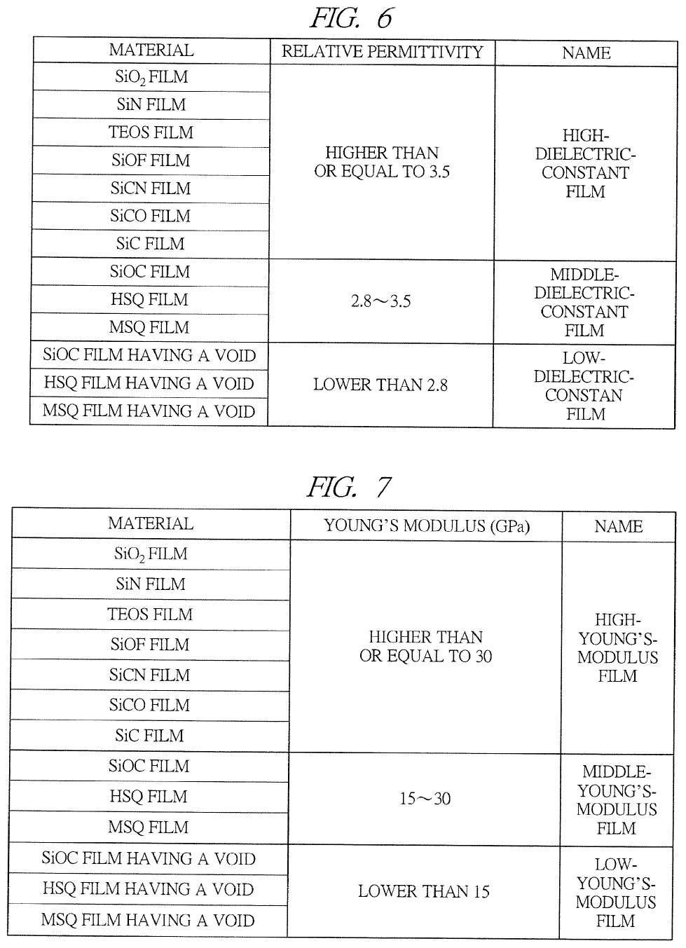

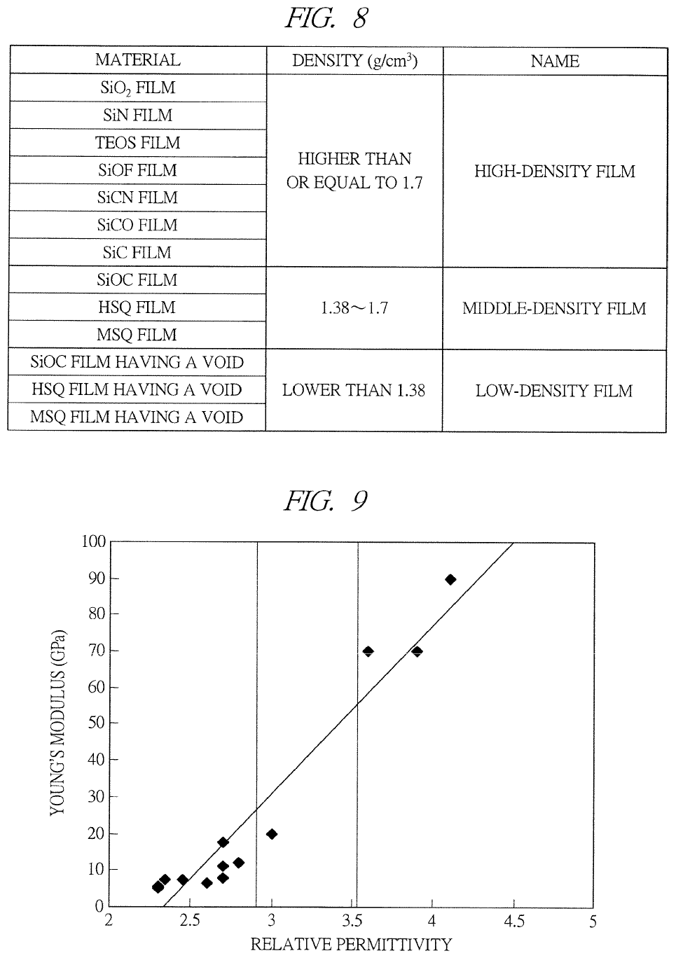

Subsequently, classification is made in view of Young's modulus as another property. FIG. 7 is a graph classifying material films used to the interlayer insulating films of the first embodiment in view of Young's modulus. As illustrated in FIG. 7, Young's modulus of silicon oxide film (SiO₂ film), silicon nitride film (SiN film), TEOS film, SiOF film, SiCN film, SiC film, and SiCO film is larger than or equal to 30 (GPa) and thus these films are classified into high-Young's-modulus films in the present Specification. On the contrary, Young's modulus of SiOC film, HSQ film, and MSQ film is larger than or equal to 15 (GPa) and smaller than 30 (GPa) and thus these films are classified into middle-Young's-modulus films. In addition, Young's modulus of SiOC film having a void, HSQ film having a void, and MSQ film having a void is smaller than 15 (GPa) and thus these films are classified into low-Young's-modulus films. As described above, the interlayer insulating films (including the barrier insulating films and damage protection films) used in the first embodiment can be classified into high-Young's-modulus films, middle-Young's-modulus films, and low-Young's-modulus films in view of Young's modulus.

Moreover, classification is made in view of density as another example of property. FIG. 8 is a graph classifying material films used in the interlayer insulating films of the first embodiment in view of density. As illustrated in FIG. 8, densities of silicon oxide film (SiO₂ film), silicon nitride film (SiN film), TEOS film, SiOF film, SiCN film, SiC film, and SiCO film are larger than or equal to 1.7 (g/cm³) and thus these films are classified into high-density films in the present Specification. On the contrary, densities of SiOC film, HSQ film, and MSQ film are larger than or equal to 1.38 (g/cm³) and smaller than 1.7 (g/cm³) and thus these films are classified into middle-density films. In addition, densities of SiOC film having a void, HSQ film having a void, and MSQ film having a void are smaller than 1.38 (g/cm³) and thus are classified into low-density films. As described above, the interlayer insulating films (including the barrier insulating films and damage protection films) used in the first embodiment can be classified into high-density films, middle-density films, and low-density films in view of density.

In this manner, the materials films forming the interlayer insulating films can be classified in view of relative permittivity, Young's modulus, and density, and there are mutual correlations among the above-described properties (relative permittivity, Young's modulus, and density) of the material films. That is, silicon oxide film (SiO₂ film), silicon nitride film (SiN film), TEOS film, SiOF film, SiCN film, SiC film, and SiCO film are classified into high-dielectric-constant films in view of relative permittivity and also classified into high-Young's modulus films in view of Young's modulus and high-density films in view of density at the same time. In other words, when using the classifications of the present Specification, the films of high-dielectric-constant films among the material films forming the interlayer insulating films are also high-Young's-modulus films and also high-density films. In the same manner, SiOC film, HSQ film and MSQ film are middle-dielectric-constant films and are also middle-Young's-modulus films and also middle-density films. Moreover, SiOC film having a void, HSQ film having a void, and MSQ film having a void are low-dielectric-constant films, and are also low-Young's-modulus films and also low-density films. In other words, in consideration of films used in the interlayer insulating films, it can be considered such that films having high relative permittivity also have high Young's modulus and also high density. On the contrary, films having low relative permittivity have characteristics of low Young's modulus and also low density.

As described above, regarding the material films forming the interlayer insulating films (including the barrier insulating films and damage protection films), existence of correlation among relative permittivity, Young's modulus, and density will be explained with reference to graphs.

FIG. 9 is a graph illustrating a relationship of relative permittivity and Young's modulus regarding material films forming the interlayer insulating films. In FIG. 9, the horizontal axis is for relative permittivity, and the vertical axis is for Young's modulus (GPa). The plot illustrated in FIG. 9 is in a substantially proportional relation. That is, regarding the material films forming the interlayer insulating films, the larger the relative permittivity, the larger the Young's modulus, and, in reverse, the smaller the relative permittivity, the smaller the Young's modulus. Accordingly, in FIG. 9, films having values of relative permittivity in a region smaller than 2.8 are regarded as low-dielectric-constant films, and films having values of relative permittivity in a region larger than or equal to 2.8 and smaller than 3.5 are regarded as middle-dielectric-constant films. Moreover, films having values of relative permittivity larger than or equal to 3.5 are regarded as high-dielectric-constant films.

Subsequently, FIG. 10 also illustrates a graph illustrating a relationship of relative permittivity and Young's modulus regarding the material films forming the interlayer insulating films. In FIG. 10, the horizontal axis is for relative permittivity, and the vertical axis is for Young's modulus (GPa). The plot illustrated in FIG. 10 is in a substantially proportional relationship. That is, regarding material films forming the interlayer insulating films, the larger the relative permittivity, the larger the Young's modulus, and, in reverse, the smaller the relative permittivity, the smaller the Young's modulus. Here, in FIG. 10, focusing on Young's modulus, films having values of Young's modulus smaller than 15 (GPa) are regarded as low-Young's modulus films, and films having values of Young's modulus larger than or equal to 15 (GPa) and smaller than 30 (GPa) are regarded as middle-Young's-modulus films. Moreover, films having values of Young's modulus larger than or equal to 30 (GPa) are regarded as high-Young's-modulus films.

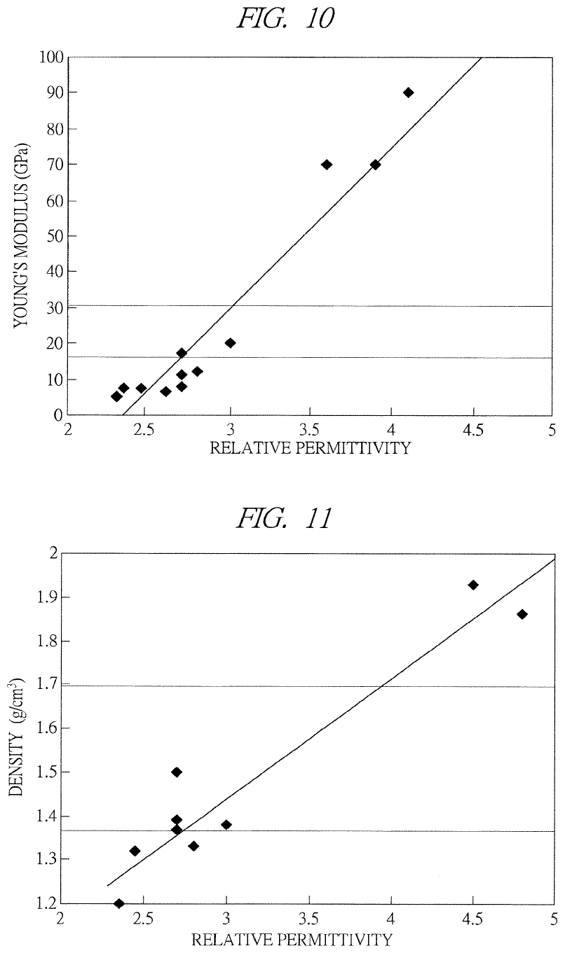

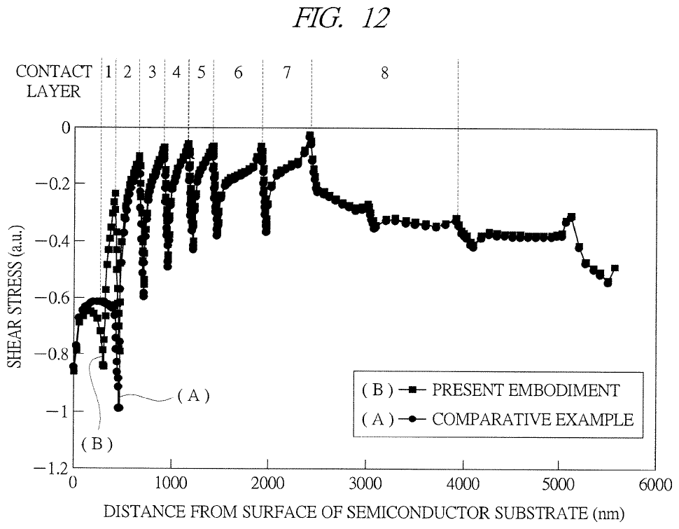

Next, FIG. 11 is a graph illustrating a relationship of relative permittivity and density regarding material films forming interlayer insulating films. In FIG. 11, the horizontal axis is for relative permittivity, and the vertical axis is for density (g/cm³). The plot illustrated in FIG. 11 is in a substantially proportional relationship. That is, regarding the material films forming the interlayer insulating films, the larger the relative permittivity, the larger the density, and, in reverse, the smaller the relative permittivity the smaller the density. Accordingly, in FIG. 11, density is focused, and films having values of density in a region smaller than 1.38 (g/cm³) are regarded as low-density films, and films having values of density in a region larger than or equal to 1.38 (g/cm³) and smaller than 1.7 g/cm³) are regarded as middle-density films. Moreover, films having values of density in a region larger than or equal to 1.7 (g/cm³) are regarded as high-density films.

To summarize the foregoing, relative permittivities, densities, and Young's modulus of SiO₂ film, SiN film, TEOS film, SiOF film, SiCN film, SiCO film, SiC film, SiOC film, HSQ film, MSQ film, SiOC film having a void, HSQ film having a void, and MSQ film having a void are as follows. More specifically, respective dielectric constant, density, and Young's modulus are: SiO₂ film (dielectric constant: 3.8, Young's modulus: 70 GPa, density: 2.2 g/cm³); SiN film (dielectric constant: 6.5, Young's modulus: 185 GPa, density: 3.4 g/cm³); TEOS film (dielectric constant: 4.1, Young's modulus: 90 GPa, density: 2.2 g/cm³); SiOF film (dielectric constant: 3.4 to 3.6, Young's modulus: 50 to 60 GPa, density: 2.2 g/cm³); SiCN film (dielectric constant: 4.8, Young's modulus: 116 GPa, density: 1.86 g/cm³); SiCO film (dielectric constant: 4.5, Young's modulus: 110 GPa, density: 1.93 g/cm³); SiC film (dielectric constant: 3.5, Young's modulus: 40 GPa, density: 3.3 g/cm³); SiOC film (dielectric constant: 2.7 to 2.9, Young's modulus: 15 to 20 GPa, density: 1.38 to 1.5 g/cm³); HSQ film (dielectric constant: 2.8 to 3, Young's modulus: 8 to 10 GPa); MSQ film (dielectric constant: 2.7 to 2.9, Young's modulus: 15 to 20 GPa, density: 1.4 to 1.6 g/cm³); SiOC film having a void (dielectric constant: 2.7, Young's modulus: 11 GPa, density: 1.37 g/cm³); HSQ film having a void (dielectric constant: 2.0 to 2.4, Young's modulus: 6 to 8); and MSQ film (dielectric constant: 2.2 to 2.4, Young's modulus: 4 to 6 GPa, density: 1.2 g/cm³).

In this manner, in the first embodiment, material films used to respective interlayer insulating films are classified in view of property. In the following, also in consideration of property of the classified material films, functions of respective interlayer insulating films will be described with reference to FIG. 3.

In FIG. 3, first, the contact interlayer insulating film CIL is formed of, for example, as stacked film of: an ozone TEOS film formed through thermal CVD using ozone and TEOS as source materials; and a plasma TEOS film formed through plasma CVD using TEOS as a source material and provided on the ozone TEOS film. A reason of forming the contact interlayer insulating film CIL of a TEOS film is that the TEOS film has a good coatability to a base unevenness. The base for forming the contact interlayer insulating film CIL is in a state having concavity and convexity as the MISFETQs are formed to the semiconductor substrate 1S. That is, as the MISFETQs are formed to the semiconductor substrate 1S, gate electrodes are formed to the surface of the semiconductor substrate 1S and thus the base has concavity and convexity. Therefore, if a film does not have a good coatability to the unevenness with concavity and convexity, it is impossible to fill in minute concavity and convexity, and it becomes a cause of generation of voids. Therefore, the TEOS film is used for the contact interlayer insulating film CIL. Because, in the TEOS film containing TEOS as its source material, an intermediate is created before the TEOS that is a source material becomes a silicon oxide film and it becomes easier to move on the deposition surface, thereby improving the coatability to the base unevenness. In other words, as the contact interlayer insulating film CIL is formed of a TEOS film, it can be said that the contact interlayer insulating film CIL is formed of a high-dielectric-constant film, a high-Young's-modulus film, or a high-density film.

Next, the interlayer insulating films IL2 to IL5 forming the second fine layer (the second layer wiring L2 to the fifth layer wiring L5) will be described. The interlayer insulating films IL2 to IL5 are formed of, for example, a SiOC film having a void, a HSQ film having a void, or a MSQ film having a void. Therefore, according to the classification of the first embodiment, the interlayer insulating films IL2 to IL5 are formed of low-dielectric-constant films. A reason of forming the interlayer insulating films IL2 to IL5 with low-dielectric-constant films in this manner will be explained below.

That is, the second layer wiring L2 to the fifth layer wiring L5 forming the second fine layer are wiring layers subjected to miniaturization in the multilayer wiring. Therefore, wiring interval of the second fine layer is narrow, and thus it is necessary to reduce parasitic capacitance between wires. Accordingly, in the second fine layer having narrow wiring interval, the interlayer insulating films IL2 to IL5 are formed of low-dielectric-constant films. By forming the interlayer insulating films IL2 to IL5 with low-dielectric-constant films, parasitic capacitance between wires can be reduced.

Further, the second layer wiring L2 to the fifth layer wiring L5 forming the second fine layer are formed of copper wirings. This is because it suppresses an increase of wiring resistance along with miniaturization of the second layer wiring L2 to the fifth layer wiring L5 is suppressed. That is, by using copper wirings having smaller resistance than aluminum wirings for the second layer wiring L2 to the fifth layer wiring L5, it is possible to make wiring resistance small. In this manner, in the second fine layer in which miniaturization is advanced, as well as wiring resistance is reduced by using copper wirings, parasitic capacitance between wirings is reduced by forming the interlayer insulating films IL2 to IL5 with low-dielectric-constant films. According to the synergetic effect, it is possible to suppress delay of electric signals transmitted in the wirings.

As copper wirings are used for the second layer wiring L2 to the fifth layer wiring L5 in the second fine layer here, it is necessary to prevent diffusion of copper atoms. Therefore, in the second fine layer, the copper film is formed in the wiring trench interposing a barrier conductive film, thereby forming the copper wiring. That is, in the second fine layer, instead of forming the copper film directly in the wiring trench, a barrier conductive film is formed on side surfaces and a bottom surface of the wiring trench and a copper film is formed on the barrier conductive film. In this manner, copper atoms forming the copper film are prevented from diffusing by the barrier conductive film. Here, the barrier conductive film is formed only to the side surfaces and bottom surface of the wiring trench. Therefore, there is a possibility that copper atoms diffuse from an upper portion of the wiring trench. A reason of not forming a barrier conductive film to the upper portion of the wiring trench is that the barrier conductive film will be formed on a plurality of wiring trenches to form the barrier conductive film to the upper portion of the wiring trench. This means that copper wirings formed to a plurality of wiring trenches are conducted through the barrier conductive film formed to the upper portions of the plurality of wiring trenches and it poses mutual short-circuiting among different copper wirings. Therefore, the barrier conductive film cannot be formed to the upper portion of the copper wiring.

However, it is necessary to prevent diffusion of copper atoms from the upper portion of the wiring trench. Therefore, the barrier insulating films BI1 to BI4, which are insulating films and also have a function of preventing diffusion of copper atoms, are formed to the upper portion of the copper wiring. The barrier insulating films BI1 to BI4 are formed of, for example, a stacked film of a SiCN film and a SiCO film. In this manner, diffusion of copper atoms from the copper wiring can be prevented. That is, diffusion of copper atoms from the side surfaces and bottom surface of the wiring trench in which the copper wiring is formed is prevented by the barrier conductive film and diffusion of copper atoms from the upper portion of the wiring trench is prevented by the barrier insulating film.

Therefore, in the second fine layer (the second layer wiring L2 to the fifth layer wiring L5), the barrier insulating films BI1 to BI4 are formed immediately above the copper wiring, and the interlayer insulating films IL2 to IL5 formed of low-dielectric-constant films are formed on the barrier insulating films BI1 to BI4. As the barrier insulating films BI1 to BI4 are formed of a SiCN film and a SiCO film, the barrier insulating films BI1 to BI4 are formed of high-dielectric-constant film, high-Young's-modulus films, in other words, high-density films.

Further, in the second fine layer, the interlayer insulating films IL2 to IL5 are formed with low-dielectric-constant films. These low-dielectric-constant films can be called, in other words, low-Young's-modulus films. The low-Young's-modulus films mean films having low Young's modulus, and to have low Young's modulus means physically having weak mechanical strength. Therefore, forming the interlayer insulating films IL2 to IL5 with low-dielectric-constant films is preferable in view of reducing parasitic capacitance between wirings, but on the other hand, it is not preferable in view of mechanical strength due to usage of the low-Young's-module film. Therefore, to strengthen the mechanical strength, the damage protection films DP1 to DP4 are formed to respective upper portions of the interlayer insulating films IL2 to IL5 formed of low-dielectric-constant films. The damage protection films DP1 to DP4 are middle-Young's-modulus films formed of, for example, SiOC films. Therefore, the mechanical strength is higher than that of the interlayer insulating films IL2 to IL5, which are low-Young's-modulus films. In this manner, the surfaces of the interlayer insulating films IL2 to IL5 having weak mechanical strength can be strengthened by the damage protection films DP1 to DP4. Note that, the damage protection films DP1 to DP4 are middle-dielectric-constant films, and thus have higher dielectric constant than the low-dielectric-constant film forming the interlayer insulating films IL2 to IL5. Therefore, when the thicknesses of the damage protection films DP1 to DP4 are too large, the effect of using low-dielectric-constant films as the interlayer insulating films IL2 to IL5 becomes less effective; therefore, it is preferable to make the thicknesses of the damage protection films as thin as possible on the premise of strengthening the mechanical strength of the interlayer insulating films IL2 to IL5.

As described in the foregoing, in the second fine layer, as a configuration of a plurality of wiring layers, the barrier insulating films BI1 to BI4 are formed immediately above the copper wirings, and the interlayer insulating films IL2 to IL5 are formed on the barrier insulating films BI1 to BI4. Then, the damage protection films DP1 to DP4 are formed to surfaces of the interlayer insulating films IL2 to IL5, respectively. That is, in the second fine layer, aiming at reducing parasitic capacitance between wirings, low-dielectric-constant films are used as the interlayer insulating films IL2 to IL5, and also, aiming at preventing diffusion of copper atoms from the copper wirings, the barrier insulating films BI1 to BI4 are used. Moreover, to strengthen the mechanical strength of the interlayer insulating films IL2 to IL5 which are low-Young's-modulus films, the damage protection films DP1 to DP4 are provided to surfaces of the interlayer insulating films IL2 to IL5, respectively.

Subsequently, the interlayer insulating films IL6 to IL7 forming the semi global layer (the sixth layer wiring L6 to the seventh layer wiring L7) will be described. The interlayer insulating films IL6 to IL7 are formed of, for example, SiOC films. That is, the interlayer insulating films IL6 to IL7 forming the semi global layer are formed of middle-dielectric-constant films, middle-Young's-modulus films, in other words, middle-density films. A reason of this is as follows.

For example, in view of reducing parasitic capacitance between wirings, low-dielectric-constant films are used also in the semi global layer. However, the semi global layer is a layer provided to an upper layer of the second fine layer, and is a layer closer to the pad PD than to the second fine layer. Therefore, for example, when a probe needle (probe) is pushed onto the pad PD during an electric characteristics inspection, probing damage is prone to be applied to the semi global layer. Further, in an assembly process such as a dicing process to singulate the semiconductor substrate 1S to a plurality of semiconductor chips, the semi global layer is prone to be damaged more than the second fine layer provided at its lower layer. From this reason, to give damage resistance to various damages as mentioned above, the semi global layer is required to have mechanical strength to some extent. Therefore, if the semi global layer is formed with low-Young's-modulus films (low-dielectric-constant films), it may be broken as it cannot keep the mechanical strength. That is, it is preferable to use films having high mechanical strength as the semi global layer. While the wiring interval of the wiring formed in the semi global layer is larger than that of the second fine layer, the distance requires a reduction in parasitic capacitance. In other words, while the mechanical strength can be heightened when the interlayer insulating films 116 to IL7 forming the semi global layer are formed of high-Young's-modulus films (high-dielectric-constant films), it makes the dielectric constant larger, resulting in an increase in parasitic capacitance between wirings. That is, in the semi global layer, it is required to achieve both ensuring the mechanical strength and reducing parasitic capacitance between wirings.

Therefore, middle-Young's-modulus films (middle-dielectric-constant films) are used as the interlayer insulating films IL6 to IL7 forming the semi global layer. For example, by using middle-dielectric-constant films as the interlayer insulating films IL6 to IL7 forming the semi global layer, the dielectric constant of the interlayer insulating films IL6 to IL7 can be made small to some extent, and also the mechanical strength of the interlayer insulating films IL6 to IL78 can be ensured for some extent.

As the wirings forming the semi global layer are formed of copper wirings, in the same manner as the second fine layer, the barrier insulating films BI5 to BI6, which are insulating films and having function of preventing diffusion of copper atoms, are formed to the upper portions of the copper wirings. The barrier insulating films BI5 to BI6 are formed of, for example, a stacked film of a SiCN film and a SiCO film and thus the barrier insulating films BI5 to BI6 are formed of high-dielectric-constant films (high-Young's-modulus films, high-density films). By the barrier insulating films BI5 to BI6, diffusion of copper atoms from the copper wirings can be prevented.

As described in the foregoing, in the semi global layer, as a configuration among a plurality of wiring layers, first, the barrier insulating films BI5 to BI6 are formed immediately above the copper wirings, and the interlayer insulating films IL6 to IL7 are formed on the barrier insulating films BI5 to BI6. In the semi global layer, aiming at achieving both reducing the parasitic capacitance between wirings and ensuring the mechanical strength, middle-dielectric-constant films are used as the interlayer insulating films IL6 to IL7, and also, aiming at preventing diffusion of copper atoms from the copper wirings, the barrier insulating films BI5 to BI6 are used.

Subsequently, the interlayer insulating films IL8a to IL8b forming the global layer (the eighth layer wiring L8) will be described. The interlayer insulating films IL8a to IL8b are formed of, for example, a silicon oxide film and/or a TEOS film. That is, the interlayer insulating films IL8a to IL8b forming the global layer are formed of high-dielectric-constant films, high-Young's-modulus films, or in other words, high-density films. A reason of this is as follows.

The global layer is provided at an upper layer than the semi global layer, and is a layer provided immediately under the pad PD. Therefore, probing damage is more prone to be applied to the global layer than to the semi global layer provided as a lower layer than the global layer. Further, in an assembly process such as a dicing process of singulating the semiconductor substrate 1S into a plurality of semiconductor chips, the global layer is a layer being prone to be damaged more than the semi global layer provided as a lower layer. Therefore, to give damage resistance to the various damages as mentioned above, the global layer is required to have higher mechanical strength than the semi global layer. From this reason, the global layer is formed of high-Young's-modulus films (high-dielectric-constant films) having high mechanical strength. In this manner, the mechanical strength of the global layer can be maintained, and damage resistance to the damage such as probing damage and/or damage during the assembly process can be given. Here, forming the global layer with high-Young's-modulus films means forming the global layer with high-dielectric-constant films. Therefore, it is considered that the parasitic capacitance between wirings forming the global layer may be problematic. However, as the global layer is a wiring at an upper layer, and has a larger wiring width than the second fine layer and the semi global layer and also has larger wiring interval. Therefore, as compared with the second fine layer and the semi global layer, influence of the parasitic capacitance is smaller. In the global layer, strengthening of the mechanical strength has priority than reduction of parasitic capacitance.

As the wirings forming the global layer are formed of copper wiring, in the same manner as the second fine layer and the semi global layer, the barrier insulating film BI7a which is an insulating film and having function of preventing diffusion of copper atoms is formed to the upper portion of the copper wiring. As the barrier insulating film BI7a is formed of, for example, a stacked film of a SiCN film and a SiCO film, the barrier insulating film BI7a is formed of a high-dielectric-constant film (high-Young's-modulus film, and high-density film). By the barrier insulating film BI7a, diffusion of copper atoms from the copper wiring can be prevented.

As described in the foregoing, in the global layer, as the configuration between a plurality of wiring layers, first, the barrier insulating film BI7a is formed immediately above the copper wiring, and the interlayer insulating film IL8a is formed on the barrier insulating film BI7a. Then, the etching stop insulating film BI7b is formed on the interlayer insulating film IL8a and the interlayer insulating film IL8b is formed on the etching stop insulating film IL8a. As ensuring the mechanical strength has the highest priority regarding the global layer, high-Young's-modulus films are used as the interlayer insulating films IL8a to IL8b, and also, aiming at preventing diffusion of copper atoms from the copper wiring, the barrier insulating film BI7a is used.

Note that, there is also the following reason in using the configurations for the semi global layer and the global layer as described above. In devices of older generations in which wiring pitch of the fine layer and gate electrode arrangement pitch are larger than those of the device of the first embodiment, the semi global layer of the first embodiment works as a fine layer of the device of older generation, and the global layer of the first embodiment works as a semi global layer of the device of older generation, or, a global layer. In this manner, by using the wiring layers of devices of older generation to the semi global layer and the global layer of the device of the first embodiment, there is an effect of reducing a development cost and development time.

Next, features of the first embodiment will be described. Descriptions of functions of the interlayer insulating films described above have been made about the contact interlayer insulating film CIL, the second fine layer, the semi global layer, and the global layer; however, descriptions have not been made about the first fine layer (the first layer wiring L1). Here, a feature of the first embodiment is the configuration of the first fine layer, and this feature will be described hereinafter.

In FIG. 3, the interlayer insulating film IL1 forming the first fine layer is formed of, for example, a SiOC film. That is, the interlayer insulating film IL1 forming the first fine layer is formed of a middle-dielectric-constant film, middle-Young's-modulus film, in other words, middle-density film. Particularly, to describe in view of a characteristic function of the interlayer insulating film IL1, the interlayer insulating film IL1 is formed of a middle-Young's-modulus film. In this manner, by forming the interlayer insulating film IL1 forming the first fine layer with a middle-Young's-modulus film, even when using a low-dielectric-constant film having a lower dielectric constant than silicon oxide film to a part of interlayer insulating films (second fine layer), film exfoliation of the low-dielectric-constant film can be prevented and therefore reliability of the semiconductor device can be improved.

A reason of this will be described with a comparison with a comparative example. The semiconductor chip is packaged in a known back-end process. For example, in the back-end process, after mounting a semiconductor chip on a wiring board, pads formed to the semiconductor chip and terminal formed to the wiring board are connected through wires. Thereafter, the semiconductor chip sealed with a resin is packaged (see FIG. 2). As the finished package is used in various temperature conditions, the package is required to operate normally accommodating a wide range of temperature change. Therefore, after being packaged, the semiconductor chip is subjected to a temperature cycle test.

For example, when a temperature cycle test is performed to a package in which a semiconductor chip is sealed by a resin, as the coefficient of thermal expansion and Young's modulus are different in the resin and the semiconductor chip, stress is applied to the semiconductor chip. In this case, in a semiconductor chip using a low-dielectric-constant film to a part of an interlayer insulating film, exfoliation of the low-dielectric-constant film particularly occurs. That is, it has been found out that the exfoliation of the low-dielectric-constant film occurs in the comparative example because stress is generated to the semiconductor chip due to differences in the coefficient of thermal expansion and Young's modulus between the semiconductor chip and the resin in a temperature change implemented in the temperature cycle test, and the stress is generated on the semiconductor chip. When exfoliation of the interlayer insulating film occurs in the semiconductor chip, the semiconductor chip is defective as a device, lowering reliability of the semiconductor device.

A configuration of the comparative example in which such a film exfoliation of a low-dielectric-constant film occurs will be described. In the comparative example, the contact interlayer insulating film CIL, the second fine layer, the semi global layer, and the global layer are the same as the first embodiment. In the comparative example, a difference from the first embodiment is that the interlayer insulating film IL1 forming the first fine layer is formed of, for example, a TEOS film. That is, in the comparative example, the interlayer insulating film IL1 forming the first fine layer is formed of a high-Young's-modulus film. The interlayer insulating film IL1 is formed with a TEOS film in this manner in consideration of easiness of processing of the wirings.

In the configuration of the comparative example, the semiconductor substrate 1S has a high Young's modulus, and the contact interlayer insulating film CIL also has a high Young's modulus. Also, the interlayer insulating film IL1 formed to an upper layer of the contact interlayer insulating film CIL is a high-Young's-modulus film, and the barrier insulating film BI1 formed on the interlayer insulating film IL1 is also a high-Young's-modulus film. That is, from the semiconductor substrate 1S through the contact interlayer insulating film CIL, the interlayer insulating film IL1, and the barrier insulating film BI1, it is configured as an integrated high-Young's-modulus layer. And, in the comparative example, the interlayer insulating film IL2 formed of a low-dielectric-constant film is formed on the integrated high-Young's-modulus layer.

Here, according to a study made by the inventors of the present invention, due to differences in coefficient of thermal expansion and Young's modulus of the semiconductor chip and the resin, stress is generated in the semiconductor chip; the inventors have newly found out that the closer to the lower layer of the multilayer wiring layers, the larger the stress generated in the semiconductor chip, and, the maximum stress is applied to an interface at which Young's modulus becomes different. Therefore, in the comparative example, the maximum stress is applied to an interface of the interlayer insulating film IL2 which contacts the integrated high-Young's-modulus layer. While the lowermost wiring layer is the first fine layer, the interlayer insulating film IL1 forming the first fine layer is a high-Young's-modulus film same as the semiconductor substrate 1S and the contact interlayer insulating film CIL in the comparative example, and thus there is not much difference in Young's modulus. Therefore, while the first fine layer is the lower most wiring, stress acting on the interface of the interlayer insulating film IL1 forming the first fine layer and the contact interlayer insulating film CIL is not always maximum. Next, the layer at a next lower layer of the first fine layer is the second fine layer. The interlayer insulating film IL2 forming the second fine layer is a low-Young's-modulus film, and contacts the integrated high-Young's-modulus layer. Therefore, as the second fine layer is close to the lower layer of the multilayer wiring layers, and also is an interface at which Young's modulus becomes different, the maximum stress is applied to the interface at which the integrated high-Young's-modulus layer and the interlayer insulating film IL2 which is a low-Young's-modulus film contact. Here, the interlayer insulating film IL2 is a low-Young's-modulus film and has weak mechanical strength, and thus the interlayer insulating film IL2 which is a low-Young's-modulus film is exfoliated from the integrated high-Young's-modulus layer when large stress exceeding critical stress of the interlayer insulating film IL2 is applied to the interface of the interlayer insulating film IL2 and the integrated high-Young's-modulus layer. When a film exfoliation of the interlayer insulating film IL2 occurs in the semiconductor chip, the semiconductor chip becomes defective as a device, lowering the reliability of the semiconductor device. In this manner, in the comparative example, a problem of a lowering in reliability of the semiconductor device occurs as film exfoliation of the interlayer insulating film IL2 (low-Young's-modulus film) contacting the integrated high-Young's-modulus layer occurs.

Here, it is considered that it would be able to reduce the stress applied to the interlayer insulating film IL2 if the difference in Young's modulus of the integrated high-Young's-modulus layer and the interlayer insulating film IL2 which is a low-Young's-modulus film is mitigated. More specifically, forming the interlayer insulating film IL2 with a material which improves Young's modulus of the interlayer insulating film IL2 is considered. However, as Young's modulus and dielectric constant are in a substantially proportional relationship, a film having high Young's modulus may be a film having high dielectric constant. Therefore, while the interlayer insulating film IL2 is formed of a low-dielectric-constant film, when a film having high Young's modulus is used as the interlayer insulating film IL2, dielectric constant of the interlayer insulating film IL2 is increased, resulting in an increase in parasitic capacitance of the second fine layer. As a result, device performance of the semiconductor device is degraded.

Alternatively, selecting a material of the resin which makes the differences in coefficient of thermal expansion and Young's modulus between the resin sealing the semiconductor chip and the semiconductor chip small is considered. More specifically, in view of reducing the differences in coefficient of thermal expansion and Young's modulus, a material of the resin is selected, and originally, reducing the stress generated between the semiconductor chip and the resin is considered. In this case, however, fluidity of the resin is lowered substantially, posing filling or molding defect.

Therefore, in the current situation, a countermeasure of effectively preventing film exfoliation occurring to the interlayer insulating film IL2 (low-Young's-modulus film) contacting the integrated high-Young's-modulus layer has not been made.

Accordingly, in the first embodiment, a technical idea capable of effectively preventing film exfoliation occurring to the interlayer insulating film IL2 (low-Young's-modulus film) contacting the integrated high-Young's-modulus layer without posing a performance degradation of the semiconductor device is provided. Hereinafter, the technical idea according to the first embodiment will be specifically described.

In FIG. 3, a feature of the first embodiment is forming the interlayer insulating film IL1 forming the first fine layer with a middle-Young's-modulus film. That is, in the first embodiment, the interlayer insulating film IL1 is formed of a SiOC film, HSQ film, or MSQ film. In this manner, it is possible not to let the integrated high-Young's-modulus layer directly contact the interlayer insulating film IL2 which is a low-Young's-modulus film. That is, in the first embodiment, the integrated high-Young's-modulus layer is formed of the semiconductor substrate 1S and the contact interlayer insulating film CIL. Alternatively, the integrated high-Young's-modulus layer can be a layer in which all of the insulating films existing between the first interlayer insulating film IL1 and the semiconductor substrate 1S have Young's modulus higher than or equal to that of the high-Young's-modulus films. In addition, the interlayer insulating film IL1 formed of a middle-Young's-modulus film is formed on the integrated high-Young's-modulus layer, and the interlayer insulating film IL2 which is a low-Young's-modulus film is formed on the interlayer insulating film IL1 interposing the barrier insulating film BI1. As a result, it is possible to have the interlayer insulating film IL2 (low-Young's-modulus film) not directly contacted with the integrated high-Young's-modulus layer. In this manner, the stress generated to the interface of the interlayer insulating film IL2 which is a low-Young's-modulus film and the integrated high-Young's-modulus layer can be diverged. More specifically, in the first embodiment, the interlayer insulating film IL1 which is a middle-Young's-modulus film is formed between the integrated high-Young's-modulus layer and the interlayer insulating film IL2 (low-Young's-modulus film). In this case, there are interfaces at which Young's modulus becomes different: the interface of the integrated high-Young's-modulus layer and the interlayer insulating film IL1 (middle-Young's-modulus film) and the interface of the interlayer insulating film IL1 (middle-Young's-modulus film); and the interlayer insulating film IL2 (low-Young's-modulus film). That is, in the comparative example, there is one interface at which Young's modulus becomes different, which is the interface of the integrated high-Young's-modulus layer and the interlayer insulating film IL2. On the contrary, in the first embodiment, there are two interfaces at which Young's modulus becomes different: the interface of the integrated high-Young's-modulus layer and the interlayer insulating film IL1 (middle-Young's-modulus film); and the interface of the interlayer insulating film IL1 (middle-Young's-modulus film) and the interlayer insulating film IL2 (low-Young's-modulus film). Therefore, while the stress is concentrated on the one interface in the comparative example, as there are two interfaces at which Young's modulus becomes different in the first embodiment, the stress is diverged to the two interfaces. In this manner, in the first embodiment, the magnitude of the stress generated to individual interface can be made smaller. As a result, it is possible to prevent exfoliation of the interlayer insulating film IL2 (low-Young's-modulus film) from the interface between the interlayer insulating film IL2 (low-Young's-modulus film) and the interlayer insulating film IL1 (middle-Young's-modulus film).

Moreover, as the difference of Young's modulus is mitigated at each of the interface of the integrated high-Young's-modulus layer and the interlayer insulating film IL1 (middle-Young's-modulus film) and the interface of the interlayer insulating film IL1 (middle-Young's-modulus film) and the interlayer insulating film IL2 (low-Young's-modulus film), stress generated at each interface becomes further smaller. In this manner, in the first embodiment, there is a function of diffusing stress generated at the interface between the integrated high-Young's-modulus layer and the interlayer insulating film IL2 (low-Young's-modulus film) into two interfaces of the interface between the integrated high-Young's-modulus layer and the interlayer insulating film IL1 (middle-Young's-modulus film) and the interface between the interlayer insulating film IL1 (middle-Young's-modulus film) and the interlayer insulating film IL2 (low-Young's-modulus film). Further, as a second function, the first embodiment has a function capable of mitigating the differences of Young's modulus at the two diverged interfaces. That is, to describe the second function in detail, in the comparative example, the interface of the integrated high-Young's-modulus layer and the interlayer insulating film IL2 is one interface at which Young's modulus becomes different, and, in this case, the difference in Young's modulus is a difference between the high Young's modulus and the low Young's modulus and thus it is large. On the contrary, in the first embodiment, when focusing on, for example, the interface of the interlayer insulating film IL1 (middle-Young's-modulus film) and the interlayer insulating film IL2 (low-Young's-modulus film), the difference in Young's modulus is a difference between the middle Young's modulus and the low Young's modulus and thus it is small.

As described in the foregoing, in the first embodiment, the interlayer insulating film IL1 forming the first fine layer with a middle-Young's-modulus film, thereby achieving functions of the first function and the second function described above, and as a result, exfoliation of the interlayer insulating film IL2 (low-Young's-modulus film) forming the second fine layer can be prevented. Therefore, as to the package (semiconductor device) in which a semiconductor chip is sealed with a resin and also a semiconductor device in which a low-dielectric-constant film is used to a part of interlayer insulating films in a semiconductor chip, reliability can be improved.

The above discussion has been made, to facilitate understanding of the feature of the first embodiment, descriptions of the barrier insulating film BI1 (high-Young's-modulus film), which is formed between the interlayer insulating film IL1 (middle-Young's-modulus film) forming the first fine layer and the interlayer insulating film IL2 (low-Young's-modulus film) forming the second fine layer, have been omitted. However, even when the barrier insulating film BI1 (high-Young's-modulus film) is formed, film exfoliation of the interlayer insulating film IL2 (low-Young's-modulus film) can be prevented according to the first embodiment.

Specific descriptions will be made. In this case, as the interlayer insulating film IL2 (low-Young's-modulus film) contacts the barrier insulating film BI1 (high-Young's-modulus film, it may be supposed to lose the effect of preventing exfoliation. However, even in this case, the effect of preventing exfoliation of the interlayer insulating film IL2 (low-Young's-modulus film) can be surely achieved. A reason of this will be described.

In the first embodiment, the interlayer insulating film IL1 forming the first fine layer is formed of a middle-Young's-modulus film. Therefore, the integrated high-Young's-modulus layer is divided at the interlayer insulating film IL1 (middle-Young's-modulus film). That is, the interlayer insulating film IL2 (low-Young's-modulus film) directly contacts the barrier insulating film BI1 (high-Young's-modulus film), but does not directly contacts the integrated high-Young's-modulus layer divided at the interlayer insulating film IL1 (middle-Young's-modulus film). Since the integrated high-Young's-modulus layer has a large volume as it includes the semiconductor substrate 1S, when the high-Young's-modulus layer having a large volume and the interlayer insulating film IL2 (low-Young's-modulus film) are directly contacted, large stress is generated at the interface of the integrated high-Young's-modulus layer and the interlayer insulating film IL2 (low-Young's-modulus film). Therefore, in consideration of this point, even when the interlayer insulating film IL2 (low-Young's-modulus film) directly contacts the barrier insulating film BI1 (high-Young's-modulus film), the volume of the barrier insulating film BI1 (high-Young's-modulus film) itself is small as long as the barrier insulating film BI1 (high-Young's-modulus film) is divided (separated) from the integrated high-Young's-modulus layer, and therefore large stress is not generated. Therefore, an important function of the first embodiment is to divide (separate) the integrated high-Young's-modulus layer and the interlayer insulating film IL2 forming the second fine layer not to let them directly contact with each other by forming the interlayer insulating film IL1 constituting the first fine layer with a middle-Young's-modulus film.

In the first embodiment, the interlayer insulating film IL1 being a middle-Young's-modulus film is formed between the integrated high-Young's-modulus layer and the interlayer insulating film IL2 (low-Young's-modulus film). In this case, there are interfaces at which Young's modulus becomes different of: the interface of the integrated high-Young's-modulus layer and the interlayer insulating film IL1 (middle-Young's-modulus film); the interface of the interlayer insulating film IL1 (middle-Young's-modulus film) and the barrier insulating film BI1 (high-Young's-modulus film); and the interface of the barrier insulating film BI1 (high-Young's-modulus film) and the interlayer insulating film IL2 (low-Young's-modulus film). That is, in the comparative example, the interface of the integrated high-Young's-modulus layer and the interlayer insulating film IL2 is one interface at which Young's modulus becomes different. On the contrary, in the first embodiment, there are three interfaces at which Young's modulus becomes different of: the interface of the integrated high-Young's-modulus layer and the interlayer insulating film IL1 (middle-Young's-modulus film); the interface of the interlayer insulating film IL1 (middle-Young's-modulus film) and the barrier insulating film BI1 (high-Young's-modulus film); and the interface of the barrier insulating film BI1 (high-Young's-modulus film) and the interlayer insulating film IL2 (low-Young's-modulus film). Therefore, while the stress is concentrated on one interface in the comparative example, the stress is diffused to the three interfaces as there are three interfaces having different Young's modulus existing in the first embodiment. Therefore, the magnitude of the stress generated to individual interface can be reduced. As a result, exfoliation of the interlayer insulating film IL2 (low-Young's-modulus film) from the interface between the interlayer insulating film IL2 (low-Young's-modulus film) and the barrier insulating film BI1 (high-Young's-modulus film) can be prevented. As described in the foregoing, even when the barrier insulating film BI1 (high-Young's-modulus film) is provided, film exfoliation of the interlayer insulating film IL2 (low-Young's-modulus film) can be prevented according to the first embodiment.

Further, in the first embodiment, the following effect can be achieved by forming the interlayer insulating film IL1 forming the first fine layer with a middle-Young's-modulus film. That is, in the comparative example, the interlayer insulating film IL1 is formed with a TEOS film and is thus a high-frequency film. On the contrary, in the first embodiment, as the interlayer insulating film IL1 is formed with a middle-Young's-modulus film, the interlayer insulating film IL1 is thus formed of a middle-dielectric-constant film in consideration of the correlation of Young's modulus and dielectric constant. Wirings of the first fine layer are miniaturized in the same manner as the second fine layer and so the wiring interval is narrow. Therefore, by forming the interlayer insulating film IL1 with a middle-dielectric-constant film as the first embodiment, parasitic capacitance between wirings can be reduced. That is, according to the first embodiment, delay of electric signals transmitted in the wiring can be suppressed, and performance of the semiconductor device can be improved.

As described above, the feature of the first embodiment lies in, among the contact interlayer insulating film CIL, interlayer insulating film IL1 and interlayer insulating film IL2, forming the contact interlayer insulating film CIL with a high-Young's-modulus film having the highest Young's modulus, forming the interlayer insulating film IL2 with a low-Young's-modulus film having the lowest Young's modulus, and forming the interlayer insulating film IL1 with a middle-Young's-modulus film having Young's modulus lower than that of the contact interlayer insulating film CIL and higher than that of the interlayer insulating film IL2.

In addition, to describe the feature in other words in consideration of the correlation of Young's modulus and dielectric constant, the feature lies in, among the contact interlayer insulating film CIL, interlayer insulating film IL1 and interlayer insulating film IL2, forming the contact interlayer insulating film CIL with a high-dielectric-constant film having the highest dielectric constant, forming the interlayer insulating film IL2 with a low-dielectric-constant film having the lowest dielectric constant, and forming the interlayer insulating film IL1 with a middle-dielectric-constant film having dielectric constant lower than that of the contact interlayer insulating film CIL and higher than that of the interlayer insulating film IL2.

Moreover, in consideration of the correlation of dielectric constant and density, the feature of the first embodiment lies in, among the contact interlayer insulating film CIL, interlayer insulating film IL1 and interlayer insulating film IL2, forming the contact interlayer insulating film CIL with a high-density film having the highest density, forming the interlayer insulating film IL2 with a low-density constant film having the lowest density constant, and forming the interlayer insulating film IL1 with a middle-density film having a density lower than that of the contact interlayer insulating film CIL and higher than that of the interlayer insulating film IL2.

Subsequently, it will be described that stress can be actually reduced according to the first embodiment. FIG. 12 is a graph illustrating a relationship of a distance from the semiconductor substrate and shear stress. In FIG. 12, the horizontal axis is for the distance (nm) from the surface of the semiconductor substrate and the vertical axis is for shear stress. Note that the values of shear stress indicate relative numerical values, and a value of about “−1” is a stress value at which film exfoliation is caused.

The numerical values of “1” to “8” described in the upper portion of FIG. 12 indicate respective layers of the multilayer wiring. For example, “1” denotes the first fine layer, and “2” to “5” denote the second fine layer. Further, “6” to “7” denote the semi global layer, and “8” denotes the global layer. Note that, the contact layer is also denoted.

The curve (A) illustrates the structure of the comparative example. That is, in the comparative example, the case of forming the interlayer insulating film forming the first fine layer with a TEOS film is illustrated. From the curve (A), it is understood that the shear stress is largest at a boundary of the first layer wiring (first fine layer) and the second layer wiring (second fine layer). This indicate that the maximum stress is applied between the interlayer insulating film (high-Young's-modulus film) forming the first layer wiring L (first fine layer) and the interlayer insulating film (low-Young's-modulus film) forming the second layer wiring L. Therefore, in the comparative example, the possibility of exfoliation of the interlayer insulating film (low-Young's-modulus film forming the second layer wiring (second fine layer) is high.

On the contrary, the curve (B) illustrates the structure of the first embodiment. That is, in the first embodiment, the case of forming the boundary of the first layer wiring (first fine layer) and the second layer wiring (second fine layer) with a SiOC film (middle-Young's-modulus film) is illustrated. From the curve (B), it is understood that the stress generated at the boundary of the first layer wiring (first fine layer) and the second layer wiring (second fine layer) is smaller as it is diverged (dispersed) to the boundary of the contact layer of the first layer wiring (first fine layer). Therefore, according to the curve (B) describing the first embodiment, it is understood that exfoliation of the interlayer insulating film (low-Young's-modulus film) forming the second layer wiring (second fine layer) can be prevented as compared with the comparative example.

Note that, in the present simulation, the first fine layer is 100 to 200 nm, a total thickness of the second fine layer is 200 to 2000 nm, a total thickness of the semi global layer is 0 to 1000 nm, and a total thickness of the global layer is 1000 to 3000 nm. In addition, while the simulation was carried out with changing the values of thicknesses of the barrier insulating film and the etching stopper film provided to the second fine layer, the semi global layer, the global layer between 30 and 60 nm, and a thickness of the damage protection film DP provided to the fine layer between 30 and 50 nm, good results (the first embodiment is capable of preventing exfoliation of the interlayer insulating film (low-Young's-modulus film) forming the second layer wiring (second fine layer) as compared with the comparative example) were obtained. Note that, the thickness of the first fine layer is important here, diffusion of the stress may be failed when the thickness is smaller than or equal to 100 nm, failing to sufficiently suppress exfoliation of the interlayer insulating film (low-Young's-modulus film) forming the second layer wiring (second fine layer). There is no problem in suppressing exfoliation when the thickness of the first fine layer is smaller than or equal to 200 nm, but the first fine layer itself is thick in this case and thus wiring delay is increased.

Further, when the first embodiment and Patent Document 1 are compared, in Patent Document 1, polyarylether having low dielectric constant is used. Polyarylether is not formed in plasma CVD but formed in an application process, and thus its adhesive force with other films is weak and it is weak against exfoliation. And, in Patent Document 1, a semiconductor element is formed on the semiconductor substrate, and a contact interlayer insulating film is formed to cover the semiconductor element. To the contact interlayer insulating film, a plug electrically connected to the semiconductor element is formed. A wiring formed of normal metal layers is formed on the contact interlayer insulating film to which the plug is formed, and a planarizing insulating layer formed of boron-phosphorus-silicate glass is formed to cover the wiring. A first insulating layer formed of a SiOC film is formed on the planarizing insulating layer, and a first buried wiring formed of a copper film is formed to be buried in the first insulating layer. Therefore, in the structure, a wiring layer is provided between the first insulating layer and the first buried wiring and the semiconductor element, and the wiring layer is covered with an insulating film of a material such as boron-phosphorus-silicate glass which seems to have a good filling (burying) characteristics. Therefore, as compared with the first embodiment, a path to reach the first buried wiring from the semiconductor element is long, and dielectric constants of the insulating films existing around the wiring in the path are high, and wiring delay is thus large. Further, the process is complex and thus the cost is increased.

Moreover, in the first embodiment, the interlayer insulating film of the contact layer is required to have good filling characteristics to the semiconductor element, and thus a TEOS-based film is used. In the first fine layer, as a minimum pitch of the first layer wiring is slightly smaller than a minimum pitch of the second layer wiring of the second fine layer, it is necessary to raise processing accuracy of the wiring trench for the first layer wiring. Thus, an interlayer insulating film having middle Young's modulus and having higher dielectric constant than that of the interlayer insulating film having low Young's modulus of the second fine layer is used.

Note that, there are borazine-based insulating films in the world. As an example, borazine-based insulating films have relative permittivity of 2.3 and Young's modulus of 60 GPa, having different material characteristics than the interlayer insulating film materials described above. However, when the wiring structure is formed using the borazine-based insulating film, there are problems that leakage current between wirings is increased and TDDB characteristics is degraded. Therefore, the borazine-based insulating film is not used in the first embodiment.

The semiconductor device according to the first embodiment is configured in the manner described above, and hereinafter, an example of a method of manufacturing the semiconductor device will be described with reference to the drawings.

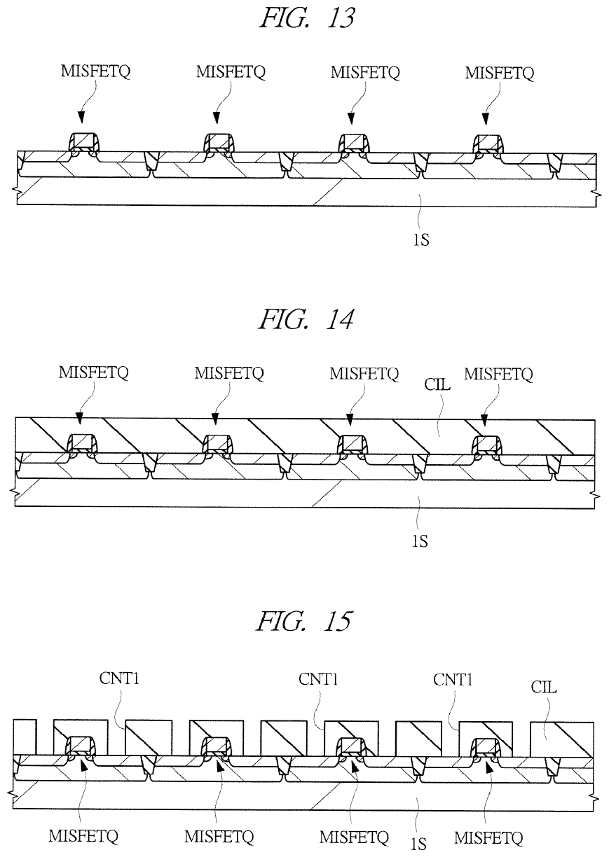

First, by using normal semiconductor manufacturing technology, the plurality of MISFETQs are formed on the semiconductor substrate 1S as illustrated in FIG. 13. Subsequently, as illustrated in FIG. 14, the contact interlayer insulating film CIL is formed on the semiconductor substrate 1S to which the plurality of MISFETQs are formed. The contact interlayer insulating film CIL is formed to cover the plurality of MISFETQs. More specifically, the contact layer insulating film CIL is formed of, for example, a stacked film of: an ozone TEOS film, which is formed on the ozone TEOS film, formed through thermal CVD using ozone and TEOS as source materials; and a plasma TEOS film formed through plasma CVD using TEOS as a source material. Note that, an etching stopper film formed of, for example, a silicon nitride film may be formed to a lower layer of the ozone TEOS film.

Next, as illustrated in FIG. 15, by using photolithography technology and etching technology, the contact hole CNT1 is formed to the contact interlayer insulating film CIL. The contact hole CNT1 is processed to penetrate through the contact interlayer insulating film CIL and reach a source region or a drain region of the MISFETQ formed to the semiconductor substrate 1S.

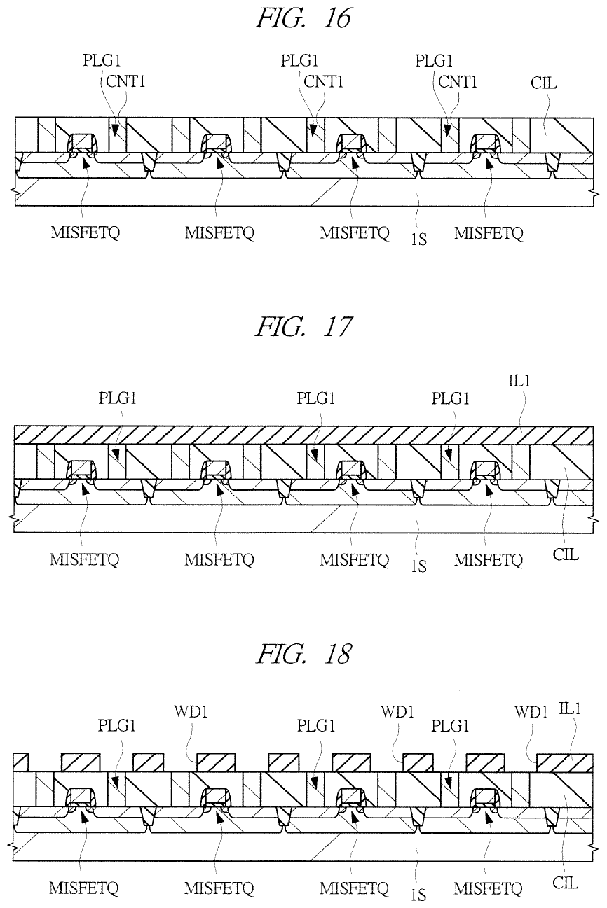

Subsequently, as illustrated in FIG. 16, a metal film is buried in the contact hole CNT1 formed in the contact interlayer insulating film CIL to form the plug PLG1. More specifically, on the contact interlayer insulating film CIL to which the contact hole CNT1 is formed, a titanium/titanium-nitride film to be a barrier conductive film is formed using sputtering. Then, a tungsten film is formed on the titanium/titanium-nitride film. In this manner, the titanium/titanium-nitride film is formed to an inner wall (sidewall and bottom surface) of the contact hole CNT1, and the tungsten film is formed on the titanium/titanium-nitride film to fill in the contact hole CNT1. After that, unnecessary parts of the titanium/titanium-nitride film and the tungsten film formed on the contact interlayer insulating film CIL are removed in CMP (Chemical Mechanical Polishing). In this manner, the plug PLG1 filled with the titanium/titanium-nitride film and the tungsten film can be formed only inside the contact hole CNT1.

Next, as illustrated in FIG. 17, the interlayer insulating film IL1 is formed on the contact interlayer insulating film CIL to which the plug PLG1 is formed. The interlayer insulating film IL1 is formed of a SiOC film which is a middle-Young's-modulus film, and formed by using, for example, plasma CVD. In this manner, the first embodiment has a feature in forming the interlayer insulating film IL1 with a SiOC film which is a middle-Young's-modulus film.

Then, as illustrated in FIG. 18, by using photolithography technology and etching technology, the wiring trench WD1 is formed to the interlayer insulating film IL1. The wiring trench WD1 is formed to penetrate through the interlayer insulating film IL1 formed of a SiOC film and have its bottom surface reaching the contact interlayer insulating film CIL. In this manner, a surface of the plug PLG1 is exposed at the bottom portion of the wiring trench WD1.

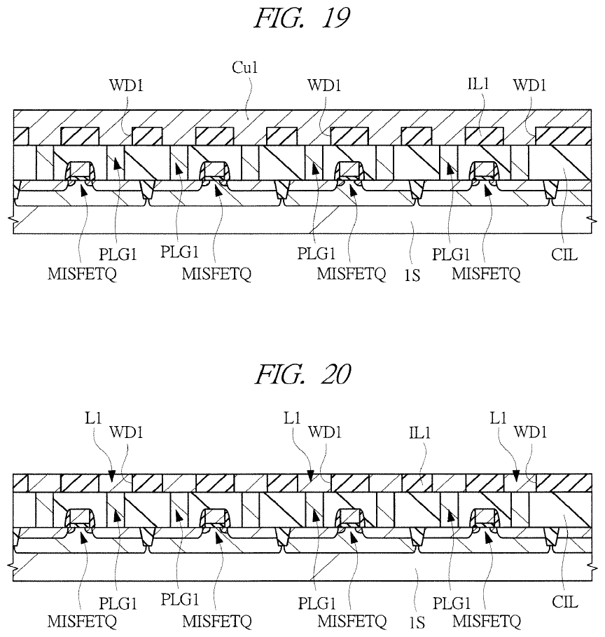

Then, as illustrated in FIG. 19, a barrier conductive film (film for preventing copper diffusion) (not illustrated) is formed on the interlayer insulating film IL1 to which the wiring trench WD1 is formed. More specifically, the barrier conductive film is formed of tantalum (Ta), titanium (Ti), ruthenium (Ru), tungsten (W), manganese (Mn), nitride or nitride-silicate of them, or a stacked film of them, and formed by, for example, sputtering.

Subsequently, on the barrier conductive film formed inside the wiring trench WD1 and on the interlayer insulating film IL1, a seed film formed of, for example, a thin copper film is formed by sputtering. Then, the copper film Cu1 is formed by electrolytic plating using the seed film as electrode. The copper film Cu1 is formed to fill in the wiring trench WD1. The copper film Cu1 is formed of, for example, a film mainly containing copper. More specifically, the copper film is formed of copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), lanthanum-based metal, and/or actinoid-based metal). Note that, when using a copper alloy, the copper film Cu1 is a copper alloy as the seed film is an alloy as described above. The same goes to copper alloys appearing in the following.

Next, as illustrated in FIG. 20, unnecessary parts of the barrier conductive film and the copper film Cu1 formed on the interlayer insulating film IL1 are removed by CMP. In this manner, the first layer wiring L1 (first fine layer) in which the barrier conductive film and the copper film Cu1 are buried in the wiring trench WD1 can be formed.

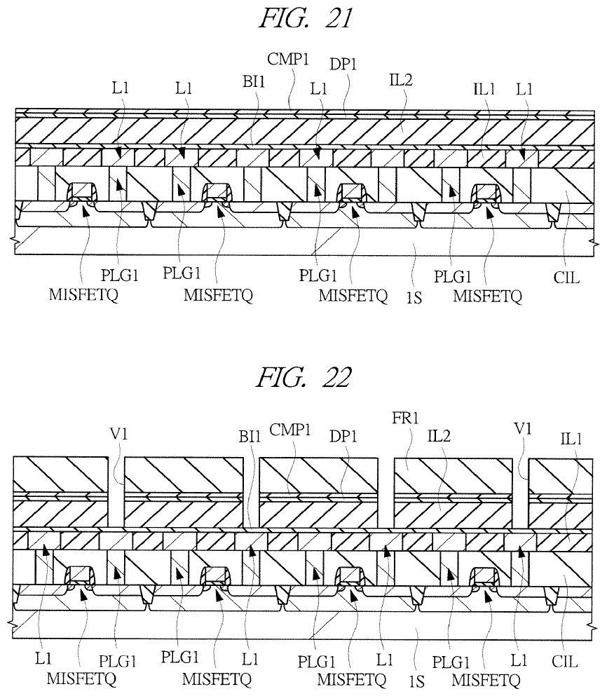

Then, ammonium plasma processing is performed on a surface of the interlayer insulating film IL1 to which the first layer wiring L1 is formed to clean up surfaces of the first layer wiring L1 and the interlayer insulating film IL1. Subsequently, as illustrated in FIG. 21, the barrier insulating film BI1 is formed on the interlayer insulating film IL1 to which the first layer wiring L1 is formed. The barrier insulating film BI1 is formed of, for example, a stacked film of a SiCN film and a SiCO film, and the stacked film can be formed by, for example, CVD. Note that, in the first embodiment, as the barrier insulating film BI1 is formed after performing the cleaning processing by ammonium plasma processing on the surface of the interlayer insulating film IL1 to which the first layer wiring L1 is formed, adhesiveness of the interlayer insulating film IL1 and the barrier insulating film BI1 is improved.

Then, the interlayer insulating film IL2 is formed on the barrier insulating film BI1, and the damage protection film DP1 is formed on the interlayer insulating film IL2. Further, a CMP protection film CMP1 is formed on the damage protection film. More specifically, the interlayer insulating film IL2 is formed of, for example, a SiOC film having a void.

Therefore, the interlayer insulating film IL2 is a low-dielectric-constant film, and also is a low-Young's-modulus film. The SiOC film having a void can be formed by, for example, plasma CVD. The damage protection film DP1 is formed of, for example, a SiOC film, and formed by, for example, plasma CVD. Therefore, the damage protection film DP1 is a middle-dielectric-constant film and also is a middle-Young's-modulus film. More over, the CMP protection film CMP1 is formed of, for example, a TEOS film or a silicon oxide film. Therefore, the CMP protection film CMP1 is a high-dielectric-constant film and also is a high-Young's-modulus film.

Subsequently, as illustrated in FIG. 22, a photoresist film FR1 formed of a chemically-amplified resist is formed on the CMP protection film CMP1. Then, by performing exposure/development process to the photoresist film FR1, the photoresist film FR1 is patterned. The patterning is performed to open regions for forming a via hole. Thereafter, with using the patterned photoresist film FR1 as a mask, the CMP protection film CMP1, the damage protection film DP1, and the interlayer insulating film IL2 are etched. In this manner, a via hole V1 penetrating through the CMP protection film CMP1, the damage protection film DP1, and the interlayer insulating film IL2 and exposing the barrier insulating film BI1 can be formed. In this manner, the barrier insulating film BI1 functions as an etching stopper upon etching.

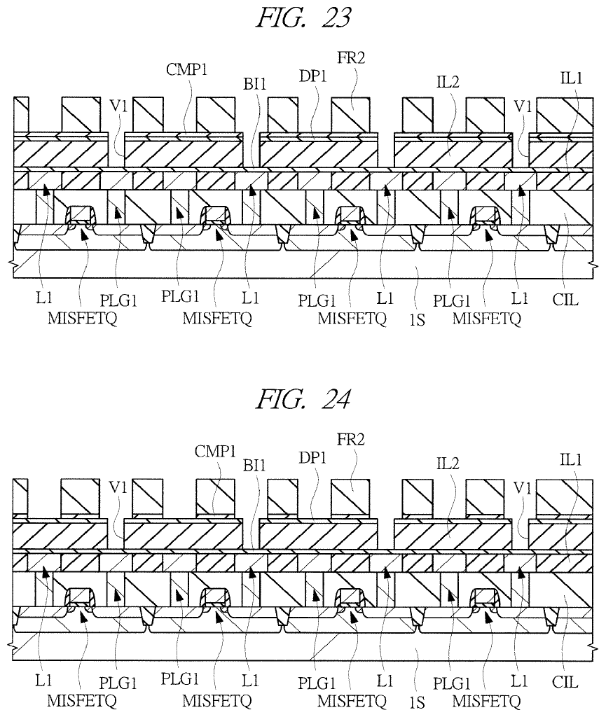

Next, as illustrated in FIG. 23, after removing the patterned photoresist film FR1, a photoresist film FR2 formed of a chemically-amplified resist is formed on the CMP protection film CMP1, and exposure/development process is performed on the photoresist film FR2, thereby patterning the photoresist film FR2. The patterning of the photoresist film FR2 is performed to open a region for forming a wiring trench. Here, as a SiCO film is formed as the barrier insulating film BI1, resist poisoning to the photoresist film FR2 can be prevented. The resist poisoning is a phenomenon as described below. That is, nitride contained in the ammonium plasma processing described above and/or nitride contained in the SiCN film forming the barrier insulating film BI1 are chemically reacted to generate amine, and this amine diffuse into the interlayer insulating film IL2. The diffused amine reaches the via hole V1 formed in the interlayer insulating film IL2. Here, upon patterning a pattern of forming the wiring trench by performing exposure on the photoresist film FR2, the photoresist film FR2 is a chemically-amplified resist to be formed in a vicinity of the via hole V1, and, as exposure reaction advances in the chemically-amplified resist as acid is generated upon exposure, by reaction with amine, which is a base, diffused from the via hole V1 the acid is neutralized. As a result, this phenomenon is such that the photoresist film FR2 in a vicinity of the via hole V1 is deactivated to pose exposure defect. When the resist poisoning occurs, patterning of the photoresist film FR2 becomes defective. Therefore, in the first embodiment, the SiCO film is provided on the SiCN film that is a generation source of amine to prevent diffusion of amine generated in the SiCN film. That is, the barrier insulating film BI1 is formed of a stacked film of a SiCN film and a SiCO film. The SiCN film itself is a film functions as a film of preventing copper diffusion for preventing diffusion of copper from the copper wiring, and the SiCO film is a film for suppressing resist poisoning by preventing diffusion of amine generated in the SiCN film. Note that, as to the material, instead of the SiCO film, a silicon oxide film or a TEOS film achieves the same effect, and using a SiN film instead of the SiCN film also achieves the same effect.

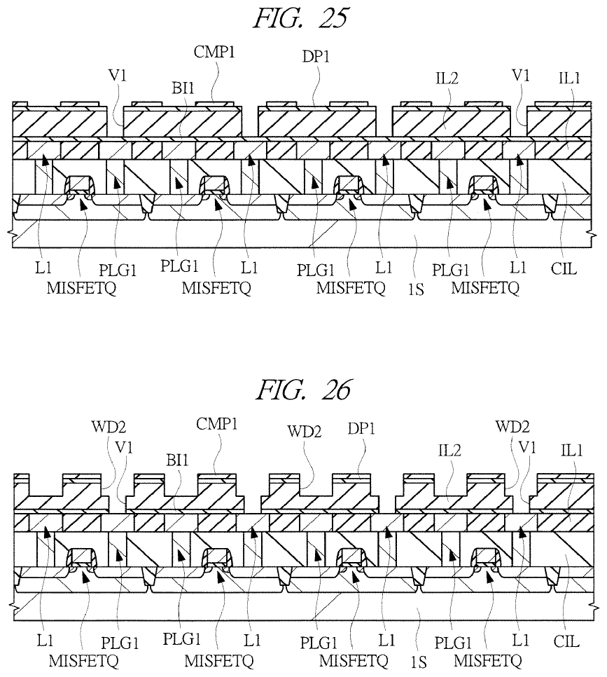

Thereafter, as illustrated in FIG. 24, through anisotropic etching using the patterned photoresist film FR2 as a mask, the CMP protection film CMP1 is etched. In the etching here, the damage protection film DP1 at a lower layer of the CMP protection film CMP1 works as an etching stopper. Then, as illustrated in FIG. 25, the patterned photoresist film FR2 is removed by a plasma ashing processing. Upon the plasma ashing processing, pattering corresponding to the wiring trench is not performed on the interlayer insulating film IL2 formed of a low-Young's-modulus film; therefore, damage due to the plasma asking processing is not applied to the wiring trench.

Subsequently, as illustrated in FIG. 26, by etch-back, the barrier insulating film BI1 exposed at the bottom portion of the via hole V1 is removed. In this manner, a surface of the layer wiring L1 is exposed at the bottom portion of the via hole V1. Through the etch-back here, parts of the damage protection film DP1 and the interlayer insulating film IL2 at a lower layer of the damage protection film DP1 exposed from the patterned CMP protection film CMP1 are also etched to form the wiring trench WD2. In this manner, using the patterned photoresist film FR2 and using the damage protection film DP1 as an etching stopper, the CMP protection film CMP1 is patterned. Thereafter, by an etch-back, while the barrier insulating film BI1 being exposed at the bottom surface of the via hole V1 is being removed, parts of the damage protection film DP1 and the interlayer insulating film IL2 are etched to form the wiring trench WD2, so that etching conditions of the etch-back is easier to set. This is because, as the barrier insulating film BI1 is formed of a SiC-based insulating film such as a SiCN film and/or a SiCO film and the damage protection film DP1 and the interlayer insulating film IL2 are formed of a SiOC film, the damage protection film DP1 and the interlayer insulating film IL2 are prone to be etched when the barrier insulating film BI1 is etched in the etch-back. Further, while the CMP protection film CMP1 is formed of a TEOS film or a silicon oxide film, it is aimed at making the CMP protection film CMP1 difficult to be etched (to increase the etching selectivity) upon etching the barrier insulating film BI1 formed of a SiCN film and/or a SiCO film.

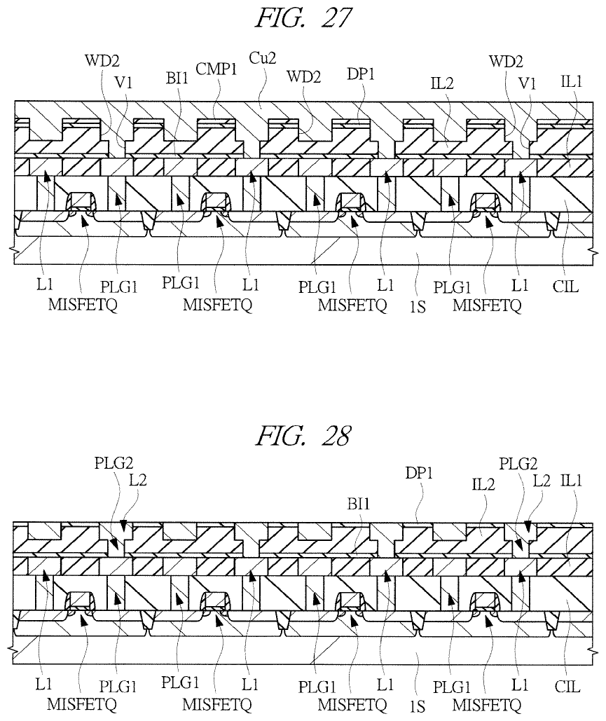

Next, as illustrated in FIG. 27, a barrier conductive film (film for preventing copper diffusion) (not illustrated) is formed on the CMP protection film CMP1 to which the wiring trench WD2 is formed. More specifically, the barrier conductive film is formed of tantalum (Ta), titanium (Ti), ruthenium (Ru), tungsten (W), manganese (Mn), nitride or nitride-silicate of them, or a stacked film of them, and formed by, for example, sputtering.

Subsequently, on the barrier conductive film formed inside the wiring trench WD2 and on the CMP protection film CMP1, a seed film formed of, for example, a thin copper film is formed by sputtering. Then, the copper film Cu2 is formed by electrolytic plating using the seed film as electrode. The copper film Cu2 is formed to fill in the wiring trench WD2. The copper film Cu2 is formed of, for example, a film mainly containing copper. More specifically, the copper film is formed of copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), a lanthanum-based metal, and/or actinoid-based metal).

Subsequently, as illustrated in FIG. 28, unnecessary parts of the barrier conductive film and the copper film Cu2 formed on the CMP protection film CMP1 are removed by CMP. In this manner, the second layer wiring L2 in which the damage protection film DP1 is exposed therefrom and the barrier conductive film and the copper film Cu2 are buried in the wiring trench WD2; and the plug PLG2 in which the barrier conductive film and the copper film Cu2 are buried in the via hole can be formed.

Here, the CMP protection film CMP1 is provided to withstand polishing pressure and scratch damage due to the CMP. While the damage protection film DP1 exposed through the CMP can withstand the polishing pressure and scratch damage of the CMP to some extent, it may not sufficiently withstand when the CMP protection film CMP1 is not provided. Further, for example, upon polishing by CMP, when surfaces of the interlayer insulating film IL2 formed of a low-Young's-modulus film is directly polished without providing the CMP protection film CMP1 and/or the damage protection film DP1, the interlayer insulating film IL2 formed of a low-Young's-modulus film cannot withstand the polishing pressure and/or scratch damage due to the CMP and the interlayer insulating film IL2 is damaged, causing a defect. Therefore, in the first embodiment, the CMP protection film CMP1 is provided to protect the interlayer insulating film IL2 and the damage protection film DP1 from the polishing of CMP.

Here, the damage protection film DP1 is formed on the interlayer insulating film IL2 and the CMP protection film CMP1 is formed on the damage protection film DP1. In this case, to describe respective films from the view point of Young's modulus, a middle-Young's-modulus film (the damage protection film DP1) is formed on a low-Young's-modulus film (the interlayer insulating film IL2), and a high-Young's-modulus film (the CMP protection film CMP1) is formed on the middle-Young's-modulus film (damage protection film DP1). That is, in the structure, between the low-Young's-modulus film (the interlayer insulating film IL2) and the high-Young's-modulus film (the CMP protection film CMP1), the middle-Young's-modulus film (the damage protection film DP1) is formed. Therefore, for example, when forming the high-Young's-modulus film (the CMP protection film CMP1) directly on the low-Young's-modulus film (the interlayer insulating film IL2) without providing the middle-Young's-modulus film (the damage protection film DP1), large polishing pressure due to the CMP is applied to the interface, posing a fear of exfoliation of the low-Young's-modulus film (the interlayer insulating film IL2). With regard to this, in the first embodiment, the middle-Young's-modulus film (the damage protection film DP1) is provided between the low-Young's-modulus film (the interlayer insulating film IL2) and the high-Young's-modulus film (the CMP protection film CMP1). Therefore, the polishing pressure due to the CMP is diffused to the interface of the low-Young's-modulus film (the interlayer insulating film IL2) and the middle-Young's-modulus film (the damage protection film DP1) and the interface of the middle-Young's-modulus film (the damage protection film DP1) and the high-Young's-modulus film (the CMP protection film CMP1). As a result, the polishing pressure applied to the low-Young's-modulus film (the interlayer insulating film IL2) is mitigated, thereby preventing exfoliation of the low-Young's-modulus film (the interlayer insulating film IL2) due to the polishing pressure of the CMP.

The CMP protection film CMP1 is removed through polishing of the CMP. Therefore, by removing the CMP protection film CMP1 formed of a high-dielectric-constant film after finishing polishing by CMP, dielectric constant of the second layer wiring L2 can be lowered, so that high-speed operation of the semiconductor device (device) can be achieved. In the above-described manner, the second layer wiring L2 can be formed.

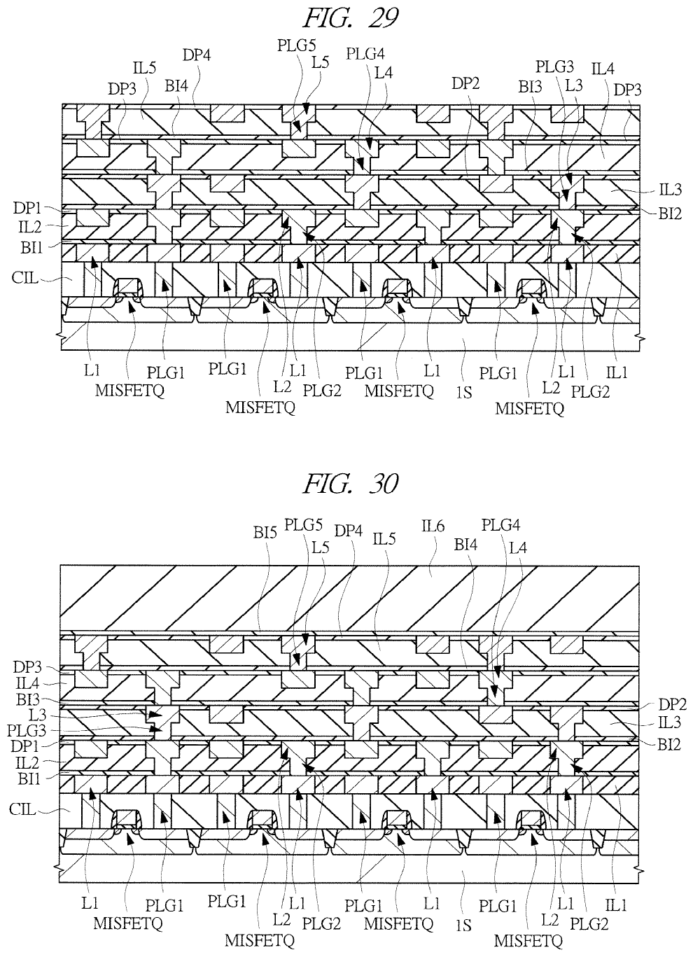

Thereafter, as illustrated in FIG. 29, an ammonium plasma processing is performed on the surface of the damage protection film DP1 to which the second layer wiring L2 is formed to clean up surfaces of the second layer wiring L2 and the damage protection film DP1. Subsequently, the barrier insulating film BI2 is formed on the damage protection film DP1 to which the second layer wiring L2 is formed. The barrier insulating film BI2 is formed of, for example, a stacked film of a SiCN film and a SiCO film, and the stacked film can be formed of, for example, CVD. Note that, in the first embodiment, as the barrier insulating film BI2 is formed after performing the cleaning process by ammonium plasma processing to the surface of the damage protection film DP1 to which the second layer wiring L2 is formed, the adhesiveness of the damage protection film DP1 and the barrier insulating film BI2 is improved. Further, the damage protection film DP1 can be considered to have a function of protecting the interlayer insulating film IL2 which is a low-Young's-modulus film from damage due to the ammonium plasma processing. By repeating such a manufacturing process, the third layer wiring L3 to the fifth layer wiring L5 are formed. In this manner, the second fine layer (the second layer wiring L2 to the fifth layer wiring L5) can be formed.

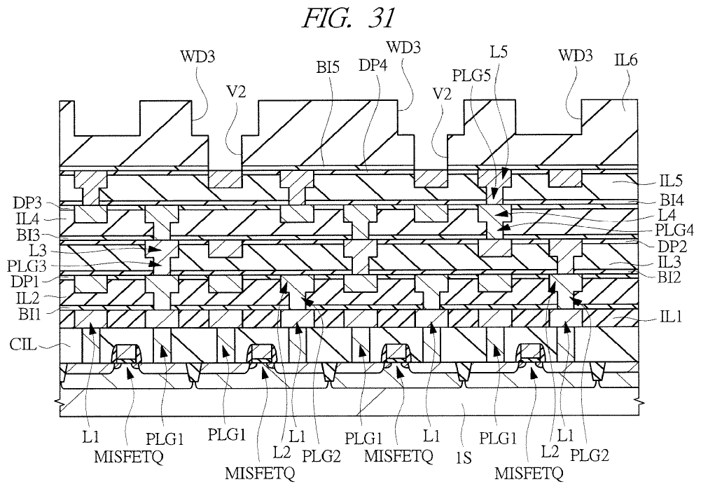

Subsequently, a process of forming the semi global layer on the second fine layer will be described. As illustrated in FIG. 30, ammonium plasma processing is performed on a surface of the damage protection film DP4 to which the fifth layer wiring L5 is formed to clean up surfaces of the fifth layer wiring L5 and the damage protection film DP4. Subsequently, the barrier insulating film BI5 is formed on the damage protection film DP4 to which the fifth layer wiring L5 is formed. The barrier insulating film BI5 is formed of, for example, a stacked film of a SiCN film and a SiCO film, and the stacked film can be formed by, for example, CVD. Note that, in the first embodiment, as the barrier insulating film BI5 is formed after performing the cleaning process by ammonium plasma processing to the surface of the damage protection film DP4 to which the fifth layer wiring L5 is formed, the adhesiveness of the damage protection film DP4 and the barrier insulating film BI5 is improved.

Next, the interlayer insulating film IL6 is formed on the barrier insulating film BI5. The interlayer insulating film IL6 is formed of, for example, a SiOC film which is a middle-Young's-modulus film, and can be formed by, for example, plasma CVD.

Then, as illustrated in FIG. 31, by using photolithography technology and etching technology, a wiring trench WD3 and a via hole V2 are formed to the interlayer insulating film IL6. The via hole V2 is formed to penetrate through the interlayer insulating film IL6 formed of a SiOC film and have its bottom surface reaching the fifth layer wiring L5. In this manner, the surface of the fifth layer wiring L5 is exposed at the bottom portion of the via hole V2.

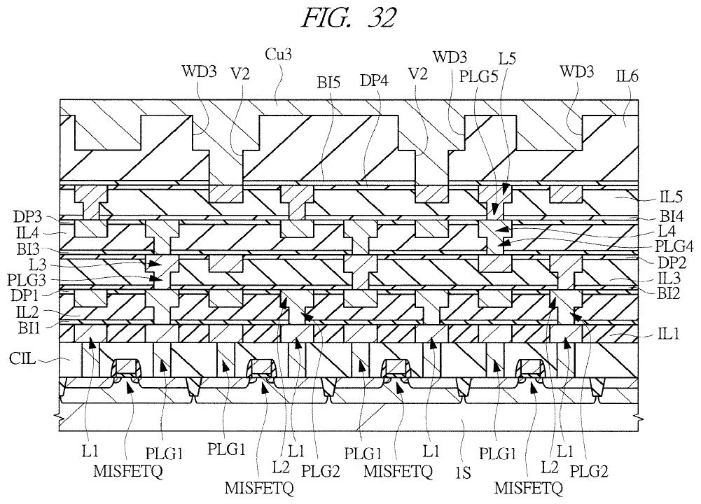

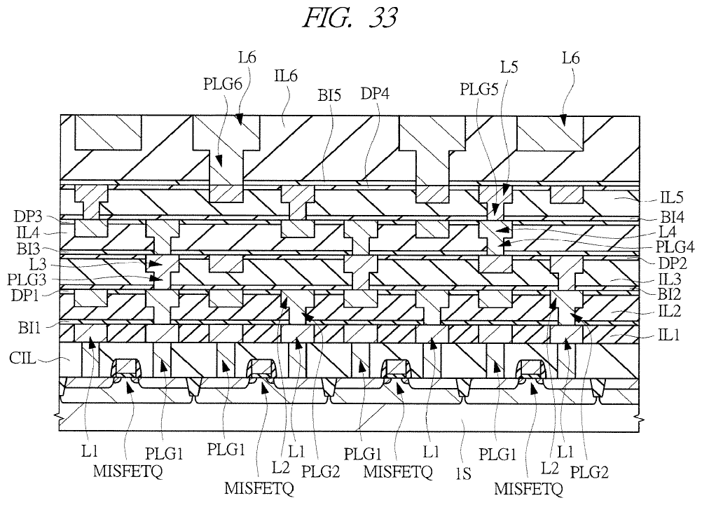

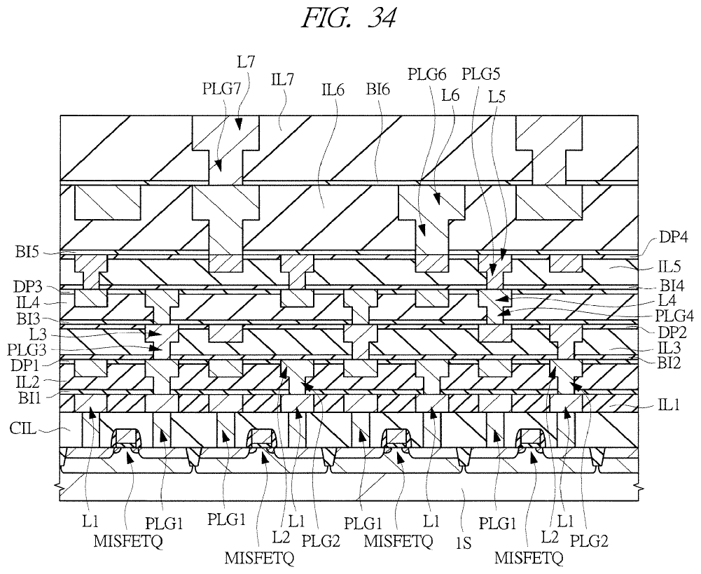

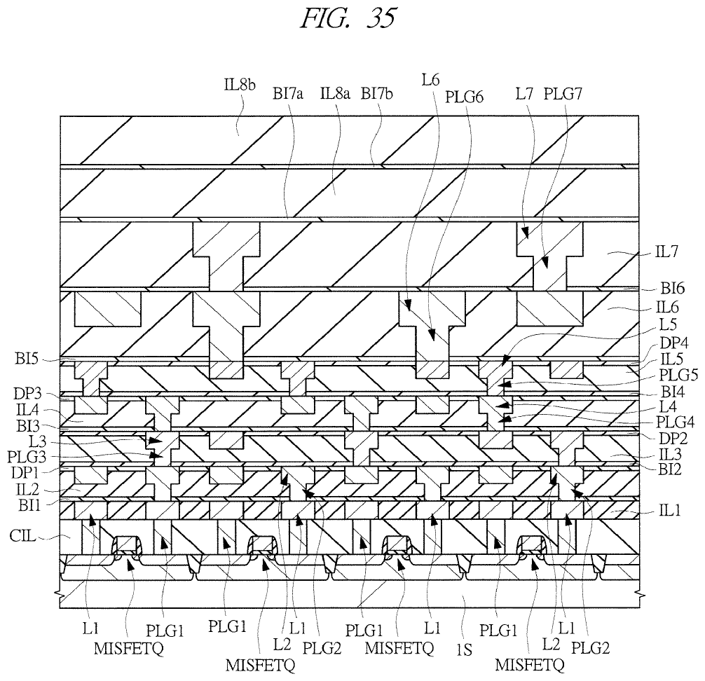

Thereafter, as illustrated in FIG. 32, a barrier conductive film (film for preventing copper diffusion) (not illustrated) is formed on the interlayer insulating film IL6 to which the wiring trench WD3 and the via hole V2 are formed. More specifically, the barrier conductive film is formed of tantalum (Ta), titanium (Ti), ruthenium (Ru), tungsten (W), manganese (Mn), nitride or nitride-silicate of them, or a stacked film of them, and formed by, for example, sputtering.

Subsequently, on the barrier conductive film formed inside the wiring trench WD3 and the via hole V2 and on the interlayer insulating film IL6, a seed film formed of, for example, a thin copper film is formed by sputtering. Then, the copper film Cu3 is formed by electrolytic plating using the seed film as electrode. The copper film Cu3 is formed to fill in the wiring trench WD3 and the via hole V2. The copper film Cu3 is formed of, for example, a film mainly containing copper. More specifically, the copper film is formed of copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), a lanthanum-based metal, and/or actinoid-based metal).

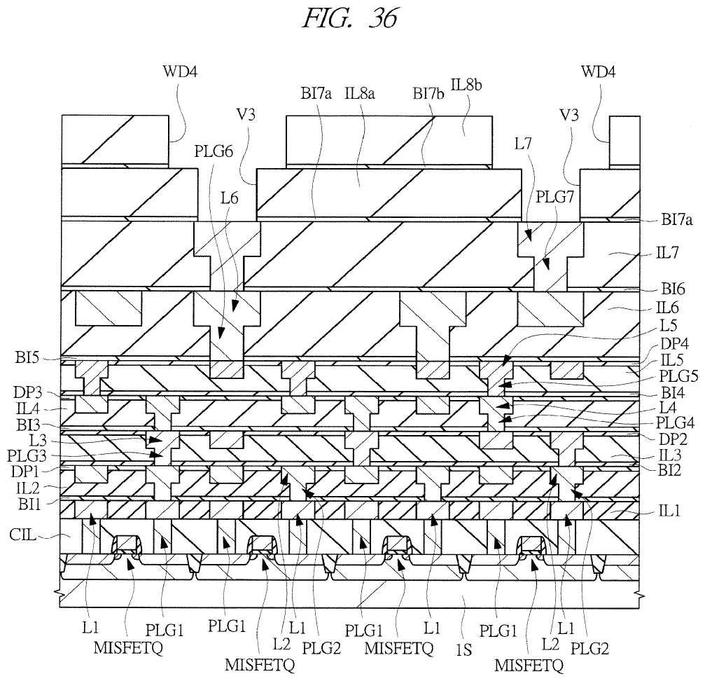

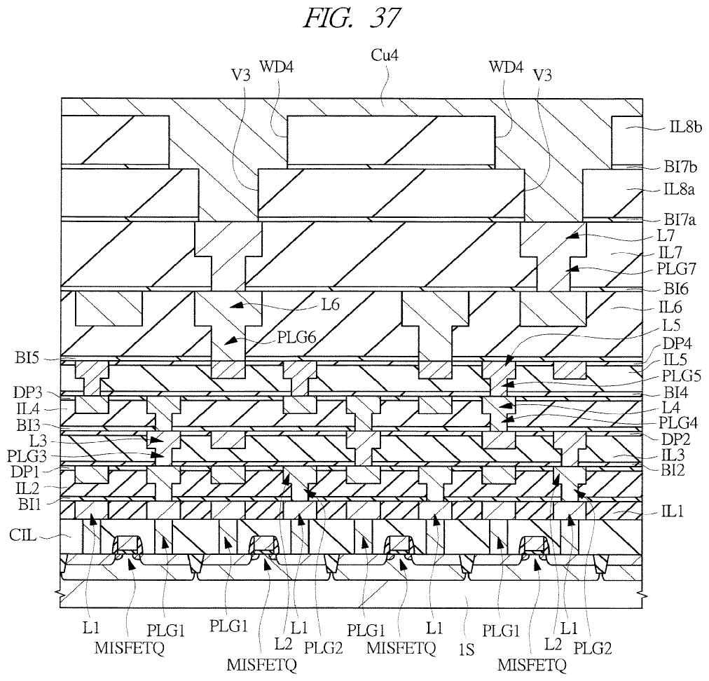

Next, as illustrated in FIG. 33, unnecessary parts of the barrier conductive film and the copper film Cu3 formed on the interlayer insulating film IL6 are removed by CMP. In this manner, the sixth layer wiring L6 in which the barrier conductive film and the copper film Cu3 are buried in the wiring trench WD3 and the plug PLG6 in which the barrier conductive film and the copper film Cu3 are buried in the via hole V2 can be formed. In the above-described manner, the sixth layer wiring L6 can be formed. By repeating such a manufacturing process, the seventh layer wiring L7 as illustrated in FIG. 34 is formed. In this manner, the semi global layer (the sixth layer wiring L6 to the seventh layer wiring L7) can be formed.

Subsequently, a process of forming the global layer on the semi global layer will be described. As illustrated in FIG. 35, ammonium plasma processing is performed on a surface of the interlayer insulating film IL7 to which the seventh layer wiring L7 is formed to clean up surfaces of the seventh layer wiring L7 and the interlayer insulating film IL7. Subsequently, the barrier insulating film BI7a is formed on the interlayer insulating film IL7 to which the seventh layer wiring L7 is formed. The barrier insulating film BI7a is formed of, for example, a stacked film of a SiCN film and a SiCO film, and the stacked film can be formed by, for example, CVD. Note that, in the first embodiment, as the barrier insulating film BI7a is formed after performing the cleaning process by ammonium plasma processing to the surface of the interlayer insulating film IL7 to which the seventh layer wiring L7 is formed, the adhesiveness of the interlayer insulating film IL7 and the barrier insulating film BI7a is improved.

Next, the interlayer insulating film IL8 is formed on the barrier insulating film BI7a. The interlayer insulating film IL8 is formed of, for example, a TEOS film and/or a silicon oxide film which is a high-Young's-modulus film, and can be formed by, for example, plasma CVD. Further, the etching stop insulating film BI7b is formed on the interlayer insulating film IL8a, and the interlayer insulating film IL8b is formed on the etching stop insulating film BI7b. The etching stop insulating film BI7b is formed of, for example, SiCN, and the SiCN film can be formed by, for example, CVD. Also, the interlayer insulating film IL8b is formed of a TEOS film and/or a silicon oxide film, which is a high-Young's-modulus film, and formed by using, for example, plasma CVD.

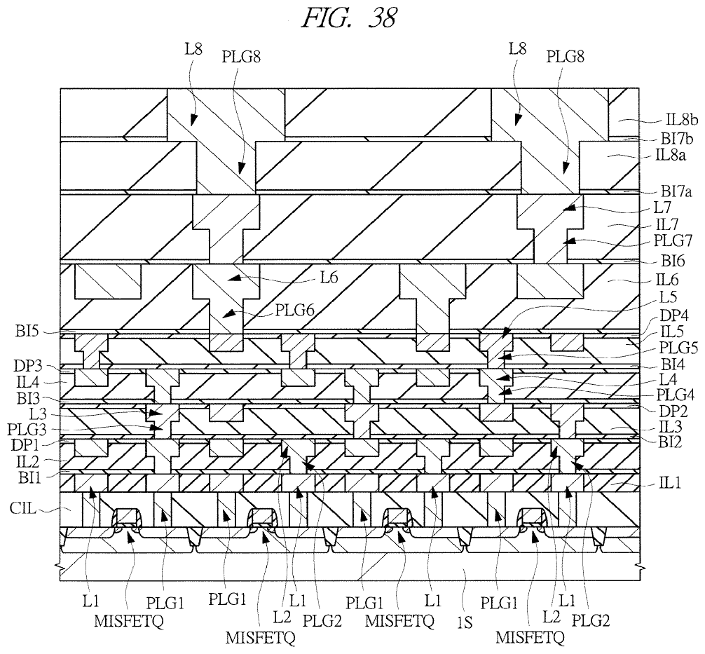

In addition, as illustrated in FIG. 36, by using photolithography technology and etching technology, a wiring trench WD4 is formed to the interlayer insulating film IL8b and the etching stop insulating film BI7b, and also, a via hole V3 is formed to the interlayer insulating film IL8b and the barrier insulating film BI7a. The via hole V3 is formed to penetrate through the interlayer insulating film IL8a formed of a TEOS film and/or a silicon oxide film and have its bottom surface reaching the seventh layer wiring L7. In this manner, the surface of the seventh layer wiring L7 is exposed at the bottom portion of the via hole V3.

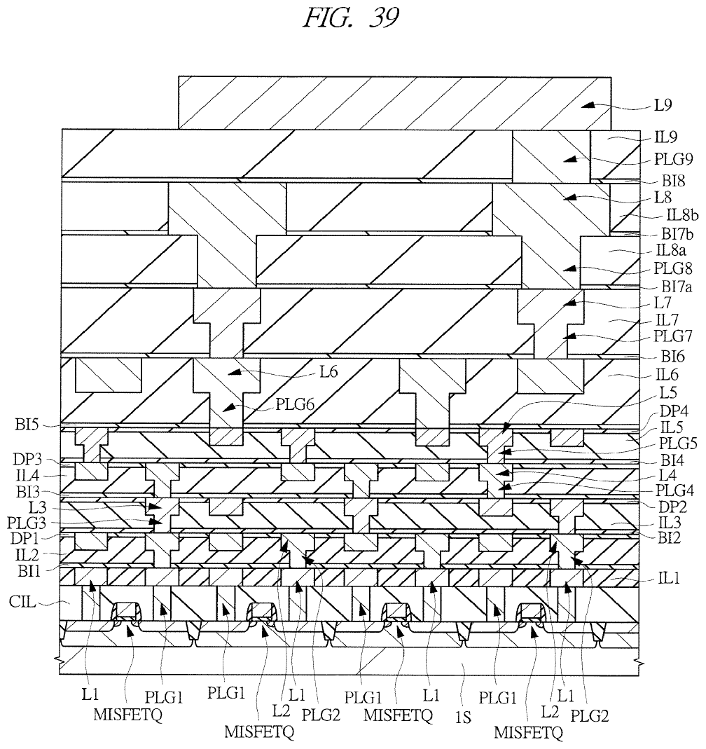

Thereafter, as illustrated in FIG. 37, a barrier conductive film (film for preventing copper diffusion) (not illustrated) is formed on the interlayer insulating film IL8b to which the wiring trench WD4 is formed and the interlayer insulating film IL8a to which the via hole V3 is formed. More specifically, the barrier conductive film is formed of tantalum (Ta), titanium (Ti), ruthenium (Ru), tungsten (W), manganese (Mn), nitride or nitride-silicate of them, or a stacked film of them, and formed by, for example, sputtering.

Subsequently, on the barrier conductive film formed inside the wiring trench WD4 and the via hole V3 and on the interlayer insulating film IL8b, a seed film formed of, for example, a thin copper film is formed by sputtering. Then, the copper film Cu4 is formed by electrolytic plating using the seed film as electrode. The copper film Cu4 is formed to fill in the wiring trench WD4 and the via hole V3. The copper film Cu4 is formed of, for example, a film mainly containing copper. More specifically, the copper film is formed of copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), a lanthanum-based metal, and/or actinoid-based metal).

Next, as illustrated in FIG. 38, unnecessary parts of the barrier conductive film and the copper film Cu4 formed on the interlayer insulating film IL8b are removed by CMP. In this manner, the eighth layer wiring L8 in which the barrier conductive film and the copper film Cu4 are buried in the wiring trench WD4 and the plug PLG8 in which the barrier conductive film and the copper film Cu4 are buried in the via hole V3 can be formed. In the above-described manner, the eighth layer wiring L8 can be formed. Therefore, the global layer (the eighth layer wiring L8) can be formed.

Subsequently, as illustrated in FIG. 39, the barrier insulating film BI8 is formed on the interlayer insulating film IL8b to which the eighth layer wiring L8 is formed and the interlayer insulating film IL9 is formed on the barrier insulating film BI8. For example, the barrier insulating film BI8 is formed of, for example, a stacked film of a SiCN film and a SiCO film, and the stacked film can be formed by, for example, CVD. Also, the interlayer insulating film IL9 is formed of a TEOS film and/or a silicon oxide film, which is a high-Young's-modulus film, and is formed by using, for example, plasma CVD. In addition, a via hole penetrating through the interlayer insulating film IL9 and the barrier insulating film BI8 is formed.

Next, a stacked film formed by sequentially stacking a titanium/titanium-nitride film, an aluminum film, and a titanium/titanium-nitride film is formed on sidewalls and a bottom surface of the via hole and the interlayer insulating film IL9 and the stacked film is patterned, thereby forming the plug PLG9 and the uppermost layer wiring L9.

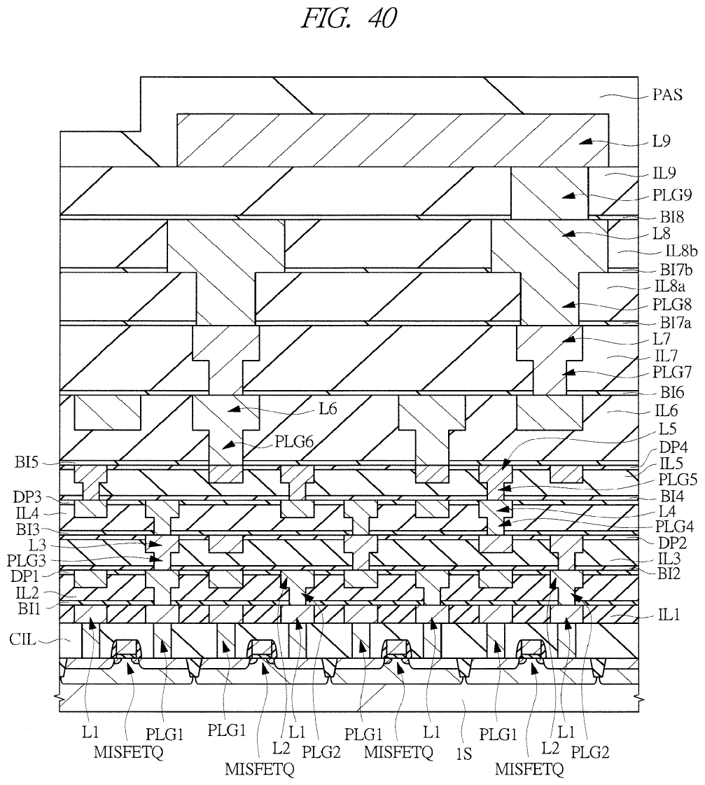

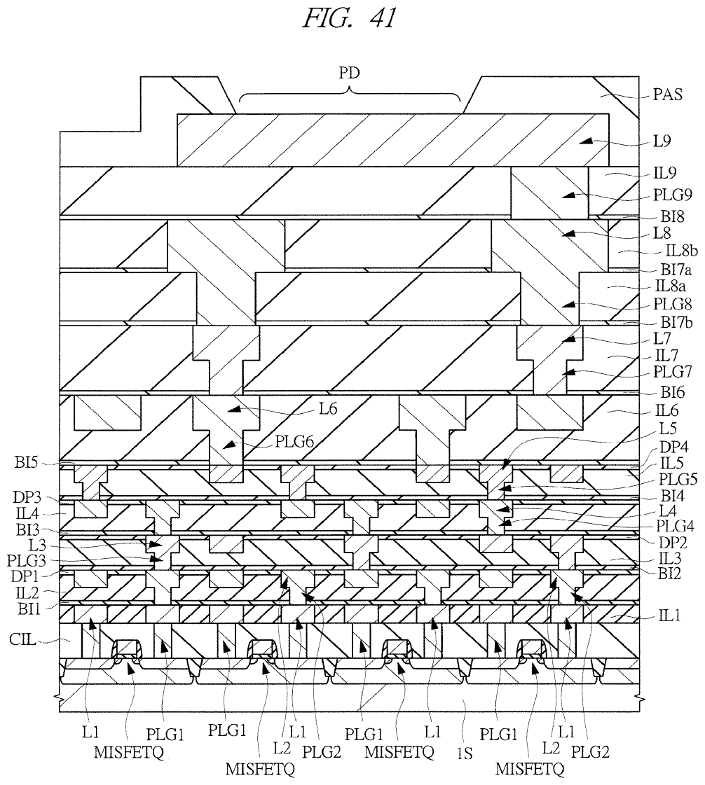

Thereafter, as illustrated in FIG. 40, the passivation film PAS to be a surface protection film is formed on the interlayer insulating film IL9 to which the uppermost layer wiring L9 is formed. The passivation film PAS is formed of, for example, a silicon oxide film and a silicon nitride film formed on the silicon oxide film, and formed by, for example, CVD. In addition, as illustrated in FIG. 41, by using photolithography technology and etching technology, an opening portion is formed to the passivation film PAS to expose a part of the uppermost layer wiring L9, thereby forming the pad PD.

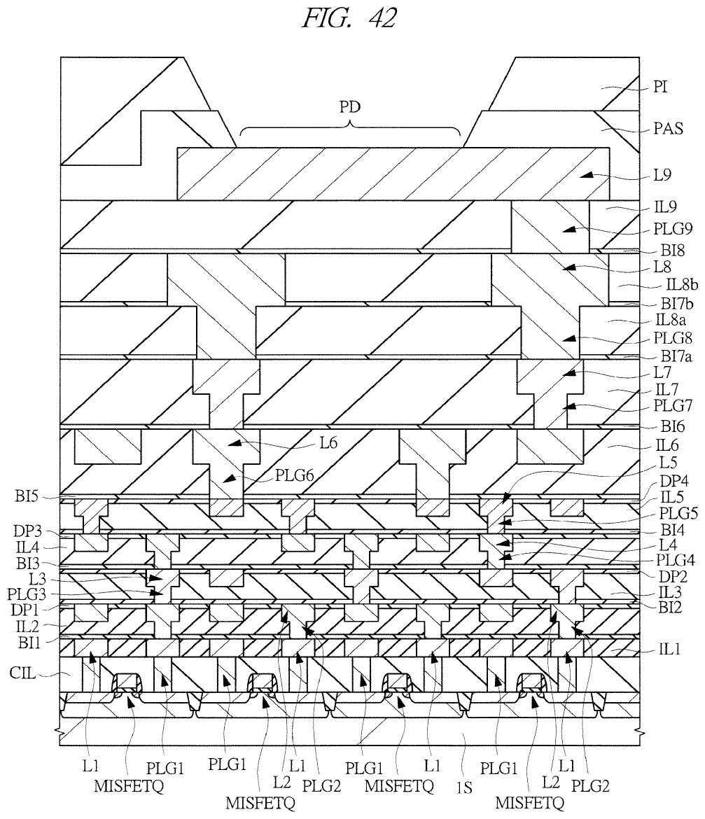

Next, as illustrated in FIG. 42, the polyimide film PI is formed on the passivation film PAS from which the pad PD is exposed. Then, the polyimide film PI is patterned to expose the pad PD. In the above-described manner, the MISFET and multilayer wiring can be formed on the semiconductor substrate 1S.

Subsequently, as illustrated in FIG. 43, the semiconductor substrate 1S is subjected to dicing so that the plurality of semiconductor chips CHP are obtained. In FIG. 43, one semiconductor chip CHP is illustrated, and the pad PD is formed on the main surface side (element-forming surface side) of the semiconductor chip CHP.

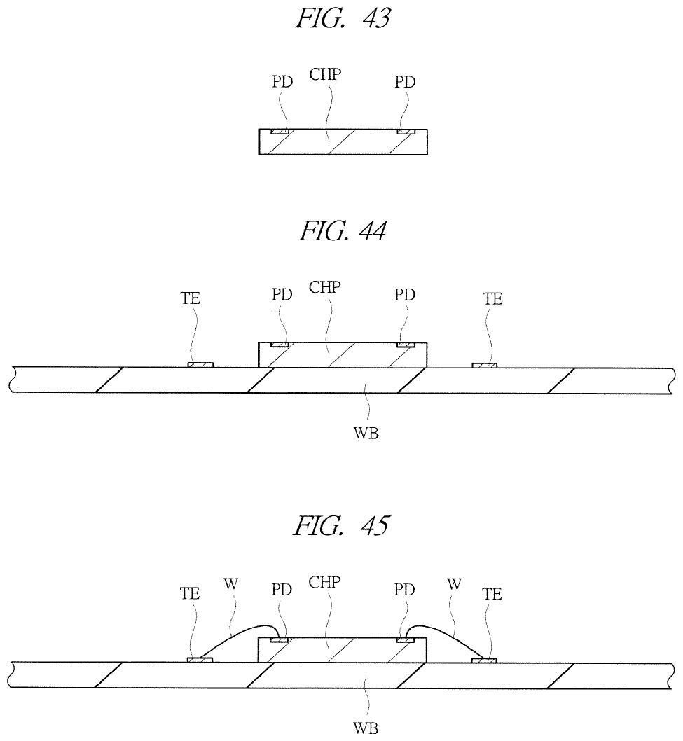

Next, as illustrated in FIG. 44, the semiconductor chip CHP is mounted on the wiring board WB. Then, as illustrated in FIG. 45, the pad PD formed to the semiconductor chip CHP and the terminal TE formed to the wiring board WB are connected by a wire W formed of a gold wire or the like. Thereafter, as illustrated in FIG. 46, sealing with the resin MR is performed so that the semiconductor chip CHP ad the wire W are covered.

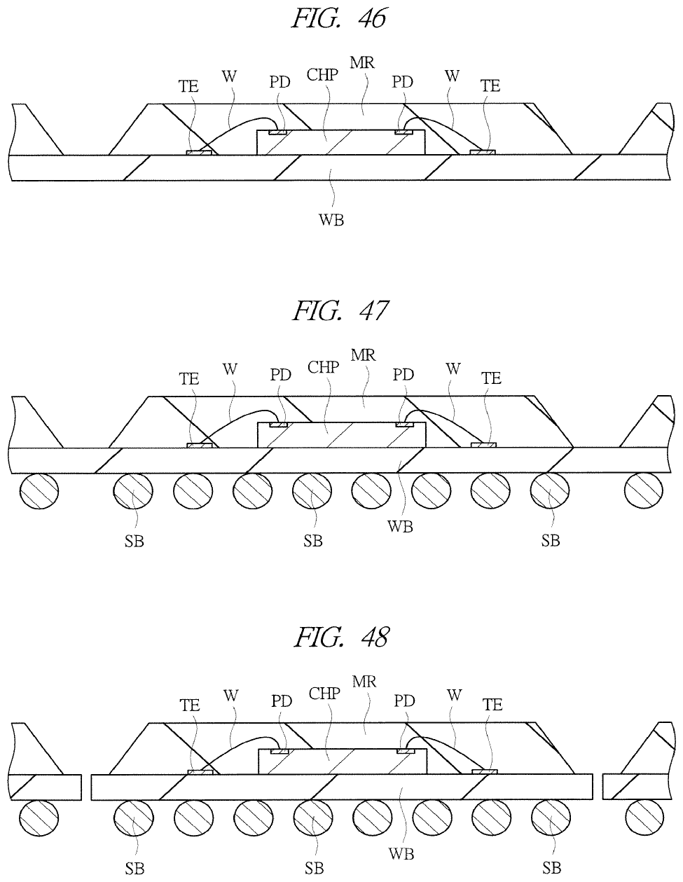

Subsequently, as illustrated in FIG. 47, the solder ball SB to be an external connection terminal is formed to the rear surface (the surface on the opposite side to the chip-mounting surface) of the wiring board WB. Then, as illustrated in FIG. 48, by singulating the wiring board WB, the semiconductor device according to the first embodiment as illustrated in FIG. 2 can be manufactured.

As the package finished in such a manner is used in various temperature conditions, the semiconductor chip is required to operate normally accommodating a wide range of temperature change. Therefore, after being packaged, the semiconductor chip is subjected to a temperature cycle test.

For example, when the temperature cycle test is performed on the package in which the semiconductor chip is sealed with a resin, as coefficient of thermal expansion and Young's modulus differ in the resin and the semiconductor chip, stress is applied to the semiconductor chip. Here, the closer to the lower layer of the multilayer wiring, the larger the stress generated in the semiconductor chip becomes, and, the maximum stress is applied to the interface at which the Young's modulus becomes different.

Here, according to the first embodiment, the interlayer insulating film IL1 which is a middle-Young's-modulus film is formed between the integrated high-Young's-modulus layer and the interlayer insulating film IL2 (low-Young's-modulus film). In this case, there are interfaces at which Young's modulus becomes different: the interface of the integrated high-Young's-modulus layer and the interlayer insulating film IL1 (middle-Young's-modulus film) and the interface of the interlayer insulating film IL1 (middle-Young's-modulus film) and the interlayer insulating film IL2 (low-Young's-modulus film). That is, in the first embodiment, there are two interfaces at which Young's modulus becomes different: the interface of the integrated high-Young's-modulus layer and the interlayer insulating film IL1 (middle-Young's-modulus film); and the interface of the interlayer insulating film IL1 (middle-Young's-modulus film) and the interlayer insulating film IL2 (low-Young's-modulus film). Therefore, while the stress is concentrated on one interface in the case in which the interlayer insulating film IL1 is formed of a high-Young's-modulus film, as there are two interfaces at which Young's modulus becomes different in the first embodiment, the stress is diverged to the two interfaces. In this manner, in the first embodiment, the magnitude of the stress generated to individual interface can be made smaller. As a result, it is possible to prevent exfoliation of the interlayer insulating film IL2 (low-Young's-modulus film) from the interface between the interlayer insulating film IL2 (low-Young's-modulus film) and the interlayer insulating film IL1 (middle-Young's-modulus film).

In the above descriptions, to facilitate understanding of the feature of the first embodiment, descriptions of the barrier insulating film BI1 (high-Young's-modulus film), which is formed between the interlayer insulating film IL1 (middle-Young's-modulus film) forming the first fine layer and the interlayer insulating film IL2 (low-Young's-modulus film) forming the second fine layer, have been omitted; however, even when the barrier insulating film BI1 (high-Young's-modulus film) is formed, film exfoliation of the interlayer insulating film IL2 (low-Young's-modulus film) can be prevented according to the first embodiment. Because, by forming the interlayer insulating film IL1 forming the first fine layer with a middle-Young's-modulus film, the integrated high-Young's-modulus layer and the interlayer insulating film IL2 forming the second fine layer can be separated without letting them directly contact with each other, and also, the stress can be diverged.

Subsequently, a further feature of the first embodiment will be described. In the first embodiment, the interlayer insulating film IL2 forming the second fine layer is formed of, for example, a SiOC film having a void. The SiOC film having a void is a low-Young's-modulus film as well as a low-dielectric-constant layer. In addition, the SiOC film having a void is formed by plasma CVD in the first embodiment. This point is the further feature of the first embodiment. That is, in the first embodiment, separating the integrated high-Young's-modulus layer and the interlayer insulating film IL2 forming the second fine layer without letting them directly contact with each other by forming the interlayer insulating film IL1 forming the first fine layer with a middle-Young's-modulus film is primarily focused. This configuration achieves greater effect by increasing the adhesive force of the interlayer insulating film IL2. Although the interlayer insulating film IL2 directly contacts, for example, the barrier insulating film BI1, when the contact is stronger, exfoliation of the interlayer insulating film IL2 can be further prevented. Therefore, in the first embodiment, the SiOC film having a void forming the interlayer insulating film IL2 is formed by plasma CVD. Since it is possible to form strong bonds by giving high energy according to plasma CVD, the interlayer insulating film IL2 having strong bonds can be formed.

Therefore, from the view point of forming the interlayer insulating film IL2 with a film having strong adhesive force, it is preferable not to use a film like PAE (polyarylether) as the interlayer insulating film IL2. Since PAE is normally formed by application method, the adhesive force is less than plasma CVD. In this manner, the first embodiment has features in: achieving separation of the integrated high-Young's-modulus layer and the interlayer insulating film IL2 forming the second fine layer without letting them directly contact with each other by forming the interlayer insulating film IL1 forming the first fine layer with a middle-Young's-modulus film; and diverging stress, these features achieve a greater effect when the insulating film constituting the interlayer insulating film IL2 is formed by plasma CVD.

Moreover, another feature of the first embodiment will be described. Generally, there is a problem of bad adhesiveness at an interface of a metal and an insulating film in semiconductor devices. For example, as illustrated in FIG. 3, while the wiring pattern of the second layer wiring L2 can be suitably provided, in a region in a vicinity of a power ring etc., a ratio of metal wirings is particularly increased. Here, let's consider that stress posed by differences in coefficient of thermal expansion and Young's modulus of the resin covering the semiconductor chip and the semiconductor chip is applied to a region (a partial region of the second layer wiring L2) in which a ratio of metal wirings is larger, such as the region in a vicinity of the power ring or the like. In this case, the damage protection film DP1 is formed on the interlayer insulating film IL2 formed of a low-Young's-modulus film. Therefore, ammonium plasma processing can be performed on the surface of the damage protection film DP1 without giving damage on the interlayer insulating film IL2 which is a low-Young's-modulus film. This means that the adhesive force of the damage protection film DP1 and the barrier insulating film BI2 is improved, and thus, it is possible to prevent exfoliation of the interface of the damage protection film DP1 and the barrier insulating film BI2 due to the stress described above even in the region in which a ratio of metal wiring is large.

Further, in the structure of the first embodiment, the damage protection film DP1 is formed on the interlayer insulating film IL2, and the barrier insulating film BI2 is formed on the damage protection film DP1. It can be said that a middle-Young's-modulus film (damage protection film DP1) is formed between a low-Young's-modulus film (interlayer insulating film IL2) and high-Young's-modulus film (barrier insulating film BI2) in the structure. Therefore, the stress applied between the low-Young's-modulus film (interlayer insulating film IL2) and the high-Young's-modulus film (damage protection film DP1) is diverged by forming the middle-Young's-modulus film (damage protection film DP1). As a result, it is possible to suppress exfoliation of the low-Young's-modulus film (interlayer insulating film IL2) due to the stress described above.

### Second Embodiment

While a package in which the whole of the semiconductor chip is sealed with a resin has been described in the first embodiment, a package in which a part of a semiconductor chip is sealed with a resin will be described in a second embodiment.

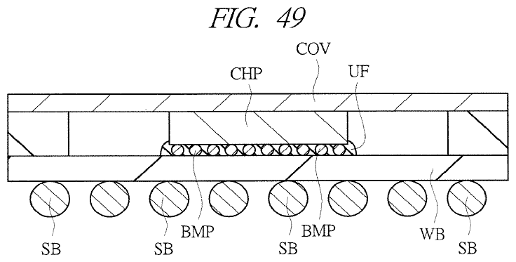

FIG. 49 is a cross-sectional view illustrating a configuration example of a package according to the second embodiment. In FIG. 49, a semiconductor chip CHP is mounted on a wiring board WB. More specifically, a bump electrode (protruding electrode) BMP is formed to the semiconductor chip CHP, and the semiconductor chip CHP is mounted onto the wiring board WB so that the bump electrode BMP is electrically connected to a terminal (not illustrated) formed to the wiring board WB. A solder ball SB which functions as an external connection terminal is formed on a back surface of the wiring board WB. At the wiring board WB, a terminal formed to a main surface of the wiring board WB and the solder ball SB formed to the back surface of the wiring board WB are electrically connected via a wiring (not illustrated) formed inside the wiring board WB. Therefore, the bump electrode BMP formed to the semiconductor chip CHP is electrically connected to the solder ball to be an external connection terminal. That is, in the package illustrated in FIG. 49, the semiconductor chip CHP and an external circuit can be electrically connected via the solder ball SB.

Further, in the package illustrated in FIG. 49, the bump electrode BMP connecting the semiconductor chip CHP and the wiring board WB is sealed with a resin called underfill UF. That is, in the package illustrated in FIG. 49, the underfill UF is formed to cover the bump electrode BMP, and thus the bump electrode BMP is protected from the external environment such as humidity and temperature by the underfill US, so that the connection strength by the bump electrode BMP is improved. Also, an upper surface of the semiconductor chip CHP is covered with a cover COV.

In this manner, in the package illustrated in FIG. 49, a part of the semiconductor chip CHP is sealed with the underfill UF, and thus stress is applied to the semiconductor chip CHP due to temperature changes in a temperature cycle test. That is, when a wide range of temperature change by a temperature cycle test is applied to the package, stress is generated to the semiconductor chip CHP due to differences in coefficient of thermal expansion and Young's modulus of the semiconductor chip CHP and the underfill UF. When the stress is generated to the semiconductor chip CHP, a problem of film exfoliation may occur in a multilayer wiring formed inside the semiconductor chip CHP. Also in the second embodiment, the same problem as that of the package of the first embodiment described above occurs.

Accordingly, also in the second embodiment, the configuration of interlayer insulating film is devised in the same manner as the first embodiment (FIG. 3) described above. More specifically, as illustrated in FIG. 3, the interlayer insulating film IL1 forming the first fine layer is formed of, for example, a SiOC film. That is, the interlayer insulating film IL1 forming the first fine layer is formed of a middle-dielectric-constant film, a middle-Young's-modulus, or in other words, a middle-density film. Particularly, from a view point of a characteristic function of the interlayer insulating film IL1, the interlayer insulating film IL1 is formed of a middle-Young's-modulus film. In this manner, by forming the interlayer insulating film IL1 forming the first fine layer with a middle-Young's-modulus film, film exfoliation of a low-dielectric-constant film is prevented even when a low-dielectric-constant film having a lower dielectric constant than silicon oxide film is used to a part (the second fine layer) of the interlayer insulating films, and thus reliability of the semiconductor device can be improved.

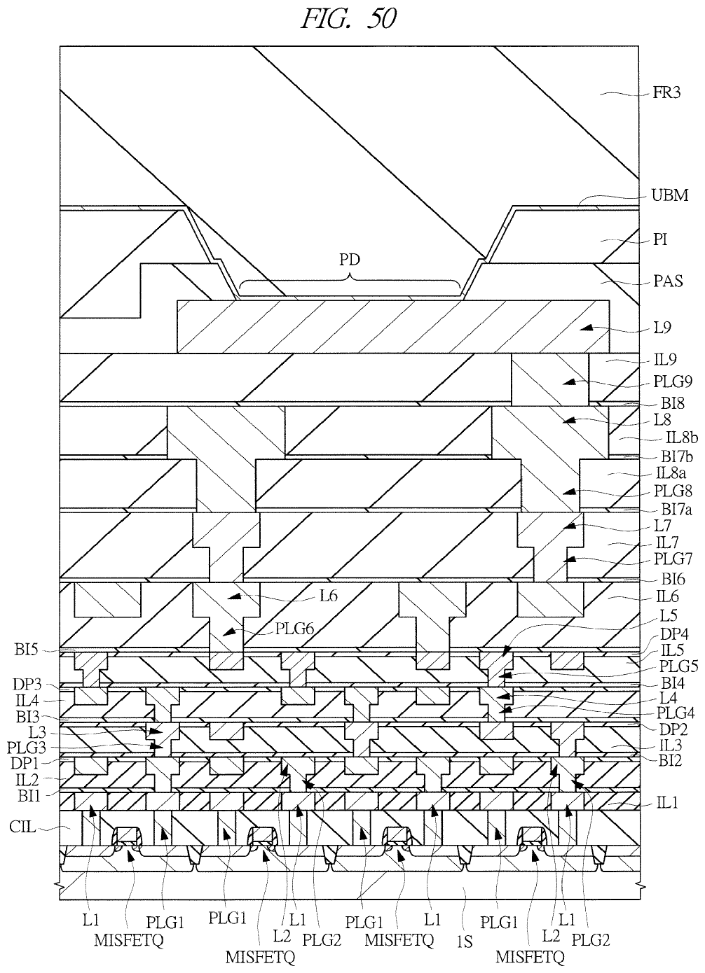

Subsequently, a method of manufacturing the semiconductor device according to the second embodiment will be described with reference to the drawings. The process of FIGS. 13 to 42 is the same as the first embodiment. Next, as illustrated in FIG. 50, an under bump metal film UBM is formed on the polyimide film PI having an opening of the pad PD. The under bump metal film UBM can be formed by using sputtering, and formed of a single-layer film of titanium film, nickel film, palladium film, titanium-tungsten alloy film, titanium nitride film or gold film, or a stacked film thereof. Here, the under bump metal film UBM is a film having a barrier function of suppressing or preventing movement of metal elements of a gold film formed in a following process from moving and movement of metal elements forming the multilayer wiring to the gold film side on the contrary, in addition to a function of improving adhesiveness of the bump electrode with the pad and/or a surface protection film. Further, a photoresist film FR3 is formed on the under bump metal film UBM.

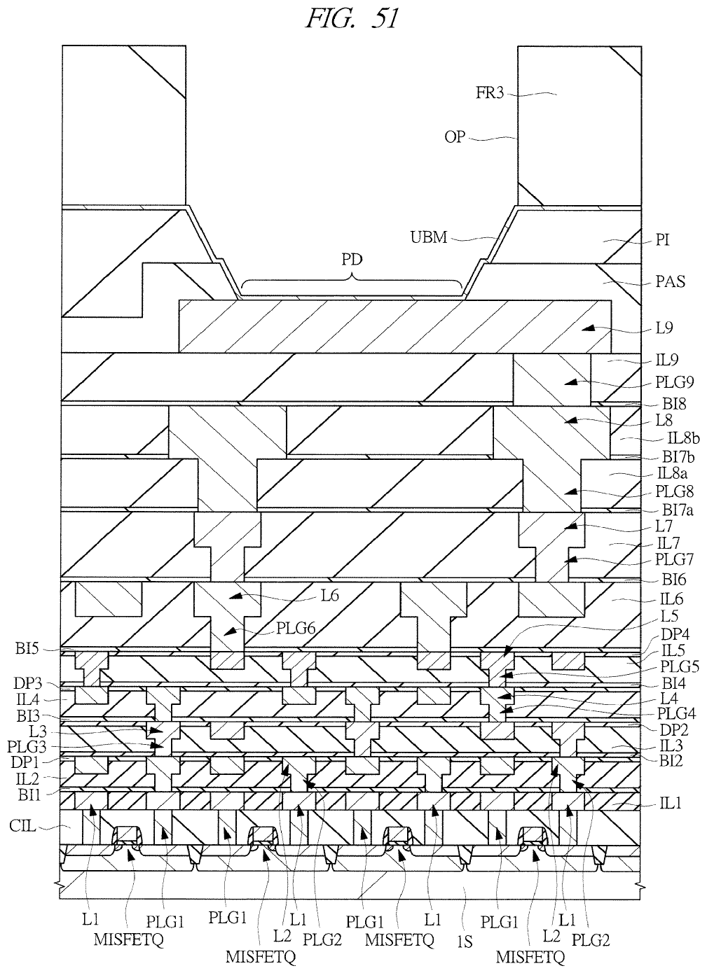

Next, as illustrated in FIG. 51, by using photolithography technology, the photoresist film FR3 is patterned. The patterning of the photoresist film FR3 is performed to open a region for forming bump electrode on the pad PD. That is, by patterning the photoresist film FR3, an opening OP exposing the pad PD is formed.

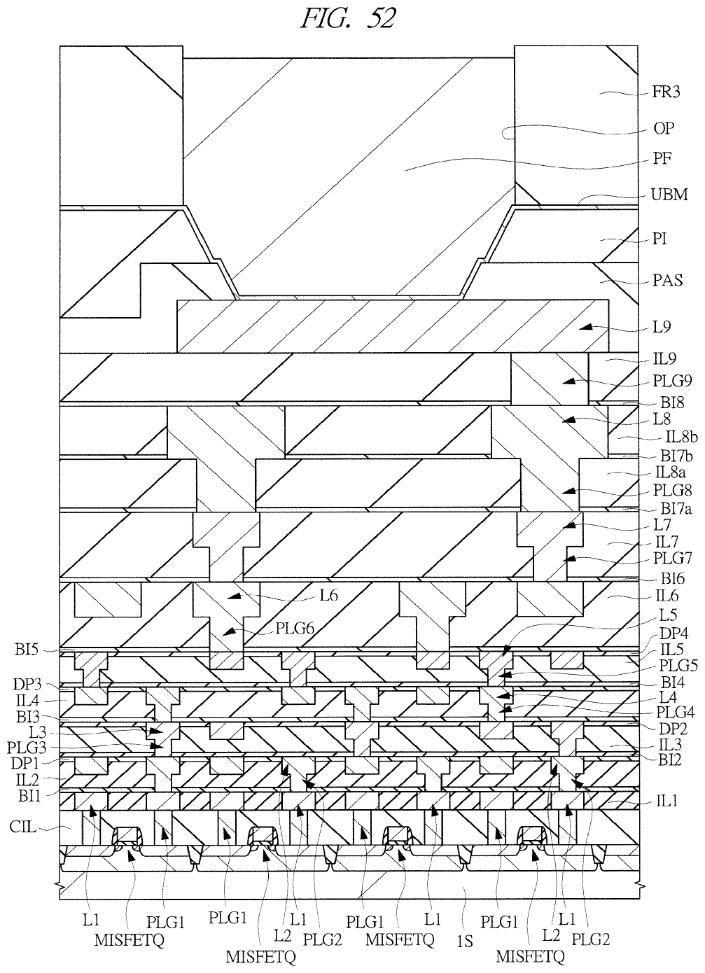

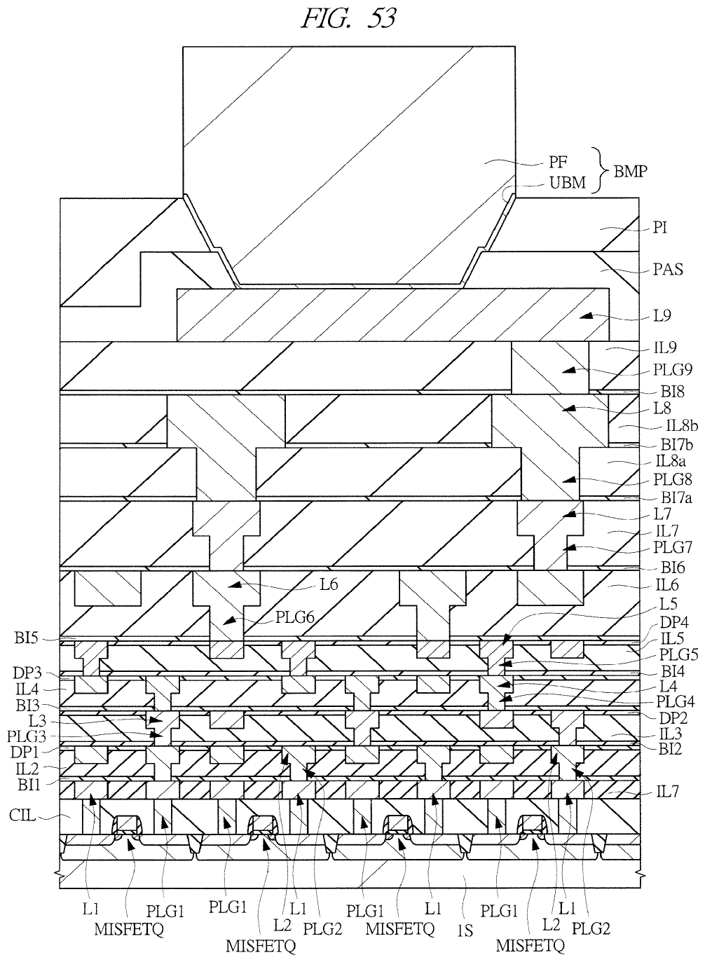

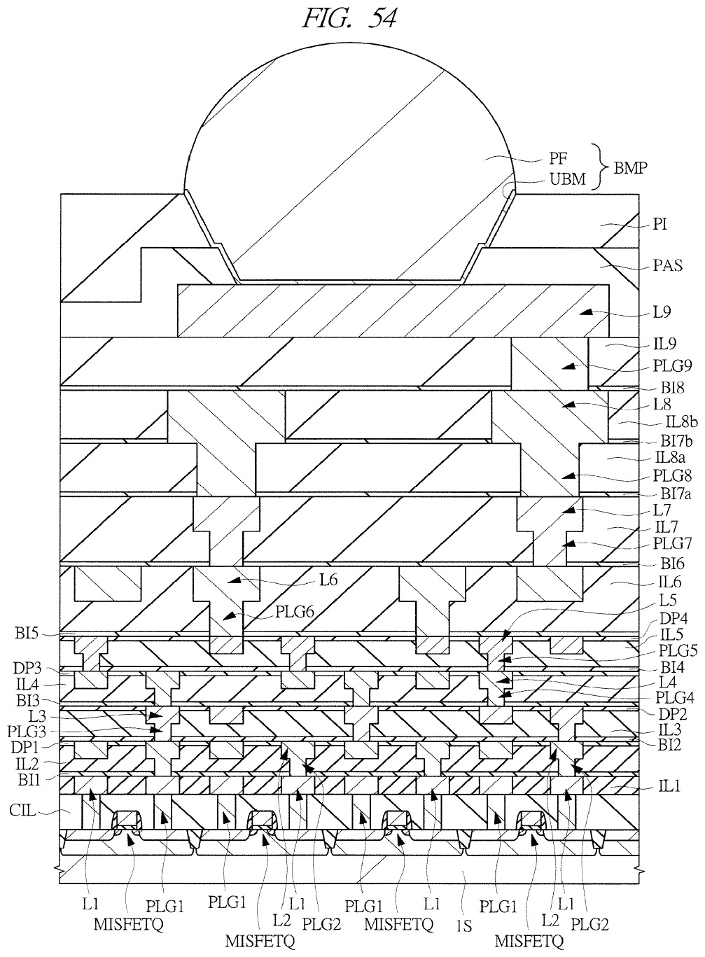

Subsequently, as illustrated in FIG. 52, by using plating, a gold film OF is formed inside the opening portion OP from which the pad PD is exposed. In this manner, the gold film PF is formed to be stacked on the pad PD. Thereafter, as illustrated in FIG. 53, the under bump metal film UBM formed at a lower layer of the patterned photoresist film FR3 and the photoresist film FR is removed. In this manner, the bump electrode BMP is formed on the pad PD. Then, as illustrated in FIG. 54, by performing a reflow processing (thermal processing) on the semiconductor substrate 1S, the shape of the bump electrode BMP is made into a spherical shape. In the above-described manner, the MISFET, multilayer wiring, and bump electrode BMP can be formed on the semiconductor substrate 1S.

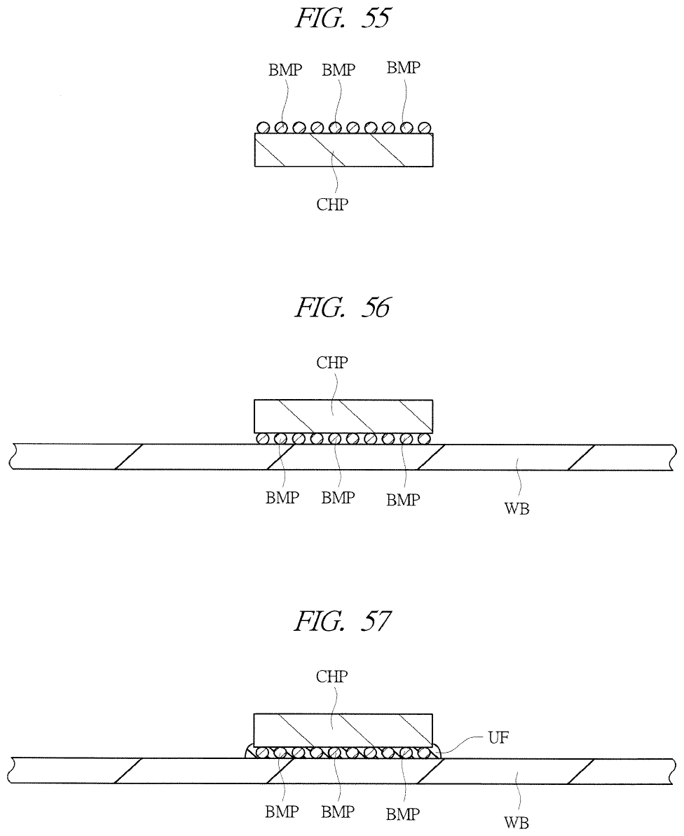

Subsequently, as illustrated in FIG. 55, the semiconductor substrate 1A is subjected to dicing, so that the plurality of semiconductor chips CHP are obtained. In FIG. 55, one semiconductor chip CHP is illustrated, and the bump electrode BMP is formed on a main surface side (element forming surface side) of the semiconductor chip CHP.

Next, as illustrated in FIG. 56, the semiconductor chip CHP is mounted on the wiring board WB. Here, the semiconductor chip CHP is mounted on the wiring board WB so that the bump electrode BMP formed to the semiconductor chip CHP and a terminal formed to the wiring board WB are contacted with each other. And, as illustrated in FIG. 57, the underfill UF is applied to cover the bump electrode BMP arranged in a gap between the semiconductor chip CHP and the wiring board WB. Thereafter, as illustrated in FIG. 58, the solder ball SB to be an external connection terminal is formed on the back surface of the wiring board WB (a surface opposite to the chip-mounting surface). Then, as illustrated in FIG. 59, as well as attaching a cover to an upper portion of the semiconductor chip CHP, the wiring board WB is singulated, and thus the semiconductor device according to the second embodiment can be manufactured.

Since the semiconductor chip CHP and the underfill UF are contacted in the semiconductor device of the second embodiment, when a temperature cycle is applied, stress is applied to the semiconductor chip CHP due to differences in coefficient of thermal expansion and Young's modulus of the semiconductor chip CHP and the underfill UF. Particularly, the closer to the lower layer of the multilayer wiring layers, the larger the stress generated in the semiconductor chip, and, the maximum stress is applied to an interface at which Young's modulus is different. However, according to the second embodiment, as illustrated in FIG. 54, the interlayer insulating film IL1 forming the first fine layer is formed of a middle-Young's-modulus film, and thus it is possible to separate the integrated high-Young's-modulus layer (the semiconductor substrate 1S and the contact interlayer insulating film CIL) and the interlayer insulating film IL2 forming the second fine layer not to let them directly contact with each other, and the stress can be diverged. As a result, film exfoliation of the interlayer insulating film IL2 formed of a low-Young's-modulus film can be prevented.

### Third Embodiment

While the packages of BGA (Ball Grid Array) have been described in the first and second embodiments, a package of QFP (Quad Flat Package) type using a lead frame will be described in a third embodiment.

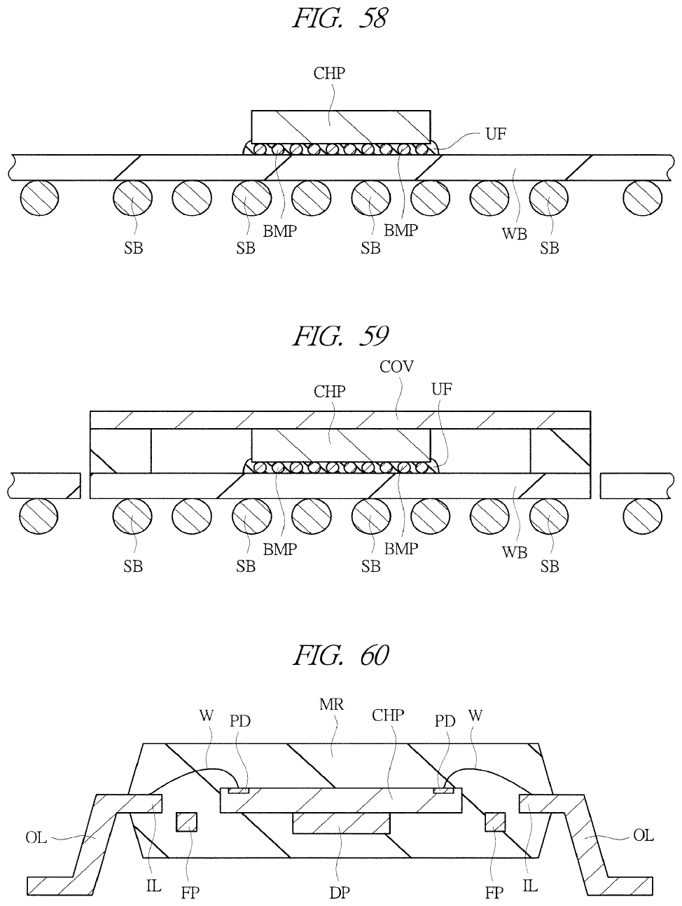

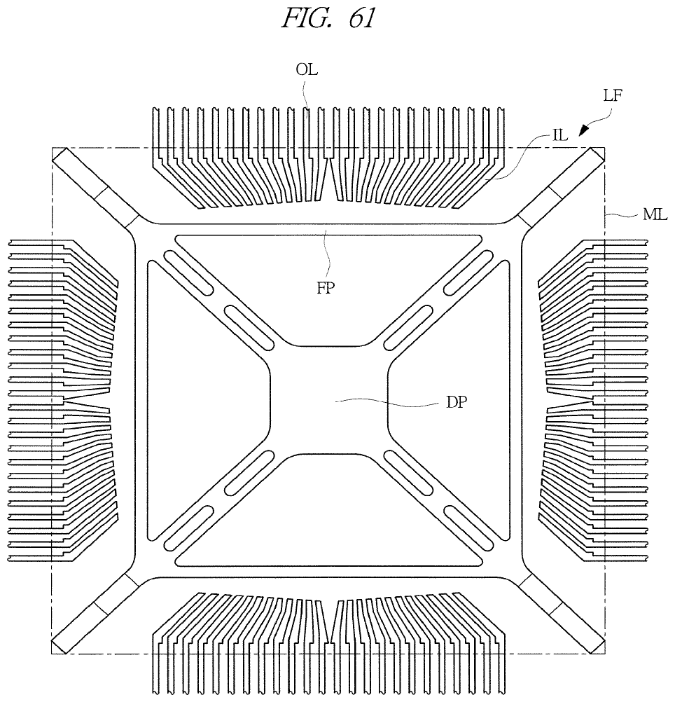

FIG. 60 describes a configuration example of a package according to the third embodiment. In FIG. 60, a semiconductor chip CHP is mounted on a die pad DP, and a frame portion FP is formed around the die pad DP. The pad PD formed to the semiconductor chip CHP is electrically connected to an inner lead IL through a wire W. In addition, the semiconductor chip CHP, the wire W, the inner lead IL, the die pad PD, and the frame portion FP are sealed with a resin MR. An outer lead OL is exposed from the resin MR.

In this manner, in the package illustrated in FIG. 60, the whole of the semiconductor chip CHP is sealed with the resin MR, and thus stress is applied to the semiconductor chip CHP due to temperature changes in a temperature cycle test. That is, when a wide range of temperature change by a temperature cycle test is applied to the package, stress is applied to the semiconductor chip CHP due to differences in coefficient of thermal expansion and Young's modulus of the semiconductor chip CHP and the resin MR. When the stress is generated to the semiconductor chip CHP, a problem of film exfoliation is feared to occur in a multilayer wiring formed in the semiconductor chip CHP. The same problem as the package of the first embodiment occurs also in the package of the third embodiment.

Accordingly, also in the third embodiment, the configuration of interlayer insulating film is devised in the same manner as the first embodiment (FIG. 3) described above. More specifically, as illustrated in FIG. 3, the interlayer insulating film IL1 forming the first fine layer is formed of, for example, a SiOC film. That is, the interlayer insulating film IL1 forming the first fine layer is formed of a middle-dielectric-constant film, a middle-Young's-modulus, or in other words, a middle-density film. Particularly, from a view point of a characteristic function of the interlayer insulating film IL1, the interlayer insulating film IL1 is formed of a middle-Young's-modulus film. In this manner, by forming the interlayer insulating film IL1 forming the first fine layer with a middle-Young's-modulus film, film exfoliation of a low-dielectric-constant film is prevented even when a low-dielectric-constant film having a lower dielectric constant than silicon oxide film is used to a part (the second fine layer) of the interlayer insulating films, and thus reliability of the semiconductor device can be improved.

Subsequently, a method of manufacturing the semiconductor device according to the second embodiment will be described with reference to the drawings. The process of FIGS. 13 to 42 is the same as the first embodiment. In this manner, the MISFET and the multilayer wiring can be formed on the semiconductor substrate 1S. Thereafter, by subjecting the semiconductor substrate 1S to dicing, the plurality of semiconductor chip are obtained.

Next, a lead frame LF as illustrated in FIG. 61 is prepared. As illustrated in FIG. 61, the lead frame LF mainly has the die pad DP to mount the semiconductor chip, the frame portion FP, the inner lead IL, and the outer lead OL. In addition, in the lead frame LF, a region surrounded by the mold line ML is a region to be sealed with a resin body. Hereinafter, a process of manufacturing the package using the lead frame LF configured in the manner will be described.

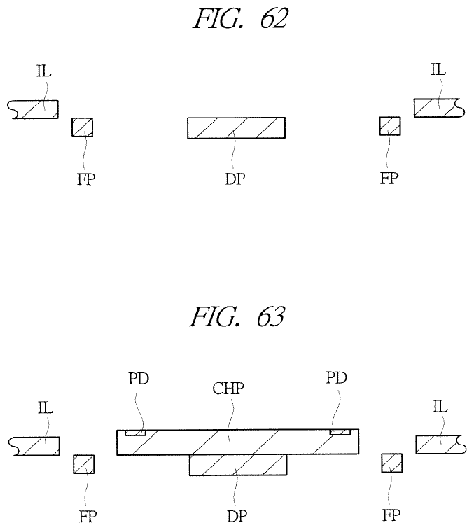

A cross section of the lead frame is illustrated in FIG. 62. As illustrated in FIG. 62, the die pad DP is disposed at a center portion, the frame portion FP is formed in a circumference surrounding the die pad PD, and the inner lead IL is formed outside the frame portion FP.

Subsequently, as illustrated in FIG. 63, the semiconductor chip CHP is mounted on the die pad DP. The semiconductor chip CHP and the die pad DP are fixedly attached with, for example, a die-attach film (not illustrated) or an adhesive material (not illustrated), etc.

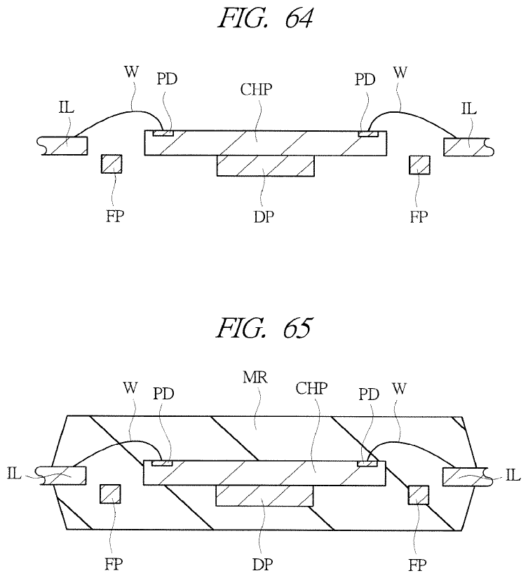

Thereafter, as illustrated in FIG. 64, the pad PD and the inner lead IL formed to the semiconductor chip CHP are electrically connected through the wire W. Then, as illustrated in FIG. 65, the semiconductor chip CHP, the wire W, the inner lead IL, the die pad DP, and the frame portion FP are sealed with the resin MR to cover them. Thereafter, an outer lead, which is not illustrated, is shaped, and thus the semiconductor device according to the third embodiment as illustrated in FIG. 60 can be manufactured.

As the semiconductor chip CHP is sealed with the resin MR in the semiconductor device of the third embodiment, when a temperature cycle is applied, stress is applied to the semiconductor chip CHP due to differences in coefficient of thermal expansion and Young's modulus of the semiconductor chip CHP and the resin MR. Particularly, the closer to the lower layer of the multilayer wiring layers, the larger the stress generated in the semiconductor chip, and, the maximum stress is applied to an interface at which Young's modulus is different. However, according to the third embodiment, as illustrated in FIG. 3, the interlayer insulating film IL1 forming the first fine layer is formed of a middle-Young's-modulus film, and thus it is possible to separate the integrated high-Young's-modulus layer (the semiconductor substrate 1S and the contact interlayer insulating film CIL) and the interlayer insulating film IL2 forming the second fine layer not to let them directly contact with each other, and the stress can be diverged. As a result, film exfoliation of the interlayer insulating film IL2 formed of a low-Young's-modulus film can be prevented.

### Fourth Embodiment

While the example of using a SiOC film to the interlayer insulating films IL6 and IL7 forming the semi global layer has been described in the first embodiment described above, an example of using a TEOS film or a silicon oxide film to the interlayer insulating films forming the semi global layer will be described in a fourth embodiment. That is, while middle-Young's-modulus films have been used as the interlayer insulating films IL6 and IL7 forming the semi global layer in the first embodiment described above, high-Young's-modulus films are used as interlayer insulating films forming the semi global layer in the fourth embodiment. Other configurations of the fourth embodiment than that are the same as the first embodiment described above.

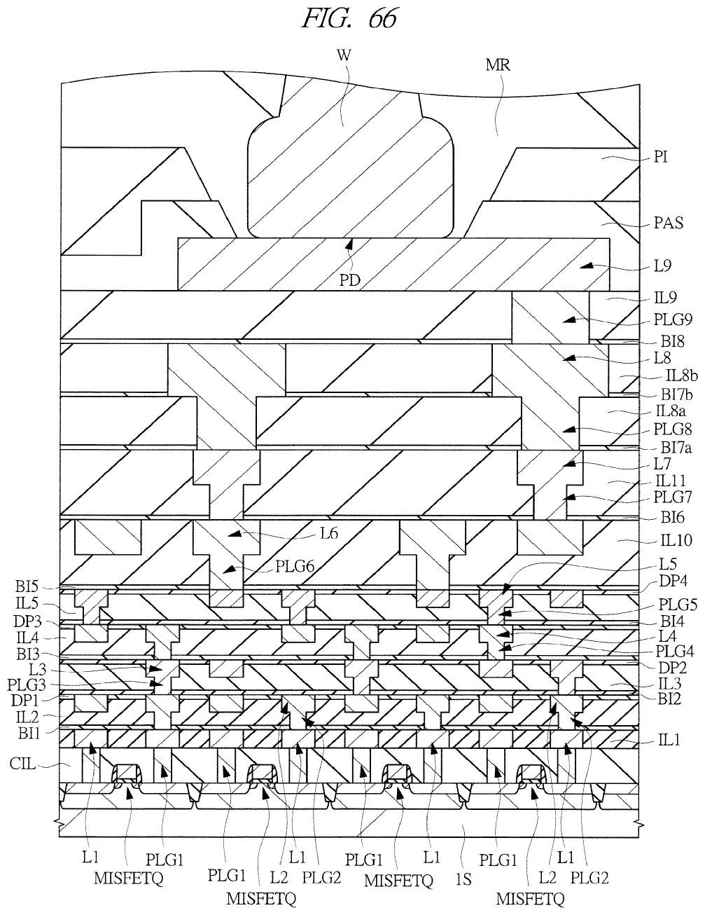

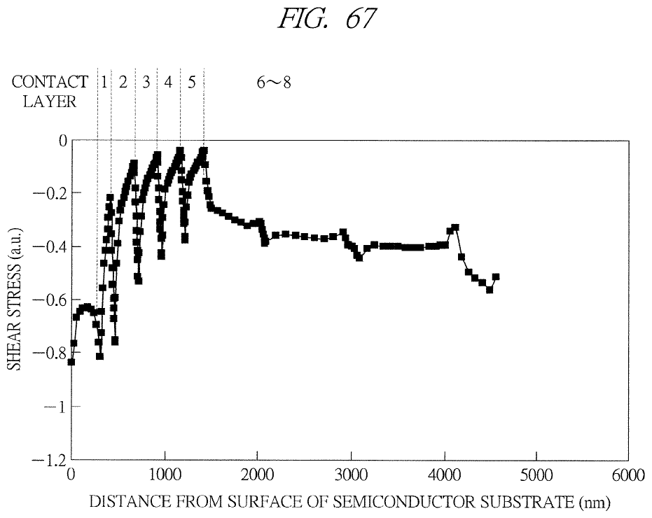

FIG. 66 is a cross-sectional view illustrating a device structure of the semiconductor device according to fourth embodiment. In FIG. 66, the device structure of the fourth embodiment is almost the same as that of the first embodiment. A different point is that, as illustrated in FIG. 66, an interlayer insulating film IL10 and an interlayer insulating film IL11 forming the semi global layer (sixth layer wiring L6 and seventh layer wiring L7) are formed of a TEOS film or a silicon oxide film, which is a high-Young's-modulus film in the fourth embodiment. In this manner, the fourth embodiment has an advantage of achieving an improvement in mechanical strength of the semi global layer.

For example, a probe needle (probe) is pushed onto the pad PD upon an electric characteristics inspection, and probing damage upon this is prone to be applied to the semi global layer. Further, in an assembly process such as a diving process to singulate the semiconductor substrate 1S into a plurality of semiconductor chips, the semi global layer is more prone to be damaged than the second fine layer at a lower layer. Therefore, to give damage resistance to various damages as mentioned above, the semi global layer is required to have mechanical strength to some extent. In consideration of this point, in the fourth embodiment, the interlayer insulating films IL6 and IL7 have been formed with middle-Young's-modulus films, but this case may also have a lack of mechanical strength. Accordingly, in the fourth embodiment, a TEOS film and/or a silicon oxide film having higher mechanical strength than the SiOC film (middle-Young's-modulus film) is used as the interlayer insulating films IL10 and IL11 forming the semi global layer so that resistance to probing damage etc. is improved.

Also in the fourth embodiment as configured as described above, when a temperature cycle is applied, stress is applied to the semiconductor chip due to differences in coefficient of thermal expansion and Young's modulus of the semiconductor chip and the resin. Particularly, the closer to the lower layer of the multilayer wiring layers, the larger the stress generated in the semiconductor chip, and, the maximum stress is applied to an interface at which Young's modulus becomes different. This characteristic is independent of the material of the interlayer insulating films forming the semi global layer. Therefore, in the fourth embodiment having an almost the same configuration as the first embodiment, as illustrated in FIG. 66, the interlayer insulating film IL1 forming the first fine layer is formed of a middle-Young's-modulus film, and thus it is possible to separate the integrated high-Young's-modulus layer (the semiconductor substrate 1S and the contact interlayer insulating film CIL) and the interlayer insulating film IL2 forming the second fine layer not to let them directly contact with each other, and the stress can be diverged. As a result, film exfoliation of the interlayer insulating film IL2 formed of a low-Young's-modulus film can be prevented same as the first embodiment.

Subsequently, it will be described that stress can be actually reduced according to the fourth embodiment. FIG. 67 is a graph illustrating a relationship of a distance from the semiconductor substrate and shear stress. In FIG. 67, the horizontal axis is for the distance (nm) from the semiconductor substrate and the vertical axis is for shear stress. Note that the values of shear stress indicate relative numerical values, and a value of about “−1” is a stress value at which film exfoliation is caused.

The numerical values of “1” to “8” described in the upper portion of FIG. 12 indicate respective layers of the multilayer wiring. For example, “1” denotes the first fine layer, and “2” to “5” denote the second fine layer. Further, “6” to “8” denote the semi global layer and the global layer. Note that, the contact layer is also denoted.

In the fourth embodiment, forming a boundary of the first layer wiring L1 (first fine layer) and a second layer wiring (second fine layer) with a SiOC film (middle-Young's-modulus film) is described. From the curve illustrated, it is understood that stress generated at the boundary of the first layer wiring L1 (first fine layer) and the second layer wiring L2 (second fine layer) is reduced as it is diverged to the boundary of the contact layer and the first layer wiring L1. That is, as illustrated in FIG. 67, the stress generated at the boundary of the contact layer and the first layer wiring and the stress generated at the boundary of the first layer wiring and the second layer wiring are both suppressed to a sufficiently smaller values than the stress value “−1” at which film exfoliation is prone to occur. This indicates that forming the first layer wiring with a middle-Young's-modulus film can separate the integrated high-Young's-modulus layer (the semiconductor substrate 1S and the contact interlayer insulating film CIL) and the interlayer insulating film IL2 forming the second fine layer not to let them directly contact with each other, and thus the stress can be diverged. Therefore, according to the curve illustrated in the fourth embodiment, exfoliation of the interlayer insulating films (low-Young's-modulus films) forming the second layer wiring (second fine layer) can be sufficiently prevented.

### Fifth Embodiment

While the example of forming the interlayer insulating film IL1 forming the first fine layer with a middle-Young's-modulus film has been descried in the first embodiment, an example of forming an interlayer insulating film forming the first fine layer with a stacked film of a middle-Young's-modulus film, a low-Young's-modulus film, and a high-Young's-modulus film will be described in a fifth embodiment.

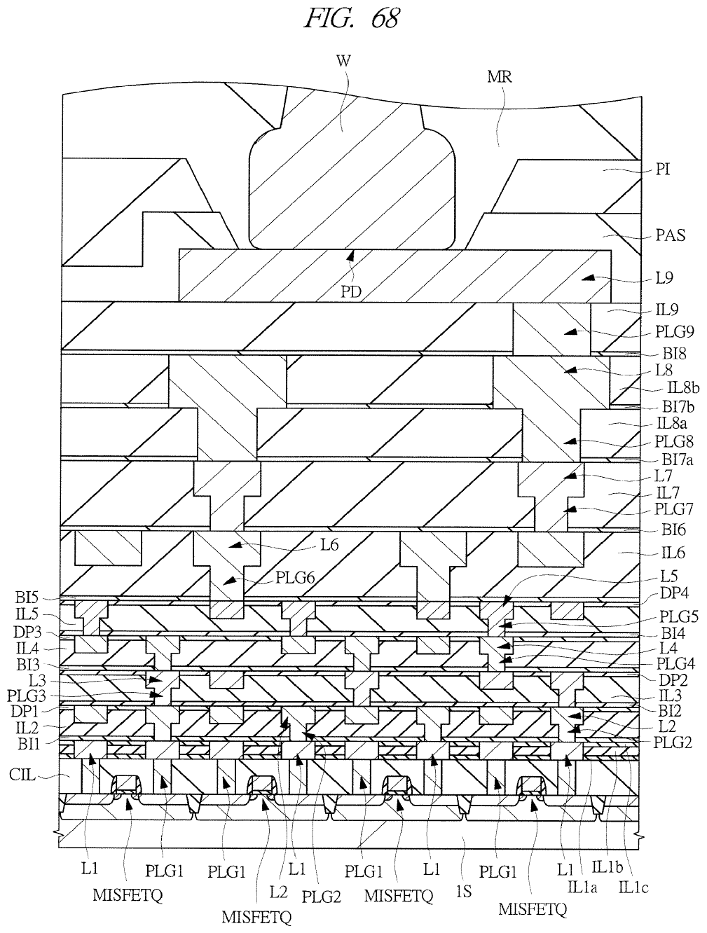

FIG. 68 is a cross-sectional view illustrating a device configuration of a semiconductor device according to the fifth embodiment. In FIG. 68, the device structure of the fifth embodiment has an almost the same configuration as the device structure (see FIG. 3) of the first embodiment described above. A different point is in the configuration of the insulating films forming the first fine layer. More specifically, in the fifth embodiment, as illustrated in FIG. 68, interlayer insulating films forming the first fine layer are formed of: an interlayer insulating film IL1a; an interlayer insulating film IL1b formed on the interlayer insulating film IL1a; and an interlayer insulating film IL1c formed on the interlayer insulating film IL1b. Here, the interlayer insulating film IL1a is formed of a middle-Young's-modulus film such as a SiOC film, a HSQ film, or a MSQ film, and the interlayer insulating film IL1b is formed of a low-Young's-modulus film such as a SiOC film having a void, a HSQ film having a void, or a MSQ film having a void. Meanwhile, the interlayer insulating film IL1c is formed of a middle-Young's-modulus film such as a SiOC film, a HSQ film, or a MSQ film.

Hereinafter, a reason of using such a configuration will be described. First, the first layer wiring L1 forming the first fine layer is basically miniaturized, and its wiring interval is narrow. Therefore, dielectric constant of the interlayer insulating films filling between wirings is problematic. That is, when dielectric constant of the interlayer insulating film is high, parasitic capacitance between wirings forming the first layer wiring L1 is increased, causing signal delay. From the view point of preventing the signal delay, it is preferable to make dielectric constant of the interlayer insulating films forming the first fine layer as low as possible. Accordingly, in the fifth embodiment, the interlayer insulating films forming the first fine layer is first formed with the interlayer insulating film IL1b which is a low-dielectric-constant film. That is, the interlayer insulating film IL1b is formed of a SiOC film having a void to lower the dielectric constant. While it is possible to lower the dielectric constant of the interlayer insulating films by forming the interlayer insulating film IL1b with a SiOC film having a void, from another view point, the interlayer insulating film IL1b is a low-Young's-modulus film having low mechanical strength. Accordingly, to strengthen the mechanical strength of the interlayer insulating film IL1b, the interlayer insulating film IL1c formed of a middle-Young's-modulus film is formed on the interlayer insulating film IL1b. That is, the interlayer insulating film IL1c is a film provided for strengthen the mechanical strength of the interlayer insulating film IL1b and for protecting the interlayer insulating film IL1b from various damages.

Next, an important function of the interlayer insulating film IL1a will be described. For example, when the interlayer insulating film IL1c is not formed, the interlayer insulating film IL1b which is a low-Young's-modulus film contacts the contact interlayer insulating film CIL which is a high-Young's-modulus film. Further, as the contact interlayer insulating film CIL is formed on the semiconductor substrate 1S, the interlayer insulating film IL1b, which is a low-Young's-modulus film, directly contacts the integrated high-Young's-modulus layer formed of the semiconductor substrate 1S and the contact interlayer insulating film CIL.

Also in the fifth embodiment, when a temperature cycle is applied, stress is applied to the semiconductor chip due to differences in coefficient of thermal expansion and Young's modulus of the semiconductor chip and the resin. Particularly, the closer to the lower layer of the multilayer wiring layers, the larger the stress generated in the semiconductor chip, and, the maximum stress is applied to an interface at which Young's modulus becomes different. Therefore, in the fifth embodiment, when the interlayer insulating film IL1a is not formed, the maximum stress is applied to the boundary of the integrated high-Young's-modulus layer and the interlayer insulating film IL1b which is a low-Young's-modulus film. As a result, film exfoliation of the interlayer insulating film IL1b occurs.

Accordingly, in the fifth embodiment, the interlayer insulating film IL1a, which is a middle-Young's-modulus film, is formed at a lower layer of the interlayer insulating film IL1b which is a low-Young's-modulus film. In this manner, according to the fifth embodiment, as the interlayer insulating film IL1a formed of a middle-Young's-modulus film is formed at a lower layer of the interlayer insulating film IL1b formed of a low-Young's-modulus film, it is possible to separate the integrated high-Young's-modulus layer (the semiconductor substrate 1S and the contact interlayer insulating film CIL) and the interlayer insulating film IL1b not to let them directly contact with each other, and the stress can be diverged. As a result, film exfoliation of the interlayer insulating film IL1b formed of a low-Young's-modulus film can be prevented.

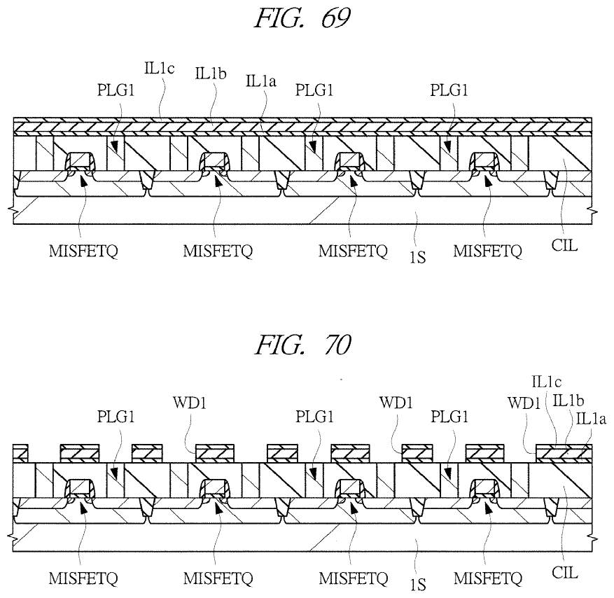

The semiconductor device according to the fifth embodiment is configured in the above-described manner, and a method of manufacturing the same will be described hereinafter with reference to the drawings. The process illustrated in FIGS. 13 to 16 is the same as the first embodiment. Subsequently, as illustrated in FIG. 69, on the contact interlayer insulating film CIL to which the plug PLG1 is formed, the interlayer insulating film IL1a, the interlayer insulating film IL1b, and the interlayer insulating film IL1c are sequentially formed. The interlayer insulating film IL1a is formed of, for example, a SiOC film which is a middle-Young's-modulus film and can be formed by, for example, CVD; and the interlayer insulating film IL1b is formed of, for example, a SiOC film having a void and can be formed by, for example, CVD. And, the interlayer insulating film IL1c is formed of, for example, a SiOC film which is a middle-Young's-modulus film and can be formed by, for example, CVD.

Next, as illustrated in FIG. 70, by using photolithography technology and etching technology, the wiring trench WD1 penetrating through the interlayer insulating films IL1a to IL1c and exposing the plug PLG1 at its bottom surface is formed.

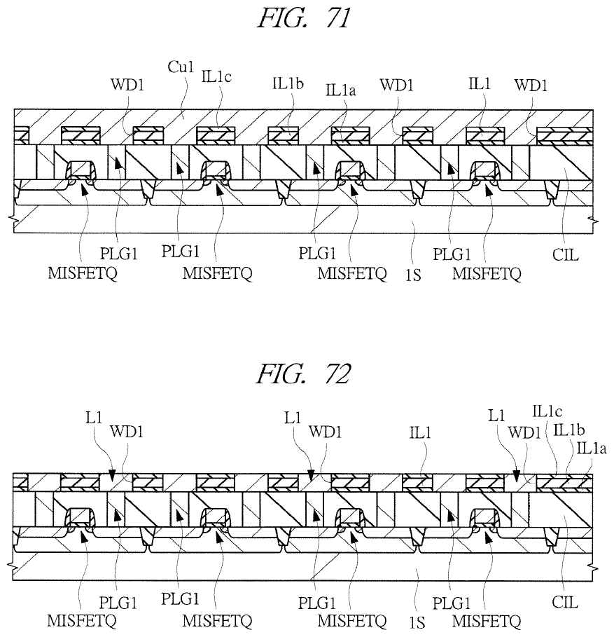

Thereafter, as illustrated in FIG. 71, a barrier conductive film (film for preventing copper diffusion) (not illustrated) is formed on the interlayer insulating film IL1c to which the wiring trench WD1 is formed. More specifically, the barrier conductive film is formed of tantalum (Ta), titanium (Ti), ruthenium (Ru), tungsten (W), manganese (Mn), nitride or nitride-silicate of them, or a stacked film of them, and formed by, for example, sputtering.

Subsequently, on the barrier conductive film formed inside the wiring trench WD1 and on the interlayer insulating film IL1c, a seed film formed of, for example, a thin copper film is formed by sputtering. Then, the copper film Cu1 is formed by electrolytic plating using the seed film as electrode. The copper film Cu1 is formed to fill in the wiring trench WD1. The copper film Cu1 is formed of, for example, a film mainly containing copper. More specifically, the copper film is formed of copper (Cu) or a copper alloy (an alloy of copper (Cu) with aluminum (Al), magnesium (Mg), titanium (Ti), manganese (Mn), iron (Fe), zinc (Zn), zirconium (Zr), niobium (Nb), molybdenum (Mo), ruthenium (Ru), palladium (Pd), silver (Ag), gold (Au), indium (In), a lanthanum-based metal, and/or actinoid-based metal).

Next, as illustrated in FIG. 72, unnecessary parts of the barrier conductive film and the copper film CUl formed on the interlayer insulating film IL1c is removed by CMP. In this manner, the first layer wiring L1 (first fine layer) in which the barrier conductive film and the copper film Cu1 are buried in the wiring trench WD1 can be formed. Note that, the interlayer insulating film IL1c is provided as a barrier film to polishing pressure of the CMP, having a function of preventing polishing pressure of the CMP on the interlayer insulating film IL1b.

The process thereafter is the same as the first embodiment. In this manner, the semiconductor device according to the fifth embodiment can be manufactured.

In the foregoing, the invention made by the inventors of the present invention has been concretely described based on the embodiments. However, it is needless to say that the present invention is not limited to the foregoing embodiments and various modifications and alterations can be made within the scope of the present invention.

### INDUSTRIAL APPLICABILITY

The present invention can be widely used in manufacturing field of manufacturing semiconductor devices.

### DESCRIPTIONS OF REFERENCES

1S Semiconductor substrate
BI1 Barrier insulating film
BI1a SiCN film
BI1b SiCO film
BI2 Barrier insulating film
BI3 Barrier insulating film
BI4 Barrier insulating film
BI5 Barrier insulating film
BI6 Barrier insulating film
BI6a SiCN film
BI6b SiCO film
BI7a Barrier insulating film
BI7a1 SiCN film
BI7a2 SiCO film
BI7b Etching stop insulating film
BI8 Barrier insulating film
BM1 Barrier insulating film
BM2 Barrier insulating film
BM7 Barrier insulating film
BM8 Barrier insulating film
BMP Bump electrode
CHP Semiconductor chip
CIL Contact interlayer insulating film
CMP1 CMP protection film
CNT1 Contact hole
COV Cover
CP Wiring
Cu1 Copper film
Cu2 Copper film
Cu3 Copper film
Cu4 Copper film
DP Die pad
DP1 Damage protection film
DP2 Damage protection film
DP3 Damage protection film
DP4 Damage protection film
FP Frame portion
FR1 Photoresist film
FR2 Photoresist film
FR3 Photoresist film
IL Inner lead
IL1 Interlayer insulating film
IL1a Interlayer insulating film
IL1b Interlayer insulating film
IL1c Interlayer insulating film
IL2 Interlayer insulating film
IL3 Interlayer insulating film
IL4 Interlayer insulating film
IL5 Interlayer insulating film
IL6 Interlayer insulating film
IL7 Interlayer insulating film
IL8a Interlayer insulating film
IL8b Interlayer insulating film
IL9 Interlayer insulating film
IL10 Interlayer insulating film
IL11 Interlayer insulating film
LF Lead frame
L1 First layer wiring
L2 Second layer wiring
L3 Third layer wiring
L4 Fourth layer wiring
L5 Fifth layer wiring
L6 Sixth layer wiring
L7 Seventh layer wiring
L8 Eighth layer wiring
L9 Uppermost layer wiring
ML Mold line
MR Resin
OL Outer lead
OP Opening portion
PAS Passivation film
PD Pad
PF Gold film
PI Polyimide film
PLG1 Plug
PLG2 Plug
PLG3 Plug
PLG4 Plug
PLG5 Plug
PLG6 Plug
PLG7 Plug
PLG8 Plug
PLG9 Plug
Q MISFET
SB Solder ball
TE Terminal
UBM Under bump metal film
UF Underfill
V1 Via hole
V2 Via hole
V3 Via hole
W Wire
WB Wiring board
WD1 Wiring trench
WD2 Wiring trench
WD3 Wiring trench
WD4 Wiring trench

1. A semiconductor device comprising:
a semiconductor substrate;
a MISFET formed on the semiconductor substrate;
a contact interlayer insulating film covering the MISFET formed on the semiconductor substrate;
a first plug formed in the contact interlayer insulating film and electrically connected to the MISFET;
a first interlayer insulating film formed on the contact interlayer insulating film;
a first layer wiring formed in the first interlayer insulating film and electrically connected to the first plug;
a barrier insulating film formed on the first interlayer insulating film and the first layer wiring;
a second interlayer insulating film formed on the barrier insulating film;
a second plug formed in the second interlayer insulating film and electrically connected to the first layer wiring; and
a second layer wiring formed in the second interlayer insulating film and electrically connected to the second plug,
wherein the contact interlayer insulating film is formed of a high-dielectric-constant film having the highest dielectric constant among the contact interlayer insulating film, the first interlayer insulating film and the second interlayer insulating film,
wherein the second interlayer insulating film is formed of a low-dielectric-constant film having the lowest dielectric constant among the contact interlayer insulating film, the first interlayer insulating film and the second interlayer insulating film,
wherein the first interlayer insulating film is formed of a middle-dielectric-constant film having dielectric constant lower than that of the contact interlayer insulating film and higher than that of the second interlayer insulating film,
wherein a dielectric constant of the high-dielectric-constant film is larger than or equal to 3.5,
wherein a dielectric constant of the middle-dielectric-constant film is larger than or equal to 2.8 and smaller than 3.5,
wherein a dielectric constant of the low-dielectric-constant film is smaller than 2.8, and
wherein the barrier insulating film is formed of:
a SiCN film; and
one of a SiCO film and a SiN film, formed on the SiCN film.

2. The semiconductor device according to claim 1,
wherein the high-dielectric-constant film is formed of either of a silicon oxide film, a SiOF film or a TEOS film,
wherein the first interlayer insulating film is formed of either of a SiOC film, an ESQ film, or an MSQ film, and
wherein the second interlayer insulating film is formed of either of a SiOC film having a void, an ESQ film having a void, or an MSQ film having a void.

3. The semiconductor device according to claim 2, further comprising:
a damage protection film formed on the second interlayer insulating film,
wherein the damage protection film is formed of a SiOC film, and
wherein the second layer wiring and the second plug are formed to be buried in the second interlayer insulating film and the damage protection film.

4. The semiconductor device according to claim 1,
wherein a thickness of the first interlayer insulating film is larger than or equal to 100 nm.

5. The semiconductor device according to claim 1,
wherein a thickness of the first interlayer insulating film is smaller than or equal to 200 nm.

6. The semiconductor device according to claim 4,
wherein a thickness of the first interlayer insulating film is smaller than or equal to 200 nm.

7. The semiconductor device according to claim 2,
wherein a thickness of the first interlayer insulating film is larger than or equal to 100 nm.

8. The semiconductor device according to claim 2,
wherein a thickness of the first interlayer insulating film is smaller than or equal to 200 nm.

9. The semiconductor device according to claim 7,
wherein a thickness of the first interlayer insulating film is smaller than or equal to 200 nm.

10. The semiconductor device according to claim 4,
wherein a thickness of the second interlayer insulating film is 200 nm to 2000 nm.

11. The semiconductor device according to claim 7,
wherein a thickness of the second interlayer insulating film is 200 nm to 2000 nm.

12. The semiconductor device according to claim 4,
wherein the high-dielectric-constant film is formed of a TEOS film.

13. The semiconductor device according to claim 7,
wherein the high-dielectric-constant film is formed of the TEOS film.

14. The semiconductor device according to claim 1, further comprising:
a third interlayer insulating film formed on the second interlayer insulating film;
a third plug formed in the third interlayer insulating film; and
a third layer wiring formed in the third interlayer insulating film and electrically connected to the third plug,
wherein the third interlayer insulating film is formed of either of a SiOC film, an HSQ film, or an MSQ film.

15. The semiconductor device according to claim 14, further comprising:
a fourth interlayer insulating film formed on the third interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

16. The semiconductor device according to claim 2, further comprising:
a third interlayer insulating film formed on the second interlayer insulating film;
a third plug formed in the third interlayer insulating film; and
a third layer wiring formed in the third interlayer insulating film and electrically connected to the third plug,
wherein the third interlayer insulating film is formed of either of a SiOC film, an HSQ film, or an MSQ film.

17. The semiconductor device according to claim 16, further comprising:
a fourth interlayer insulating film formed on the third interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

18. The semiconductor device according to claim 4, further comprising:
a third interlayer insulating film formed on the second interlayer insulating film;
a third plug formed in the third interlayer insulating film; and
a third layer wiring formed in the third interlayer insulating film and electrically connected to the third plug,
wherein the third interlayer insulating film is formed of either of a SiOC film, an HSQ film, or an MSQ film.

19. The semiconductor device according to claim 18, further comprising:
a fourth interlayer insulating film formed on the third interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

20. The semiconductor device according to claim 1, further comprising:
a fourth interlayer insulating film formed on the second interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

21. The semiconductor device according to claim 2, further comprising:
a fourth interlayer insulating film formed on the second interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

22. The semiconductor device according to claim 4, further comprising:
a fourth interlayer insulating film formed on the second interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

23. A semiconductor device comprising:
a semiconductor substrate;
a MISFET formed on the semiconductor substrate;
a contact interlayer insulating film covering the MISFET formed on the semiconductor substrate;
a first plug formed in the contact interlayer insulating film and electrically connected to the MISFET;
a first interlayer insulating film formed on the contact interlayer insulating film;
a first layer wiring formed in the first interlayer insulating film and electrically connected to the first plug;
a barrier insulating film formed on the first interlayer insulating film and the first layer wiring;
a second interlayer insulating film formed on the barrier insulating film;
a second plug formed in the second interlayer insulating film and electrically connected to the first layer wiring; and
a second layer wiring formed in the second interlayer insulating film and electrically connected to the second plug,
wherein the contact interlayer insulating film is formed of a high-Young's-modulus film having the highest Young's modulus among the contact interlayer insulating film, the first interlayer insulating film and the second interlayer insulating film,
wherein the second interlayer insulating film is formed of a low-Young's-modulus film having the lowest Young's modulus among the contact interlayer insulating film, the first interlayer insulating film and the second interlayer insulating film,
wherein the first interlayer insulating film is formed of a middle-Young's-modulus film having Young's modulus lower than that of the contact interlayer insulating film and higher than that of the second interlayer insulating film,
wherein a Young's modulus of the high-Young's-modulus film is larger than or equal to 30,
wherein a Young's modulus of the middle-Young's-modulus film larger than or equal to 15 and smaller than 30,
wherein a Young's modulus of the low-Young's-modulus film is smaller than 15, and
wherein the barrier insulating film is formed of:
a SiCN film; and
one of a SiCO film and a SiN film, formed on the SiCN film.

24. The semiconductor device according to claim 23, wherein the high-Young's-modulus film is formed of either of a silicon oxide film, a SiOF film or a TEOS film, wherein the first interlayer insulating film is formed of either of a SiOC film, an HSQ film, or an MSQ film, and wherein the second interlayer insulating film is formed of either of a SiOC film having a void, an HSQ film having a void, or an MSQ film having a void.

25. The semiconductor device according to claim 24, further comprising:
a damage protection film formed on the second interlayer insulating film,
wherein the damage protection film is formed of a SiOC film, and
wherein the second layer wiring and the second plug are formed to be buried in the second interlayer insulating film and the damage protection film.

26. The semiconductor device according to claim 23,
wherein a thickness of the first interlayer insulating film is larger than or equal to 100 nm.

27. The semiconductor device according to claim 23,
wherein a thickness of the first interlayer insulating film is smaller than or equal to 200 nm.

28. The semiconductor device according to claim 26,
wherein a thickness of the first interlayer insulating film is smaller than or equal to 200 nm.

29. The semiconductor device according to claim 24,
wherein a thickness of the first interlayer insulating film is larger than or equal to 100 nm.

30. The semiconductor device according to claim 24,
wherein a thickness of the first interlayer insulating film is smaller than or equal to 200 nm.

31. The semiconductor device according to claim 29,
wherein a thickness of the first interlayer insulating film is smaller than or equal to 200 nm.

32. The semiconductor device according to claim 26,
wherein a thickness of the second interlayer insulating film is 200 nm to 2000 nm.

33. The semiconductor device according to claim 29,
wherein a thickness of the second interlayer insulating film is 200 nm to 2000 nm.

34. The semiconductor device according to claim 26,
wherein the high-Young's-modulus film is formed of a TEOS film.

35. The semiconductor device according to claim 29,
wherein the high-Young's-modulus film is formed of the TEOS film.

36. The semiconductor device according to claim 23, further comprising:
a third interlayer insulating film formed on the second interlayer insulating film;
a third plug formed in the third interlayer insulating film; and
a third layer wiring formed in the third interlayer insulating film and electrically connected to the third plug,
wherein the third interlayer insulating film is formed of either of a SiOC film, an HSQ film, or an MSQ film.

37. The semiconductor device according to claim 36, further comprising:
a fourth interlayer insulating film formed on the third interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

38. The semiconductor device according to claim 24, further comprising:
a third interlayer insulating film formed on the second interlayer insulating film;
a third plug formed in the third interlayer insulating film; and
a third layer wiring formed in the third interlayer insulating film and electrically connected to the third plug,
wherein the third interlayer insulating film is formed of either of a SiOC film, an HSQ film, or an MSQ film.

39. The semiconductor device according to claim 38, further comprising:
a fourth interlayer insulating film formed on the third interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

40. The semiconductor device according to claim 26, further comprising:
a third interlayer insulating film formed on the second interlayer insulating film;
a third plug formed in the third interlayer insulating film; and
a third layer wiring formed in the third interlayer insulating film and electrically connected to the third plug,
wherein the third interlayer insulating film is formed of either of a SiOC film, an HSQ film, or an MSQ film.

41. The semiconductor device according to claim 40, further comprising:
a fourth interlayer insulating film formed on the third interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

42. The semiconductor device according to claim 23, further comprising:
a fourth interlayer insulating film formed on the second interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

43. The semiconductor device according to claim 24, further comprising:
a fourth interlayer insulating film formed on the second interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.

44. The semiconductor device according to claim 26, further comprising:
a fourth interlayer insulating film formed on the second interlayer insulating film;
a fourth plug formed in the fourth interlayer insulating film;
a fourth layer wiring formed on the fourth interlayer insulating film and electrically connected to the fourth plug; and
a passivation film formed on the fourth layer wiring,
wherein the fourth layer wiring is exposed from an opening portion formed to the passivation film, and
wherein the fourth interlayer insulating film is formed of either of a silicon oxide film, a SiOF film or a TEOS film.
